(19) United States
(12) Patent Application Publication
(10) Pub. No.: US 2026/0082685 A1
(43) Pub. Date: Mar. 19, 2026

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Takashi YOSHIMURA, Matsumoto-city (JP); Makoto SHIMOSAWA, Matsumoto-city (JP)

(21) Appl. No.: 19/399,348

(22) Filed: Nov. 24, 2025

Related U.S. Application Data
(63) Continuation of application No. PCT/JP2024/043869, filed on Dec. 11, 2024.

(30) Foreign Application Priority Data
Dec. 13, 2023 (JP) 2023-210076

(51) Int. Cl. H10D 84/00; H10D 8/00; H10D 8/01; H10D 12/00; H10D 12/01; H10D 62/10; H10D 62/53; H10D 64/62

(52) U.S. Cl. CPC H10D 84/161; H10D 8/422; H10D 12/481; H10D 62/103; H10D 62/53; H10D 64/62; H10D 8/045; H10D 12/038

(57) ABSTRACT

Provided is a semiconductor device comprising: a semiconductor substrate; an interlayer dielectric film that is above the semiconductor substrate and is provided with a contact hole; a first upper electrode provided above the interlayer dielectric film, and including a first region having a first contact portion that is electrically connected to the first upper electrode via the contact hole, and a second region having a second contact portion that is electrically connected to the first upper electrode via the contact hole, wherein the second contact portion has a higher resistance than that of the first contact portion.

The contents of the following patent application(s) are incorporated herein by reference:
NO. 2023-210076 filed in JP on Dec. 13, 2023
NO. PCT/JP2024/043869 filed in WO on Dec. 11, 2024.

### BACKGROUND

### 1. Technical Field

The present invention relates to a semiconductor device and a method for manufacturing the semiconductor device.

### 2. Related Art

Patent document 1 describes a semiconductor device provided with a silicide layer in a contact hole.

### RELATED ART DOCUMENTS

### Patent Document

Patent Document 1: Japanese Laid-Open Patent Publication No. 2003-318396
Patent Document 2: Japanese Laid-Open Patent Publication No. 2007-335554
Patent Document 3: Japanese Laid-Open Patent Publication No. 2002-334850

### BRIEF DESCRIPTION OF THE DRAWINGS

FIG. 1A shows an example of a top view of a semiconductor device 100.

FIG. 1B shows an example of a top view of the semiconductor device 100.

FIG. 1C shows an example of a cross section a-a′ in FIG. 1B.

FIG. 2A is an enlarged view of a cross section of the semiconductor device 100.

FIG. 2B is an enlarged view of a cross section of the semiconductor device 100.

FIG. 2C is an enlarged view of a cross section of the semiconductor device 100.

FIG. 2D is an enlarged view of a cross section of the semiconductor device 100.

FIG. 2E is an enlarged view of a cross section of the semiconductor device 100.

FIG. 3A is an enlarged view of a cross section of the semiconductor device 100.

FIG. 3B is an enlarged view of a cross section of the semiconductor device 100.

FIG. 3C is an enlarged view of a cross section of the semiconductor device 100.

FIG. 3D is an enlarged view of cross section of the semiconductor device 100.

FIG. 3E is an enlarged view of a cross section of the semiconductor device 100.

FIG. 4A is an enlarged view of a cross section of the semiconductor device 100.

FIG. 4B is an enlarged view of a cross section of the semiconductor device 100.

FIG. 5A shows an example of a cross section a-a′ in FIG. 1B.

FIG. 5B shows another example of the cross section a-a′ in FIG. 1B.

FIG. 5C is an enlarged view of a cross section of the semiconductor device 100.

FIG. 5D shows another example of a cross section a-a′ in FIG. 1B.

FIG. 5E shows another example of a cross section a-a′ in FIG. 1B.

FIG. 6A is an enlarged view of a cross section of the semiconductor device 100.

FIG. 6B is an enlarged view of a cross section of the semiconductor device 100.

FIG. 7A is an enlarged view of a cross section of the semiconductor device 100.

FIG. 7B is an enlarged view of a cross section of the semiconductor device 100.

FIG. 8 is a flowchart showing an example of a process of manufacturing a semiconductor device 100.

FIG. 9 is a flowchart showing an example of a process of manufacturing a semiconductor device 100.

FIG. 10A is an enlarged view of a cross section of the semiconductor device 100.

FIG. 10B is an enlarged view of a cross section of the semiconductor device 100.

FIG. 10C is an enlarged view of a cross section of the semiconductor device 100.

FIG. 10D is an enlarged view of a cross section of the semiconductor device 100.

FIG. 11A is an enlarged view of a cross section of the semiconductor device 100.

FIG. 11B is an enlarged view of a cross section of the semiconductor device 100.

FIG. 12A is an enlarged view of a cross section of the semiconductor device 100.

FIG. 12B is an enlarged view of a cross section of the semiconductor device 100.

FIG. 12C is an enlarged view of a cross section of the semiconductor device 100.

FIG. 12D is an enlarged view of a cross section of the semiconductor device 100.

FIG. 13 shows another example of a top view of the semiconductor device 100.

FIG. 14A is an enlarged view of a cross section of the semiconductor device 100.

FIG. 14B is an enlarged view of a cross section of the semiconductor device 100.

FIG. 15 shows another example of a top view of the semiconductor device 100.

FIG. 16A is an enlarged view of a cross section of the semiconductor device 100.

FIG. 16B is an enlarged view of a cross section of the semiconductor device 100.

FIG. 17 shows another example of a top view of the semiconductor device 100.

FIG. 18 shows another example of a top view of the semiconductor device 100.

FIG. 19 shows an example of a top view of a gate pad 112.

FIG. 20A shows an example of the cross section b-b′ in FIG. 19.

FIG. 20B shows an example of the cross section c-c′ in FIG. 19.

FIG. 21 shows another example of a top view of the gate pad 112.

FIG. 22A shows an example of the cross section f-f′ in FIG. 21.

FIG. 22B shows an example of cross section g-g′ in FIG. 21.

FIG. 22C shows an example of the cross section h-h′ in FIG. 21.

FIG. 23 shows another example of a top view of the semiconductor device 100.

FIG. 24A shows an example of cross section d-d′ from FIG. 23.

FIG. 24B shows an example of cross section e-e′ from FIG. 23.

FIG. 24C shows another example of the cross section d-d′ in FIG. 23.

FIG. 24D shows another example of the cross section e-e′ in FIG. 23.

FIG. 25 shows another example of a top view of the semiconductor device 100.

FIG. 26 shows another example of a top view of the semiconductor device 100.

FIG. 27 shows another example of a top view of the semiconductor device 100.

FIG. 28 shows another example of a top view of the semiconductor device 100.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When a Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a description of a P+ type or an N+ type means a higher doping concentration than that of the P type or the N type, and a description of a P− type or an N− type means a lower doping concentration than that of the P type or the N type.

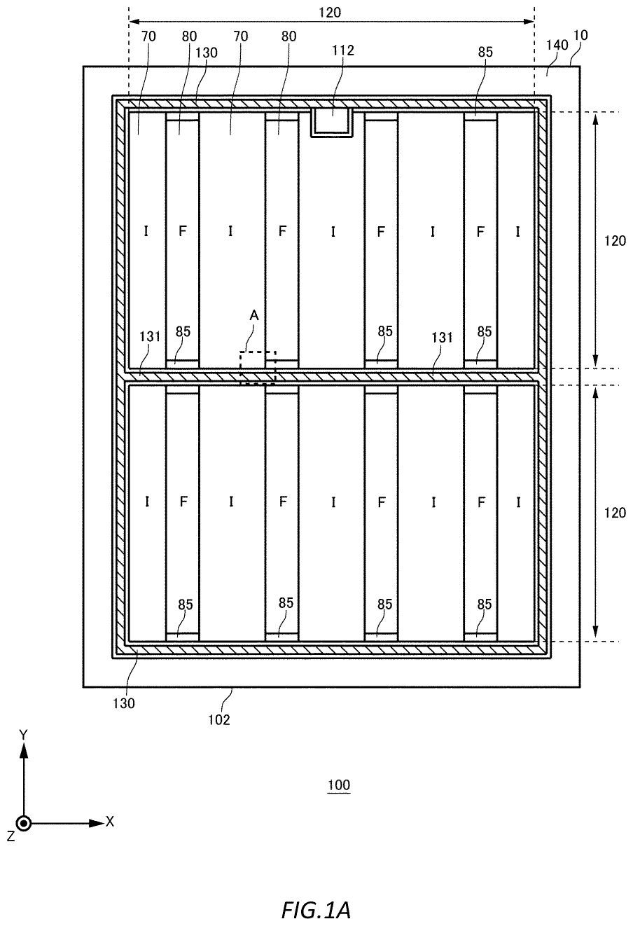

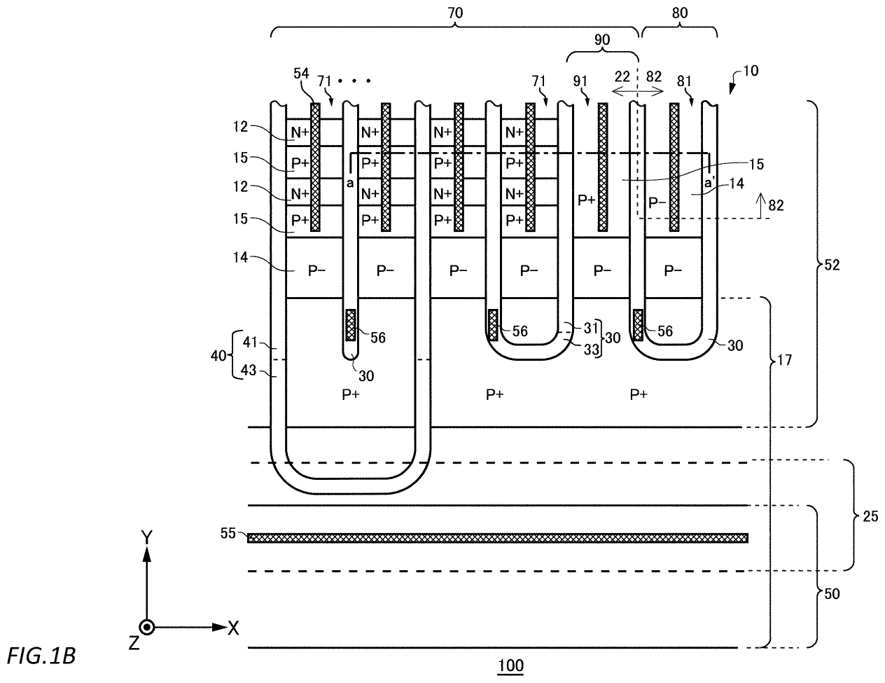

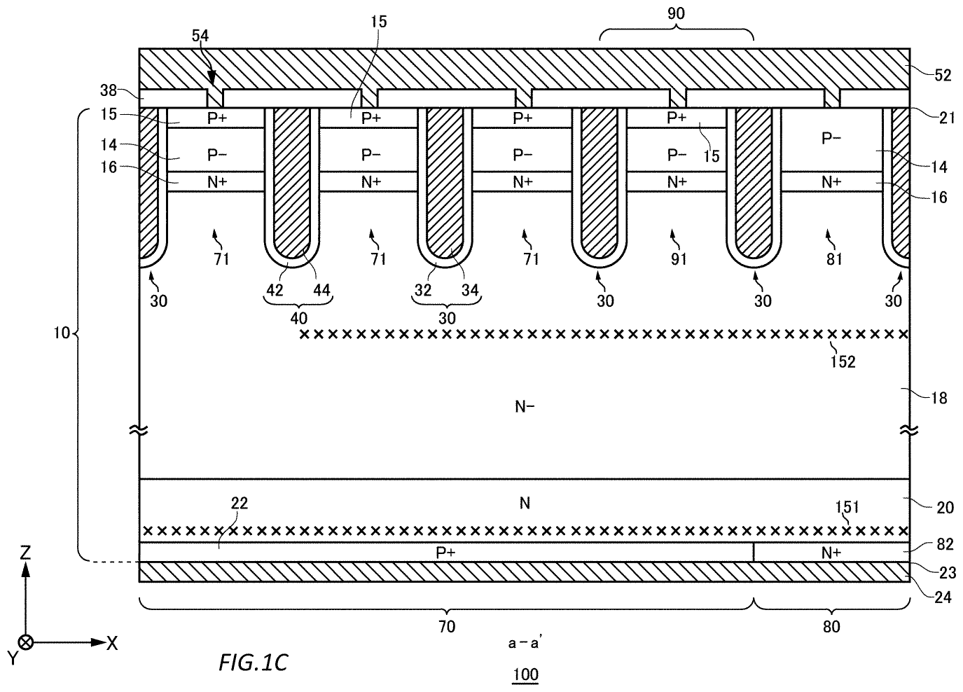

FIG. 1A shows an example of the top view of the semiconductor device 100. In the present example, only some members of the semiconductor device 100 are illustrated and some members are omitted.

A semiconductor substrate 10 has end sides 102 in a top view. The semiconductor substrate 10 in the present example includes two sets of end sides 102 facing each other in the top view. In the present example, the X axis and the Y axis are parallel to any of the end sides 102.

The semiconductor substrate 10 is provided with an active portion 120. The active portion 120 is a region where a main current flows in the depth direction between a front surface 21 and a back surface 23 of the semiconductor substrate 10 when the semiconductor device 100 operates. An emitter electrode 52 is provided above the active portion 120, but illustration thereof is omitted in the present figure.

In the active portion 120, a transistor portion 70 including a transistor element such as an IGBT, and a diode portion 80 including a diode element such as a freewheeling diode (FWD) are provided. In the example of FIG. 1A, transistor portions 70 and diode portions 80 are alternately arranged along a predetermined array direction (the X axis direction in the present example) at the front surface 21 of the semiconductor substrate 10.

In the present example, a region where the transistor portion 70 is arranged is denoted by a symbol “I”, and a region where the diode portion 80 is arranged is denoted by a symbol “F”. The transistor portion 70 and the diode portion 80 may each have a longitudinal length in an extending direction. That is, a length of the transistor portion 70 in the Y axis direction is greater than its width in the X axis direction. Similarly, a length of the diode portion 80 in the Y axis direction is greater than its width in the X axis direction. The extending directions of the transistor portion 70 and the diode portion 80, and a longitudinal direction of each trench portion described below may be the same.

The semiconductor device 100 may include one or more pads above the semiconductor substrate 10. The semiconductor device 100 of the present example has a gate pad 112. The semiconductor device 100 may include a pad such as an anode pad and a cathode pad. Each pad is arranged in the vicinity of the end side 102. The region near the end side 102 refers to a region between the end side 102 and the emitter electrode 52 in a top view. When the semiconductor device 100 is mounted, each pad may be connected to an external circuit via a wiring line such as a wire.

A gate potential is applied to the gate pad 112. The gate pad 112 is an example of the first upper electrode. The gate pad 112 is electrically connected to a gate conductive portion 44 of a gate trench portion 40 in the active portion 120. The semiconductor device 100 includes a gate runner that connects the gate pad 112 and the gate trench portion 40. In FIG. 1A, the gate runner is hatched with diagonal lines.

The gate runner of the present example has an outer circumferential gate runner 130 and an inter-active-portion gate runner 131. The gate runner may be composed of either a gate metal layer 50 or a connection portion 25, or a combination of both as appropriate. The outer circumferential gate runner 130 and the inter-active-portion gate runner 131 may have the same configuration or may have a different configuration. The outer circumferential gate runner 130 is arranged between the active portion 120 and the end side 102 of the semiconductor substrate 10 in a top view. The outer circumferential gate runner 130 of the present example surrounds the active portion 120 in the top view. A region surrounded by the outer circumferential gate runner 130 in the top view may be the active portion 120. Further, the outer circumferential gate runner 130 is connected to the gate pad 112. The outer circumferential gate runner 130 is arranged above the semiconductor substrate 10. The outer circumferential gate runner 130 may be composed of the gate metal layer 50 and the connection portion 25.

The inter-active-portion gate runner 131 is provided between a plurality of active portions 120. In FIG. 1A, two active portions 120 are arranged side by side in the Y axis direction. Providing the inter-active-portion gate runner 131 between the plurality of active portions 120 inside the semiconductor substrate 10 can reduce a variation in wiring length from the gate pad 112 for each region of the semiconductor substrate 10.

The inter-active-portion gate runner 131 is connected to the gate trench portion of the active portion 120. The inter-active-portion gate runner 131 is arranged above the semiconductor substrate 10. The inter-active-portion gate runner 131 of the present example is composed of the gate metal layer 50 and the connection portion 25. The gate metal layer 50 may be a metal layer including aluminum or the like.

The inter-active-portion gate runner 131 may be connected to the outer circumferential gate runner 130. The inter-active-portion gate runner 131 of the present example is provided extending in the X axis direction from one outer circumferential gate runner 130 to another outer circumferential gate runner 130 substantially at the center of the Y axis direction, so as to cross the active portion 120. When the active portion 120 is divided by the inter-active-portion gate runner 131, the transistor portion 70 and the diode portion 80 may be alternately arranged in the X axis direction in each divided region.

An edge termination structure portion 140 is provided on the front surface 21 of the semiconductor substrate 10. The edge termination structure portion 140 is provided between the active portion 120 and the end side 102 in a top view. The edge termination structure portion 140 in this example is arranged between the outer circumferential gate runner 130 and the end side 102. The edge termination structure portion 140 reduces electric field strength on the front surface 21 side of the semiconductor substrate 10. The edge termination structure portion 140 may include at least one of a guard ring, a field plate, or a RESURF which is annularly provided to enclose the active portion 120.

FIG. 1B shows an example of the top view of the semiconductor device 100. The semiconductor device 100 in the present example includes the transistor portion 70 and the diode portion 80. The present figure is an enlarged view of the upper surface of the region A in FIG. 1A.

The transistor portion 70 is a region obtained by projecting a collector region 22 provided on a back surface side of the semiconductor substrate 10 onto the upper surface of the semiconductor substrate 10. The collector region 22 will be described below. The transistor portion 70 includes a transistor such as an IGBT. In the present example, the transistor portion 70 is an IGBT. Note that the transistor portion 70 may be another transistor such as a MOSFET.

The diode portion 80 is a region obtained by projecting a cathode region 82 provided on a back surface 23 side of the semiconductor substrate 10 onto an upper surface of the semiconductor substrate 10. The cathode region 82 will be described later. On the back surface 23 of the semiconductor substrate 10, the collector region 22 of the P+ type may be provided in a region other than the cathode region 82. In the specification, the diode portion 80 may also include an extension region 85 where the diode portion 80 extends to a gate runner described below in the Y axis direction. On the back surface 23 of the extension region 85, the collector region 22 may be provided.

The present figure shows a region around an active portion of the semiconductor device 100 and other regions are omitted. For example, an edge termination structure portion may be provided in a region on a negative side in the Y axis direction in the semiconductor device 100 in the present example. The edge termination structure portion reduces electric field strength on an upper surface side of the semiconductor substrate 10. For example, the edge termination structure portion has a structure of a guard ring, a field plate, a RESURF, and a combination thereof. Note that although the present example describes an edge on the negative side in the Y axis direction for convenience, the same applies to other edges of the semiconductor device 100.

The semiconductor substrate 10 is a substrate which is formed of a semiconductor material. The semiconductor substrate 10 may be a silicon substrate, may be a silicon carbide substrate, may be a gallium nitride substrate, may be a diamond substrate, or may be other kinds of substrate. The semiconductor substrate 10 in the present example is the silicon substrate. Note that when simply referred to as a top view in the present specification, it means that the semiconductor substrate 10 is viewed from an upper surface side. As will be described below, the semiconductor substrate 10 includes the front surface 21 and the back surface 23.

The semiconductor device 100 in the present example includes a gate trench portion 40, a dummy trench portion 30, an emitter region 12, a base region 14, a contact region 15, and a well region 17 at the front surface 21 of the semiconductor substrate 10. In addition, the semiconductor device 100 in the present example includes an emitter electrode 52 and a gate metal layer 50 which are provided above the front surface 21 of the semiconductor substrate 10. Each of the emitter electrode 52 and the gate metal layer 50 is an example of the first upper electrode. The gate trench portion 40 is an example of the MOS gate structure provided in the semiconductor device 100. It is to be noted that although the semiconductor device 100 in the present example is a transistor including the MOS gate structure, the semiconductor device 100 may alternatively be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). A barrier metal layer formed of titanium, a titanium compound, or the like may be provided under the emitter electrode 52 and the gate metal layer 50 formed of aluminum and the like. The barrier metal layer will be described below. The emitter electrode 52 and the gate metal layer 50 are provided separated from each other.

The emitter electrode 52 and the gate metal layer 50 are provided above the semiconductor substrate 10 with an interlayer dielectric film 38 interposed therebetween. The interlayer dielectric film 38 is omitted in FIG. 1B. A contact hole 54, a contact hole 55, and a contact hole 56 are provided to penetrate the interlayer dielectric film 38.

The contact hole 55 electrically connects the gate metal layer 50 and a gate conductive portion in the transistor portion 70 to each other via the connection portion 25. A plug layer formed of tungsten or the like may be formed inside the contact hole 55. The plug layer will be described later.

The contact hole 56 connects the emitter electrode 52 with a dummy conductive portion within the dummy trench portion 30. A plug layer formed of tungsten or the like may be formed inside the contact hole 56.

The connection portion 25 is connected to a front surface side metal layer such as the emitter electrode 52 or the gate metal layer 50. In an example, the connection portion 25 is provided between the gate metal layer 50 and the gate conductive portion. The connection portion 25 in the present example may be provided to extend in the X axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is a conductive material such as polysilicon doped with impurities. The connection portion 25 in the present example is polysilicon (N+) doped with impurities of the N type. The connection portion 25 is provided above the front surface 21 of the semiconductor substrate 10 via a dielectric film such as an oxide film, or the like.

The gate trench portions 40 are examples of a plurality of trench portions extending in a predetermined extending direction on a front surface 21 side of the semiconductor substrate 10. The gate trench portions 40 are arrayed at a predetermined interval along a predetermined array direction (the X axis direction in the present example). The gate trench portion 40 in the present example may include two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 is preferably formed in a curved shape. Connecting end portions of the two extending parts 41 of the gate trench portion 40 can reduce electric field strength at the end portions of the extending parts 41. In the connecting part 43 of the gate trench portion 40, the gate metal layer 50 may be electrically connected to the gate conductive portion via the connection portion 25.

The dummy trench portions 30 are examples of a plurality of trench portions extending in a predetermined extending direction on the front surface 21 side of the semiconductor substrate 10. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). Although the dummy trench portion 30 in the present example has an I shape at the front surface 21 of the semiconductor substrate 10, the dummy trench portion 30 may have a U shape at the front surface 21 of the semiconductor substrate 10, similarly to the gate trench portion 40. That is, the dummy trench portion 30 may have two extending parts 31 which extend along the extending direction and a connecting part 33 which connects the two extending parts 31.

The transistor portion 70 in the present example has a structure in which two gate trench portions 40 and two dummy trench portions 30 are repeatedly arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It is to be noted that the ratio between the gate trench portions 40 and the dummy trench portions 30 is not limited to that in the present example. A ratio of the gate trench portions 40 may be greater than a ratio of the dummy trench portions 30, or the ratio of the dummy trench portions 30 may be greater than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of a second conductivity type which is provided on a front surface 21 side of the semiconductor substrate 10 relative to a drift region 18 as described below. The well region 17 is an example of a well region provided on a peripheral side of an active portion 120. The active portion 120 will be described below. The well region 17 is of the P+ type as an example. The well region 17 is formed within a predetermined range from an end portion of an active region on a side where the gate metal layer 50 is provided. A diffusion depth of the well region 17 may be deeper than a depth of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in an extending direction.

A mesa portion 71 is a mesa portion provided adjacent to the trench portion in a plane parallel to the front surface 21 of the semiconductor substrate 10. The mesa portion may be a part of the semiconductor substrate 10 sandwiched between two trench portions adjacent to each other, and may be a part from the front surface 21 of the semiconductor substrate 10 to a depth of a lowermost bottom portion of each trench portion. The extending part of each trench portion may be defined as one trench portion. That is, a region sandwiched between two extending parts may be defined as a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter regions 12 and the contact regions 15 are alternately provided in an extending direction.

The base region 14 is a region of the second conductivity type which is provided on the front surface 21 side of the semiconductor substrate 10. The base region 14 is of the P− type as an example. The base regions 14 may be provided at both end portions of the mesa portion 71 in the Y axis direction at the front surface 21 of the semiconductor substrate 10. Note that FIG. 1B shows only one end of the base region 14 in the Y axis direction.

The emitter region 12 is a region of a first conductivity type which has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+ type as an example. The contact region 15 in the present example is provided at the front surface 21 in the mesa portion 71. The contact region 15 may be provided in the X axis direction from one to another of the two trench portions sandwiching the mesa portion 71. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54.

The semiconductor device 100 in the present example includes the emitter electrode 52 and the gate metal layer 50 which are provided above the front surface 21 of the semiconductor substrate 10. The emitter electrode 52 and the gate metal layer 50 are provided separated from each other. The transistor portion 70 in the present example includes a boundary portion 90 that is positioned at a boundary between the transistor portion 70 and the diode portion 80. It is to be noted that the semiconductor device 100 may not include the boundary portion 90.

The boundary portion 90 is a region provided in the transistor portion 70 and in direct contact with the diode portion 80. The boundary portion 90 includes the contact region 15 at the front surface 21 of the semiconductor substrate 10. The boundary portion 90 in the present example does not have an emitter region 12. In an example, trench portions in the boundary portion 90 are dummy trench portions 30. The boundary portion 90 in the present example is arranged such that the dummy trench portions 30 are located at its both ends in the X axis direction.

A contact hole 54 is provided above the base region 14 in the diode portion 80. The contact hole 54 is provided above the contact region 15 in the boundary portion 90. No contact holes 54 are provided above the well regions 17 provided at both ends in the Y axis direction.

A mesa portion 91 is provided in the boundary portion 90. The mesa portion 91 has a contact region 15 at the front surface 21 of the semiconductor substrate 10. The mesa portion 91 of the present example has the base region 14 and the well region 17 on the negative side of the Y axis direction.

A mesa portion 81 is provided in a region sandwiched between adjacent dummy trench portions 30 in the diode portion 80. The mesa portion 81 includes the base region 14 at the front surface 21 of the semiconductor substrate 10. The mesa portion 81 in the present example includes the well region 17 on a negative side in the Y axis direction.

The emitter region 12 is provided in a mesa portion 71, but may not be provided in the mesa portion 81 and the mesa portion 91. The contact region 15 is provided in the mesa portion 71 and the mesa portion 91, but may not be provided in the mesa portion 81.

FIG. 1C shows an example of the cross section a-a′ in FIG. 1B. The cross section a-a′ is an X-Z cross section passing through the contact region 15 in the transistor portion 70. The semiconductor device 100 in the present example includes the semiconductor substrate 10, the interlayer dielectric film 38, the emitter electrode 52, and a collector electrode 24 in the cross section a-a′. The collector electrode 24 is an example of a back surface side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 of the present example is of the N− type, as an example. The drift region 18 may be a region in the semiconductor substrate 10 which has remained without other doping regions formed. That is, a doping concentration of the drift region 18 may be a doping concentration of the semiconductor substrate 10.

The buffer region 20 is a region of the first conductivity type which is provided on the back surface 23 side of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. Note that the buffer region 20 may be omitted.

The collector region 22 is provided below the buffer region 20 in the transistor portion 70. The collector region 22 is of the second conductivity type. The collector region 22 in the present example is of the P+ type as an example.

The collector electrode 24 is formed on the back surface 23 of the semiconductor substrate 10. The collector electrode 24 is formed of a conductive material such as metal. The material of the collector electrode 24 may be a same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The contact region 15 is provided above the base region 14 in the mesa portion 91. The contact region 15 is provided in contact with the dummy trench portion 30 in the mesa portion 91. In another cross section, the emitter region 12 is provided above the base region 14. The emitter region 12 is provided between the base region 14 and the front surface 21. The emitter region 12 is provided in contact with the gate trench portion 40. The emitter region 12 may or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type, as an example. It is to be noted that the accumulation region 16 may not be provided.

The accumulation region 16 is provided in contact with the gate trench portion 40. The accumulation region 16 may or may not be in contact with the dummy trench portion 30. A doping concentration of the accumulation region 16 is higher than the doping concentration of the drift region 18. An ion implantation dose amount of the accumulation region 16 may be 1.0E+12 cm⁻² or more and 1.0E+13 cm⁻² or less. In addition, the ion implantation dose amount of the accumulation region 16 may be 3.0E+12 cm⁻² or more and 6.0E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided on the front surface 21. Each trench portion is provided from the front surface 21 to the drift region 18. In a region provided with at least one of the emitter region 12, the base region 14, the contact region 15, or the accumulation region 16, each trench portion also penetrates these regions to reach the drift region 18. A structure in which the trench portion passes through the doping region is not limited to a structure which is made by forming the doping region and then forming the trench portion in order. The configuration of the trench portion penetrating the doping region includes a configuration of the doping region being formed between the trench portions after forming the trench portion.

The gate trench portion 40 includes a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside the gate dielectric film 42 within the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel with an electron inversion layer is formed in a surface layer of an interface of the base region 14 which is in contact with the gate trench.

The dummy trench portion 30 may have the same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed within the dummy trench, and is formed inside the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and contact holes 56 may be provided penetrating the interlayer dielectric film 38. A film thickness of the interlayer dielectric film 38 is, for example, 1.0 μm, but is not limited thereto.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may also include a high temperature silicon oxide (HTO: High Temperature Oxide) film.

The semiconductor device 100 of the present example comprises a back surface side lifetime control region 151 and a front surface side lifetime control region 152. It should be noted that the semiconductor device 100 may not include one of the back surface side lifetime control region 151 or the front surface side lifetime control region 152.

A back surface side lifetime control region 151 may be provided in the transistor portion 70. It should be noted that the back surface side lifetime control region 151 may be omitted. The back surface side lifetime control region 151 is a region where a lifetime killer has intentionally been formed by implanting an impurity inside the semiconductor substrate 10, or the like. As an example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The front surface side lifetime control region 152 is provided closer to the front surface 21 side with respect to the center of the semiconductor substrate 10 in the depth direction of the semiconductor substrate 10. The front surface side lifetime control region 152 in the present example is provided in a drift region 18. The front surface side lifetime control region 152 is provided in both the transistor portion 70 and the diode portion 80. The front surface side lifetime control region 152 may be provided in the diode portion 80 and the boundary portion 90 and may not be provided in a part of the transistor portion 70. The front surface side lifetime control region 152 can suppress the implantation of holes from the diode portion 80 and the transistor portion 70 to reduce a reverse recovery loss.

The front surface side lifetime control region 152 may be formed with any of the methods for forming the back surface side lifetime control region 151. The element, the dose amount, and the like for forming the back surface side lifetime control region 151 may be the same as or different from those for forming the front surface side lifetime control region 152.

The front surface side lifetime control region 152 is provided extending from the diode portion 80 to the transistor portion 70. The front surface side lifetime control region 152 may be formed by an irradiation from the front surface 21 of the semiconductor substrate 10. The front surface side lifetime control region 152 may alternatively be formed by an irradiation from the back surface 23 side of the semiconductor substrate 10. The front surface side lifetime control region 152 in the present example is provided below the gate trench portion 40. Due to particle beams or the like for forming the front surface side lifetime control region 152 passing through a MOS gate structure of the semiconductor device 100, a defect may be generated at an interface between the gate oxide film and the semiconductor substrate.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. In addition, the lifetime killer concentration may be a chemical concentration of the noble gas element such as helium and neon, or may be a chemical concentration of the metal element such as platinum.

The back surface side lifetime control region 151 is provided closer to the back surface 23 side than the center of the semiconductor substrate 10 in the depth direction of the semiconductor substrate 10. The back surface side lifetime control region 151 of the present example is provided in the buffer region 20. The back surface side lifetime control region 151 of the present example is provided on an entire surface of the semiconductor substrate 10 in the XY plane, and can be formed without using a mask. The back surface side lifetime control region 151 may be provided in a part of the semiconductor substrate 10 in the XY plane. An impurity dose amount for forming the back surface side lifetime control region 151 may be 0.5 E+10 cm⁻² or more and 1.0 E+14 cm⁻² or less, or may be 5.0 E+10 cm⁻² or more and 1.0 E+13 cm⁻² or less.

The back surface side lifetime control region 151 may be formed by an implantation from the back surface 23 side. Accordingly, it becomes easy to avoid an effect on the front surface 21 side of the semiconductor device 100. For example, the back surface side lifetime control region 151 is formed by irradiating helium or a proton from the back surface 23 side. Herein, which of the front surface 21 side and the back surface 23 side the implantation is performed from for forming the back surface side lifetime control region 151 can be determined by acquiring a state of the front surface 21 side by an SRP method or a measurement of a leakage current.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary portion 90 in the present example.

The semiconductor device 100 may be a power semiconductor device for controlling electrical power, and the like. The semiconductor device 100 in the present example may have a vertical semiconductor structure in which a back surface side metal layer is provided on the back surface 23 side of the semiconductor substrate 10. It should be noted that, the semiconductor device 100 may have a horizontal semiconductor structure in which no metal layer is provided on the back surface 23 side.

It is to be noted that, in the present example, an RC-IGBT having a trench gate structure is described as an example of the semiconductor device 100. It should be noted that the semiconductor device 100 may be a semiconductor device having a planar gate structure, or may be other semiconductor devices such as a diode. The semiconductor device 100 may include a MOSFET of an N channel, or may include a MOSFET of a P channel.

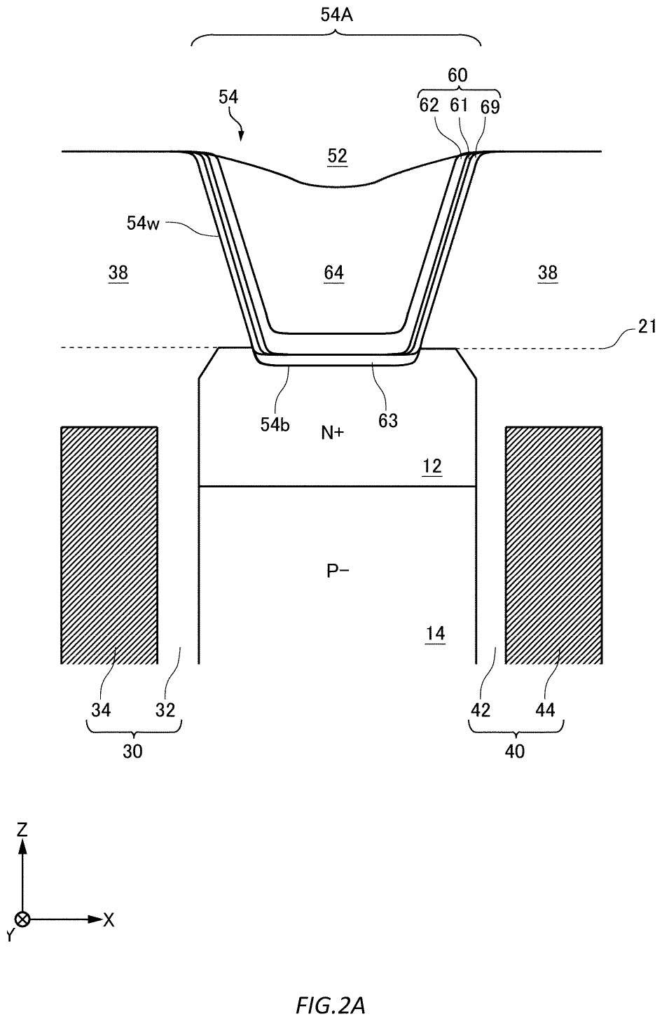

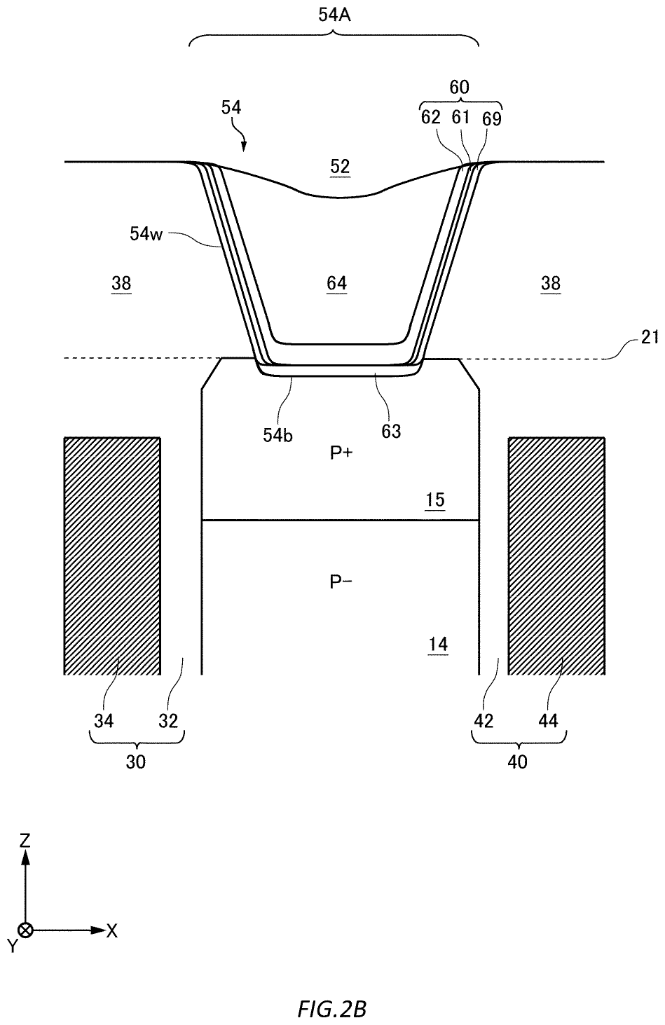

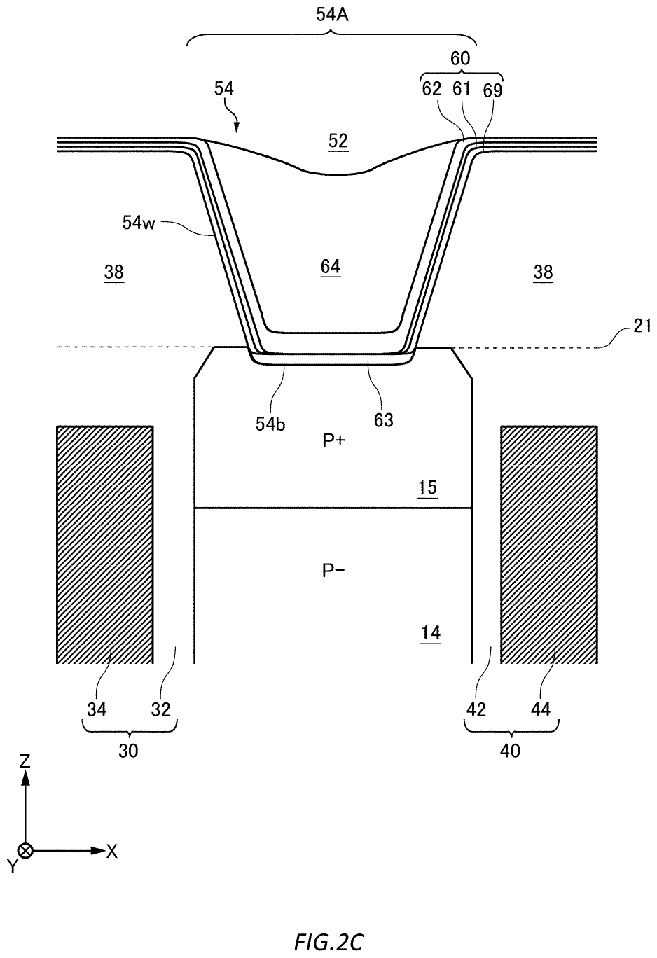

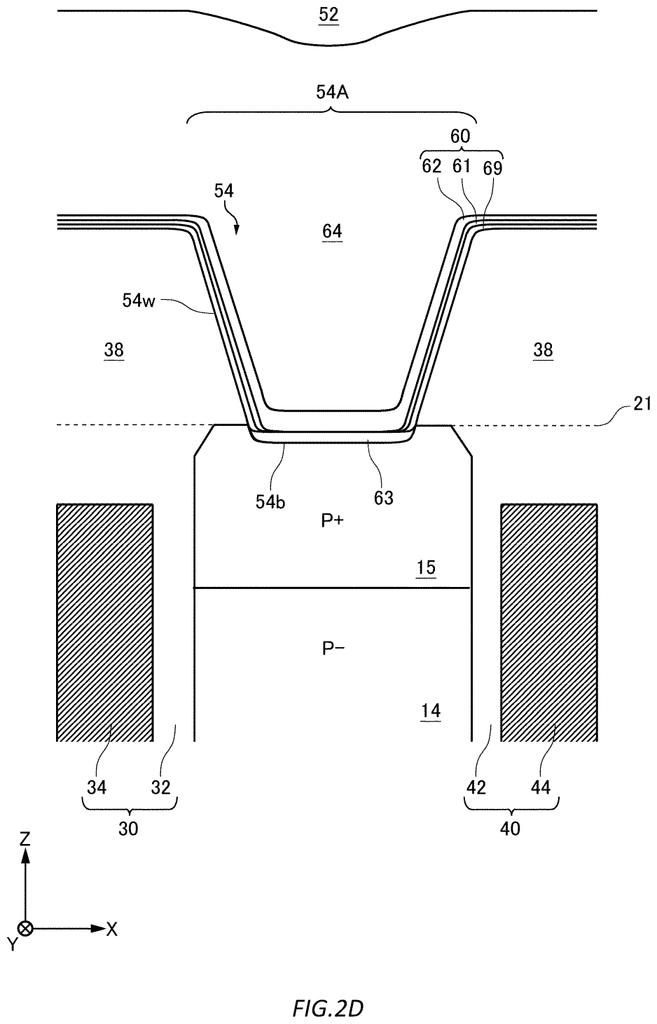

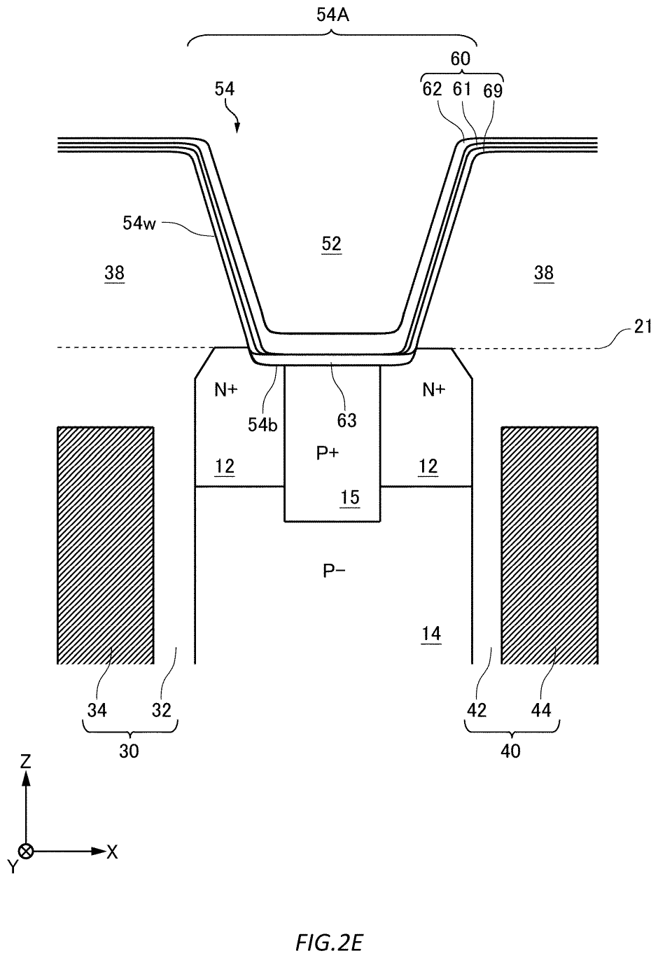

FIG. 2A is an enlarged view of a cross section of the semiconductor device 100. FIG. 2B is an enlarged view of a cross section of the semiconductor device 100. The cross section in FIG. 2A is an X-Z cross section passing through the emitter region 12 on the front surface 21 of the semiconductor substrate 10, and the cross section in FIG. 2B is an X-Z cross section passing through the contact region 15 on the front surface 21. In the present example, an enlarged view of a cross section near the first contact portion 54A is shown. The first contact portion 54A is electrically connected to the emitter electrode 52 via the contact hole 54. The first contact portion 54A comprises a contact hole 54, a first barrier metal layer 60, a first alloy layer 63, and a plug layer 64.

Note that, in the present specification, by using the contact hole 54, structures of the first contact portion 54A and a second contact portion 54B described below may be described, but similar structures may also be applied to another contact hole, such as the contact hole 55 and the contact hole 56. Also, in the present specification, for convenience, an inner wall among the inner walls of the contact hole 54, which is upper than the front surface 21 of the semiconductor substrate 10 is described as a side wall 54w, and an inner wall among the inner walls of the contact hole 54, which is lower than the front surface 21 of the semiconductor substrate 10 is described as a bottom surface 54b.

In the contact hole 54, the first barrier metal layer 60 is provided above the first alloy layer 63. The first barrier metal layer 60 may be provided to be in contact with the upper surface of the interlayer dielectric film 38. The first barrier metal layer 60 includes a nitride of a first metal of a predetermined conductivity. The first barrier metal layer 60 of the present example is provided, in the contact hole 54, on a side wall of the upper surface of an oxide layer 66 and the interlayer dielectric film 38, and has a metal film 69, a lower layer barrier metal portion 61, and an upper layer barrier metal portion 62. However, the first barrier metal layer 60 may not have the metal film 69 or the lower layer barrier metal portion 61.

The metal film 69 is provided on the side wall 54w of the contact hole 54. The metal film 69 includes a first metal of a predetermined conductivity. The first metal may be at least one of titanium (Ti), cobalt (Co), nickel (Ni), tantalum (Ta), magnesium (Mg), vanadium (V), lanthanum (La), palladium (Pd), or zirconium (Zr). The first metal may be a metal that has a hydrogen absorbing effect. For example, the first metal is titanium (Ti). The metal film 69 is a Ti film deposited by sputtering. The metal film 69 may be deposited above the interlayer dielectric film 38.

The first alloy layer 63 is provided on the bottom surface 54b of the contact hole 54. The first alloy layer 63 of the present example is provided on the upper surface of the semiconductor substrate 10. The first alloy layer 63 is formed by annealing the metal film 69 including the first metal. The first alloy layer 63 may be an alloy formed of the first metal and a constituent element of a layer on the bottom surface of the contact hole 54. As an example, when the semiconductor substrate 10 is a silicon substrate, the first alloy layer 63 may be a silicide layer. As another example, when the semiconductor substrate 10 is a silicon carbide substrate, a gallium nitride substrate, a diamond substrate, or the like, the first alloy layer 63 may be an alloy layer including these substrate materials and the first metal. The first alloy layer 63 of the present example is a titanium silicide layer formed by annealing a metal film 69 that is deposited on the bottom surface 54b of the contact hole 54 as an initial metal film. Note that a doping region including the emitter region 12 and the contact region 15 may be formed such that a high concentration of an N type impurity or a P type impurity at a place in contact with the first alloy layer 63 (not shown), to reduce the contact resistance.

The lower layer barrier metal portion 61 is provided on the metal film 69 in the contact hole 54. The lower layer barrier metal portion 61 includes a nitride of a first metal of a predetermined conductivity. For example, the lower layer barrier metal portion 61 is TiN. The lower layer barrier metal portion 61 is formed by annealing the metal film 69 including the first metal. The lower layer barrier metal portion 61 of the present example is TiN formed by annealing a metal film 69 deposited on the side wall of the contact hole 54 as an initial metal film in a nitrogen atmosphere. Note that all of the metal films 69 may be changed into the lower layer barrier metal portion 61 upon annealing. Alternatively, the lower layer barrier metal portion 61 may not be formed even if the annealing is performed.

The lower layer barrier metal portion 61 and the first alloy layer 63 may be formed by the same annealing process. For example, by using the metal film 69 deposited on the inner wall of the contact hole 54, a lower layer barrier metal portion 61 of TiN is formed on the side wall 54w of the contact hole 54, and a first alloy layer 63 of titanium silicide is formed on the bottom surface 54b of the contact hole 54. Note that after the annealing, the metal film 69 may remain on the upper surface of the first alloy layer 63, or the lower layer barrier metal portion 61 may be formed on the upper surface of the first alloy layer 63 (or the metal film 69 remaining on the upper surface of the first alloy layer 63).

The upper layer barrier metal portion 62 is stacked on the lower layer barrier metal portion 61 in the contact hole 54. The upper layer barrier metal portion 62 includes a conductive material. For example, the upper layer barrier metal portion 62 is TiN. The upper layer barrier metal portion 62 is provided by stacking on the first alloy layer 63 that is provided on the bottom surface 54b of the contact hole 54. That is, the upper layer barrier metal portion 62 is provided in contact with the upper surface of the first alloy layer 63. The upper layer barrier metal portion 62 may be formed by sputtering a conductive material. The upper layer barrier metal portion 62 of the present example is TiN formed by sputtering. Alternatively, if the lower layer barrier metal portion 61 is not formed even if the annealing was performed, the upper layer barrier metal portion 62 may be stacked on the metal film 69.

The plug layer 64 is provided above the first barrier metal layer 60 in the contact hole 54. The plug layer 64 may be provided in contact with the upper layer barrier metal portion 62 in the contact hole 54. The plug layer 64 is a conductive material that is filled inside the contact hole 54. The plug layer 64 may be a material different from that of the emitter electrode 52. For example, the material of the plug layer 64 is tungsten. Note that also outside of the contact hole 54, the plug layer 64 may be provided above the interlayer dielectric film 38 in contact with the upper layer barrier metal portion 62. The plug layer 64 may be omitted, and the emitter electrode 52 may be filled inside the contact hole 54.

The interlayer dielectric film 38 includes the contact hole 54 and is provided above the semiconductor substrate 10. Although the interlayer dielectric film 38 includes one layer of a dielectric film provided above the front surface 21, the interlayer dielectric film 38 may alternatively include a plurality of stacked dielectric films. The interlayer dielectric film 38 may be a silicon oxide film such as BPSG.

The lower layer barrier metal portion 61 is denser than that of the upper layer barrier metal portion 62. The lower layer barrier metal portion 61 and the upper layer barrier metal portion 62 may be formed by different deposition methods. The lower layer barrier metal portion 61 may be a TiN film formed by annealing of Ti deposited on the side wall of the interlayer dielectric film 38. The upper layer barrier metal portion 62 may be a TiN film formed by sputtering of TiN. Thereby, the lower layer barrier metal portion 61 may be a TiN film denser than the upper layer barrier metal portion 62. The lower layer barrier metal portion 61 and the upper layer barrier metal portion 62 may include the same material.

Since the upper layer barrier metal portion 62 formed by sputtering does not require the initial metal film to be formed thereon, and can thereby avoid being affected by the hydrogen absorbing effect due to remaining Ti or the like. However, since the upper layer barrier metal portion 62 is not a dense film like the lower layer barrier metal portion 61, the plug layer 64 may penetrate into the upper layer barrier metal portion 62 upon forming the plug layer 64. However, by forming the lower layer barrier metal portion 61 densely, the interlayer dielectric film 38 can be protected from damage upon deposition of the plug layer 64.

The film thickness of the lower layer barrier metal portion 61 may be thinner than the film thickness of the upper layer barrier metal portion 62. The film thickness of the lower layer barrier metal portion 61 may be thinner than the film thickness of the first alloy layer 63.

The lower layer barrier metal portion 61 may cover the side wall 54w of the contact hole 54. The lower end of the lower layer barrier metal portion 61 may be in contact with the first alloy layer 63. That is, the bottom surface 54b and the side wall 54w of the contact hole 54 may be covered by the first alloy layer 63 and the metal film 69, respectively.

The opening width of the contact hole 54 is the width of the contact hole 54 in the trench array direction on the upper surface of the interlayer dielectric film 38. The opening width of the contact hole 54 may be 100 nm or more and 1000 nm or less.

FIG. 2C is an enlarged view of a cross section of the semiconductor device 100. The cross section in FIG. 2C is an X-Z cross section passing through the contact region 15 on the front surface 21 of the semiconductor substrate 10. In the present example, an enlarged view of a cross section near the first contact portion 54A according to the modification example is shown. The first contact portion 54A of the present example is different from the first contact portion 54A shown in FIG. 2A and FIG. 2B in that the first barrier metal layer 60 is provided outside the contact hole 54 and above the interlayer dielectric film 38. Another structure may be any configuration shown in the present specification. Note that the illustration of the X-Z cross section that passes through the emitter region 12 on the front surface 21 of the semiconductor substrate 10 is omitted since it is common to that of the X-Z cross section of FIG. 2C, except that the emitter region 12 is provided instead of the contact region 15 of FIG. 2C.

The first barrier metal layer 60 may be provided outside the contact hole 54 to be in contact with the upper surface of the interlayer dielectric film 38. By forming the first barrier metal layer 60 also on the interlayer dielectric film 38, the reliability, such as wire bond and resin sealing, in implementation can be improved. Also, the first barrier metal layer 60 may not have the lower layer barrier metal portion 61 and the metal film 69 in either the outside or the inside of the contact hole 54. As an example, the first barrier metal layer 60 may only have the upper layer barrier metal portion 62 provided the inside and the outside of the contact hole 54.

FIG. 2D is an enlarged view of a cross section of the semiconductor device 100. The cross section in FIG. 2D is an X-Z cross section passing through the contact region 15 on the front surface 21 of the semiconductor substrate 10. In the present example, an enlarged view of a cross section near the first contact portion 54A according to a further modification example is shown. The first contact portion 54A of the present example is different from the first contact portion 54A shown in FIG. 2C in that the plug layer 64 is provided outside the contact hole 54 and above the interlayer dielectric film 38. Another structure may be any configuration shown in the present specification. Note that the illustration of the X-Z cross section that passes through the emitter region 12 on the front surface 21 of the semiconductor substrate 10 is omitted since it is common to that of the X-Z cross section of FIG. 2D, except that the emitter region 12 is provided instead of the contact region 15 of FIG. 2D.

The plug layer 64 may be provided outside the contact hole 54 to be in contact with the upper surface of the first barrier metal layer 60. By forming the plug layer 64 also on the interlayer dielectric film 38, the reliability, such as wire bond and resin sealing, in implementation can be improved.

FIG. 2E is an enlarged view of a cross section of the semiconductor device 100. The cross section in FIG. 2E is an X-Z cross section passing through the contact region 15 on the front surface 21 of the semiconductor substrate 10. In the present example, a structure in which the contact region 15 is positioned at the center of the mesa portion, and the emitter region 12 is provided to be in contact with the trench portion is described as an example. The first contact portion 54A of the present example is different from the first contact portion 54A of FIG. 2A and FIG. 2B in that the first barrier metal layer 60 is provided outside the contact hole 54 and above the interlayer dielectric film 38, and in that an emitter electrode 52 is provided in the contact hole 54 instead of the plug layer 64. The emitter electrode 52 is connected to the front surface 21 of the semiconductor substrate 10 via the contact hole 54.

Even if there is no plug layer 64, by forming the first barrier metal layer 60 also on the interlayer dielectric film 38, the reliability in implementation, such as resin sealing, can be improved. Note that the emitter region 12 is positioned on both sides of the contact region 15 in FIG. 2E, but it may be positioned at only one side. Even in a structure in which the contact region 15 and the emitter region 12 described in FIG. 2A to FIG. 2D are alternately arranged along the trench portion, as in the present example, the first barrier metal layer 60 may be provided in the outside of contact hole 54 above the interlayer dielectric film 38, and the emitter electrode 52 may be provided in the contact hole 54 instead of the plug layer 64. Also, a structure in which the first barrier metal layer 60, the emitter electrode 52, and the plug layer 64 described in FIG. 2A to 2D may be applied even in a structure in which the contact region 15 and the emitter region 12 shown in the present example appear simultaneously in the cross section of the trench portion.

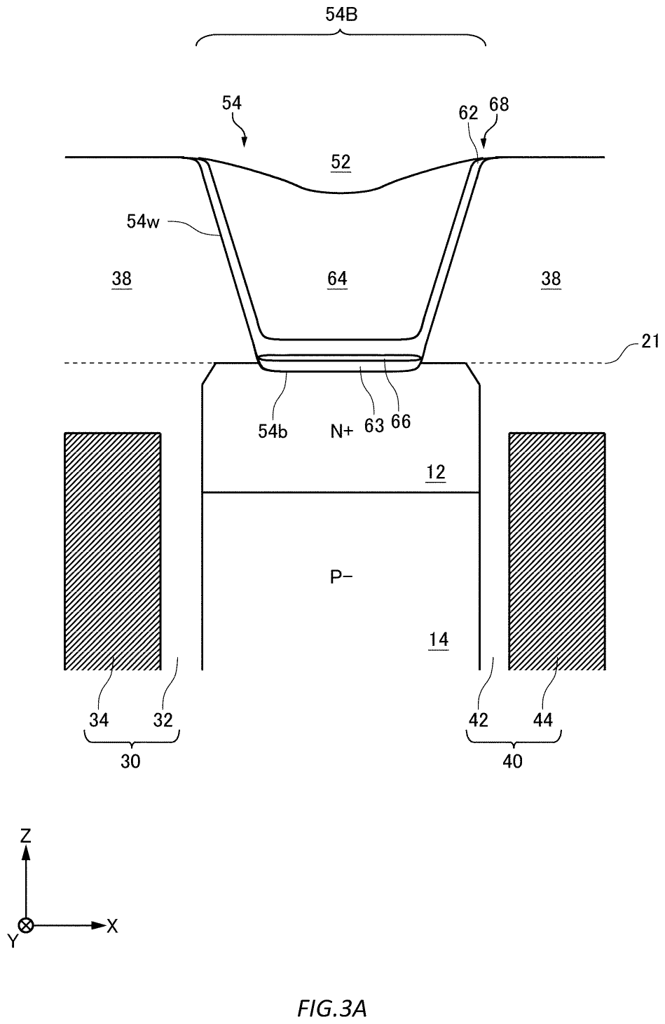

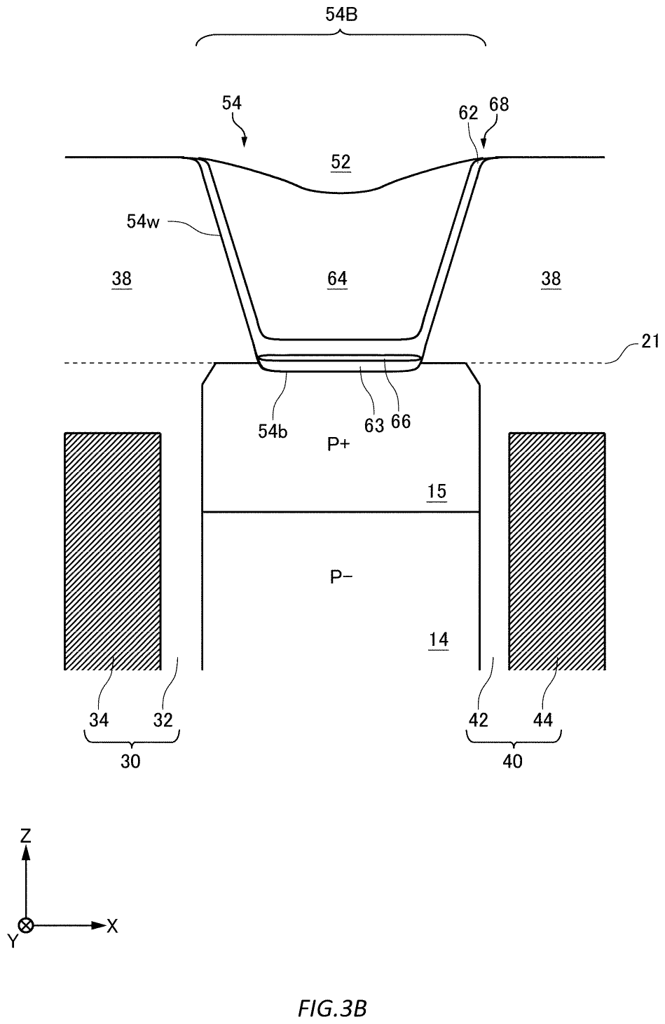

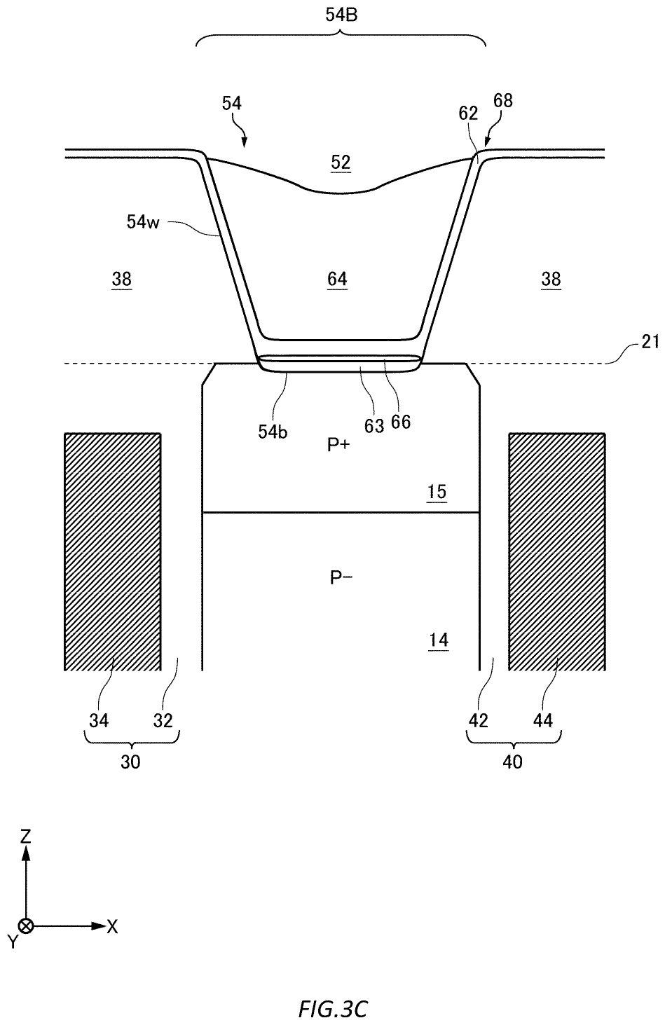

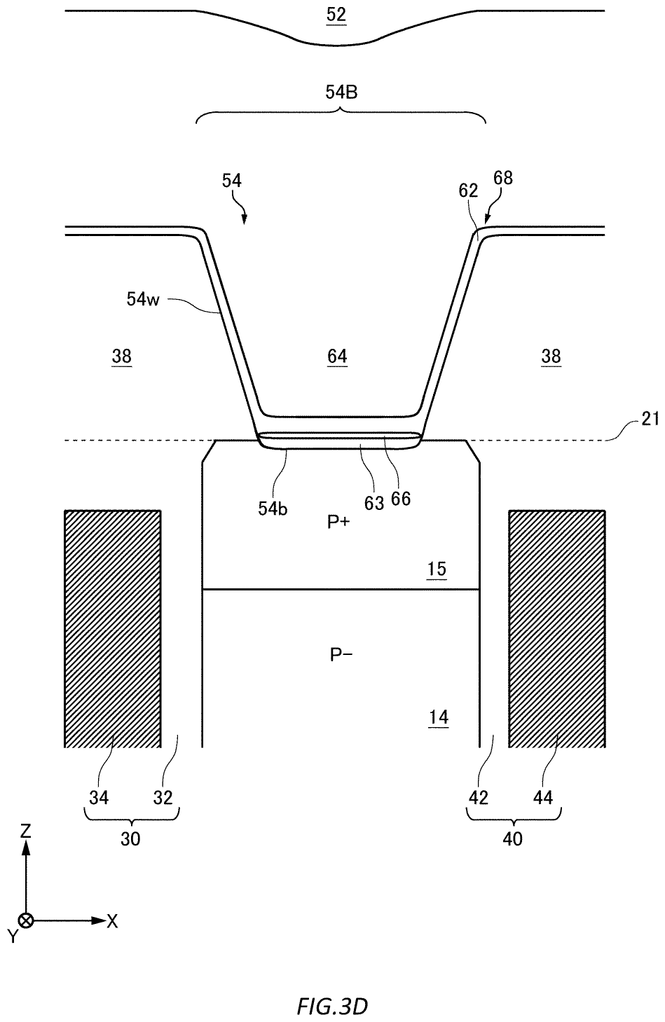

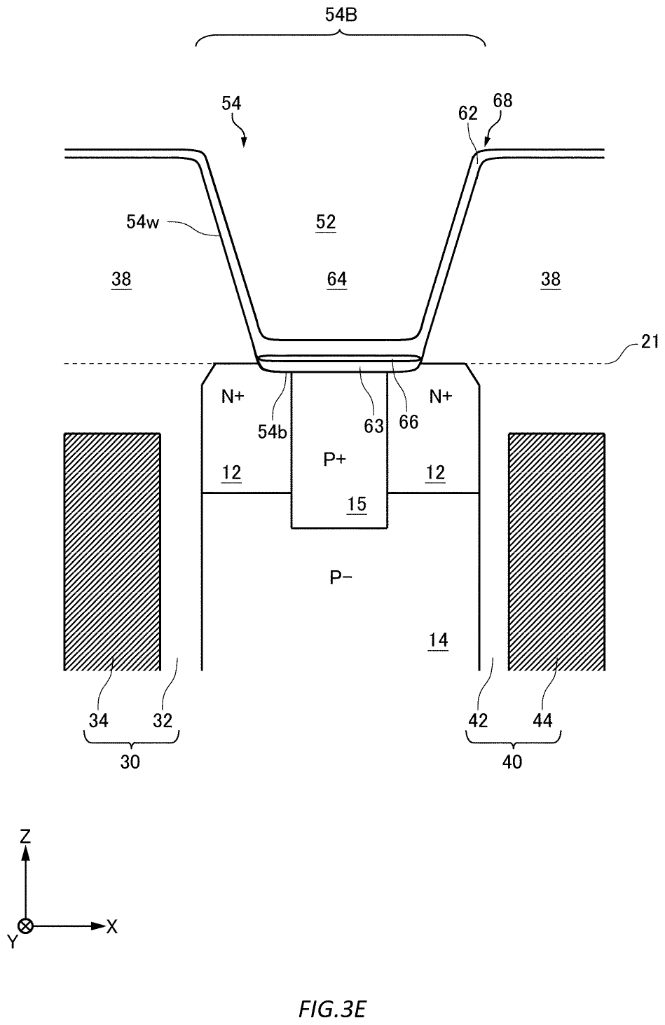

FIG. 3A is an enlarged view of a cross section of the semiconductor device 100. FIG. 3B is an enlarged view of a cross section of the semiconductor device 100. The cross section in FIG. 3A is an X-Z cross section passing through the emitter region 12 on the front surface 21 of the semiconductor substrate 10, and the cross section in FIG. 3B is an X-Z cross section passing through the contact region 15 on the front surface 21. In the present example, an enlarged view of a cross section near the second contact portion 54B is shown. The second contact portion 54B is electrically connected to the emitter electrode 52 via the contact hole 54. The second contact portion 54B comprises a contact hole 54, a second barrier metal layer 68, a first alloy layer 63, a plug layer 64, and an oxide layer 66. Herein, the difference between the first contact portions 54A shown in FIG. 2A and FIG. 2B is mainly described, and descriptions about the common elements are accordingly omitted.

The first alloy layer 63 is provided on the bottom surface 54b of the contact hole 54. The first alloy layer 63 of the present example is provided on the upper surface of the semiconductor substrate 10. The first alloy layer 63 is formed by annealing the metal film 69 including the first metal. The first alloy layer 63 of the present example is a titanium silicide layer formed by annealing a metal film 69 that is deposited on the bottom surface 54b of the contact hole 54 as an initial metal film.

The oxide layer 66 is provided on the upper surface of the first alloy layer 63 in the contact hole 54. The oxide layer 66 may be in contact with the upper surface of the first alloy layer 63, or may be in contact with the lower surface of the second barrier metal layer 68. The oxide layer 66 may be provided to be in contact with the first alloy layer 63 and the second barrier metal layer 68. That is, the oxide layer 66 may be provided to be stacked between the first alloy layer 63 and the second barrier metal layer 68.

The oxide layer 66 may include elements configuring the first alloy layer 63. The oxide layer 66 may include elements that constitute the semiconductor substrate 10, or oxides of silicon. For example, the oxide layer 66 is a silicon oxide film. Composition of the oxide layer 66 may be at least one of SiO, SiO₂, or Si₂O₃. The oxide layer 66 may include oxide of a first metal of a predetermined conductivity. For example, the oxide layer 66 may include titanium, and may include a titanium oxide film. The composition of the oxide layer 66 may be at least one of TiO, TiO₂, or Ti₂O₃. The oxide layer 66 may be such a dense film that functions as a metal-diffusion-prevention layer. For example, the oxide layer 66 can prevent the plug layer 64 from diffusing during deposition of the plug layer 64 and protect the first alloy layer 63 from damages caused by the deposition of the plug layer 64.

The film thickness of the oxide layer 66 may be thinner than the film thickness of the first alloy layer 63. The film thickness of the oxide layer 66 may be thinner than the film thickness of the upper layer barrier metal portion 62. The film thickness of the oxide layer 66 may be 0.5 nm or more and 4.0 nm or less. For example, the film thickness of the oxide layer 66 is 2.5 nm. The film thickness of the oxide layer 66 may be the film thickness at the thickest position in the contact hole 54.

The oxide layer 66 may be formed by exposure to chemicals, such as etching. The oxide layer 66 may be formed by etching the upper surface of the first alloy layer 63. The upper surface of the first alloy layer 63 may be etched by wet etching or dry etching. The oxide layer 66 may be formed by the dry etching of the upper surface of the first alloy layer 63.

The oxide layer 66 may be formed by etching for removing the metal film 69 or the lower layer barrier metal portion 61. That is, forming the oxide layer 66 and removing the metal film 69 or the lower layer barrier metal portion 61 may be performed in the same process. By providing the oxide layer 66, the resistance of the second contact portion 54B becomes higher than the resistance of the first contact portion 54A, and therefore a hole injection upon conducting of the diode portion 80 can be suppressed, and the reverse recovery loss can be reduced.

In the contact hole 54, the second barrier metal layer 68 is provided above the oxide layer 66. The second barrier metal layer 68 may be provided outside the contact hole 54 to be in contact with the upper surface of the interlayer dielectric film 38. The second barrier metal layer 68 includes a nitride of a first metal of a predetermined conductivity. The second barrier metal layer 68 of the present example is provided, in the contact hole 54, on a side wall of the upper surface of an oxide layer 66 and the interlayer dielectric film 38, and has an upper layer barrier metal portion 62.

In the contact hole 54, the upper layer barrier metal portion 62 is stacked on the oxide layer 66. The upper layer barrier metal portion 62 includes a conductive material. For example, the upper layer barrier metal portion 62 is TiN. The upper layer barrier metal portion 62 is provided by stacking on the oxide layer 66 that is provided on the upper surface of the first alloy layer 63. The upper layer barrier metal portion 62 may be formed by sputtering a conductive material. The upper layer barrier metal portion 62 of the present example is TiN formed by sputtering. The upper layer barrier metal portion 62 may be provided to be in contact with the oxide layer 66. Since the upper layer barrier metal portion 62 formed by sputtering does not require the initial metal film to be formed thereon, and can thereby avoid being affected by the hydrogen absorbing effect due to remaining Ti or the like.

The plug layer 64 is provided above the first barrier metal layer 60 or the second barrier metal layer 68 in the contact hole 54. The plug layer 64 may be provided in contact with the upper layer barrier metal portion 62 in the contact hole 54. The plug layer 64 is a conductive material that is filled inside the contact hole 54. The plug layer 64 may be a material different from that of the emitter electrode 52. For example, the material of the plug layer 64 is tungsten. Note that also outside of the contact hole 54, the plug layer 64 may be provided above the interlayer dielectric film 38 in contact with the upper layer barrier metal portion 62. The plug layer 64 may be omitted, and the emitter electrode 52 may be filled inside the contact hole 54.

The interlayer dielectric film 38 includes the contact hole 54 and is provided above the semiconductor substrate 10. Although the interlayer dielectric film 38 includes one layer of a dielectric film provided above the front surface 21, the interlayer dielectric film 38 may alternatively include a plurality of stacked dielectric films. The interlayer dielectric film 38 may be a silicon oxide film such as BPSG.

The lower layer barrier metal portion 61 is denser than that of the upper layer barrier metal portion 62. The lower layer barrier metal portion 61 and the upper layer barrier metal portion 62 may be formed by different deposition methods. The lower layer barrier metal portion 61 may be a TiN film formed by annealing of a metal film 69 of Ti deposited on the side wall of the interlayer dielectric film 38. The upper layer barrier metal portion 62 may be a TiN film formed by sputtering of TiN. Thereby, the lower layer barrier metal portion 61 may be a TiN film denser than the upper layer barrier metal portion 62. The lower layer barrier metal portion 61 and the upper layer barrier metal portion 62 may include the same material.

Since the upper layer barrier metal portion 62 is not a dense film like the lower layer barrier metal portion 61, the plug layer 64 may penetrate into the upper layer barrier metal portion 62 upon forming the plug layer 64. However, by forming the lower layer barrier metal portion 61 densely, the interlayer dielectric film 38 can be protected from damage upon deposition of the plug layer 64.

The film thickness of the lower layer barrier metal portion 61 may be thinner than the film thickness of the upper layer barrier metal portion 62. The film thickness of the lower layer barrier metal portion 61 may be thinner than the film thickness of the first alloy layer 63. The lower layer barrier metal portion 61 may thinned by etching after a dense film is formed. The etching performed after the dense film is formed may be performed using a chemical liquid. The chemical liquid used for performing the etching may be, for example, hydrofluoric acid, an ammonia hydrogen peroxide, sulfuric acid, or the like. The ammonia hydrogen peroxide is a mixed liquid of ammonia (NH₄OH), hydrogen peroxide (H₂O₂), and water (H₂O). The etching performed after the dense film is formed may be dry etching, reverse sputtering, or the like. The film thickness of the lower layer barrier metal portion 61 may be 1 nm or more and 10 nm or less. The film thickness of the lower layer barrier metal portion 61 may be the film thickness at the position in the contact hole 54, with the thickest thickness. The film thickness of the lower layer barrier metal portion 61 may be formed in a predetermined range in the entire side wall of the interlayer dielectric film 38. The film thickness of the upper layer barrier metal portion 62 may be 1 nm or more and 100 nm or less. The film thickness of the first alloy layer 63 may be 1 nm or more and 200 nm or less.

The lower layer barrier metal portion 61 may cover the side wall 54w of the contact hole 54. The lower end of the lower layer barrier metal portion 61 may be in contact with the oxide layer 66. That is, the bottom surface 54b and the side wall 54w of the contact hole 54 may be covered by the first alloy layer 63 and the lower layer barrier metal portion 61, respectively.

The opening width of the contact hole 54 is the width of the contact hole 54 in the trench array direction on the upper surface of the interlayer dielectric film 38. The opening width of the contact hole 54 may be 100 nm or more and 1000 nm or less.

Herein, when electron beams, particle beams, and the like for forming the lifetime control region pass through the MOS gate structure, a defect may be generated in the vicinity of an interface between the oxide film and the semiconductor layer in the MOS gate structure. Then, when metal such as Ti having a hydrogen absorbing effect exists in the vicinity of the MOS gate structure, hydrogen diffused in the gate portion may be absorbed so as to result in an inhibition of a hydrogen termination of a dangling bond of the MOS gate structure and a variation of a threshold voltage.

On the upper surface of the first alloy layer 63 or the side wall 54w of the contact hole 54, an initial metal film that is unreacted and that has hydrogen absorbing effect may remain. In the semiconductor device 100 of the present example, the remaining amount of the initial metal film having the hydrogen absorbing effect may be reduced by etching and oxidizing the upper surface of the first alloy layer 63, allowing the formation of the oxide layer 66. Also, the semiconductor device 100 of the present example can reduce the remaining amount of metal of the initial metal film that has the hydrogen absorbing effect by removing or thinning the metal film 69 and the lower layer barrier metal portion 61. Thus, the influence of the hydrogen absorbing effect can be suppressed and the hydrogen termination of dangling bonds in the MOS gate structure can be promoted. Accordingly, a variation in a threshold voltage can be suppressed.

By having the oxide layer 66, the semiconductor device 100 can ensure the barrier property during the deposition of the plug layer 64. In the semiconductor device 100 of the present example, the variation of the threshold voltage can be suppressed while enhancing the reliability on the front surface 21 side. In addition, in the semiconductor device 100, the reverse recovery loss can be reduced because the lifetime control region can be formed while suppressing the variation of the threshold voltage.

It is to be noted that although an effect of the electron beams and particle beams for forming the lifetime control region on the MOS gate structure becomes large when irradiating the beams from the front surface 21 side of the semiconductor substrate 10, the beams may affect the MOS gate structure also when being irradiated from the back surface 23 side of the semiconductor substrate 10. Thus, also when irradiating from the back surface 23 side, the semiconductor device 100 can recover the damage of the MOS gate structure and suppress the variation of the threshold voltage. It is to be noted that although an acceleration voltage becomes large to result in an increase in the size of the device when irradiating particle beams and the like from the back surface 23 side of the semiconductor substrate 10, in the semiconductor device 100 of the present example, the effect of irradiating particle beams and the like from the front surface 21 can be suppressed, and thus the lifetime control region can be formed with a more compact device.

FIG. 3C is an enlarged view of a cross section of the semiconductor device 100. The cross section in FIG. 3C is an X-Z cross section passing through the contact region 15 on the front surface 21 of the semiconductor substrate 10. In the present example, an enlarged view of a cross section near the second contact portion 54B according to a modification example is shown. The second contact portion 54B of the present example is different from the second contact portion 54B shown in FIG. 3A and FIG. 3B in that the second barrier metal layer 68 is provided outside the contact hole 54 and above the interlayer dielectric film 38. Another structure may be any configuration shown in the present specification. Note that the illustration of the X-Z cross section that passes through the emitter region 12 on the front surface 21 of the semiconductor substrate 10 is omitted since it is common to that of the X-Z cross section of FIG. 3C, except that the emitter region 12 is provided instead of the contact region 15 of FIG. 3C.

The second barrier metal layer 68 may be provided outside the contact hole 54 to be in contact with the upper surface of the interlayer dielectric film 38. By forming the second barrier metal layer 68 also on the interlayer dielectric film 38, the reliability, such as wire bond and resin sealing, in implementation can be improved. FIG. 3D is an enlarged view of a cross section of the semiconductor device 100. The cross section in FIG. 3D is an X-Z cross section passing through the contact region 15 on the front surface 21 of the semiconductor substrate 10. In the present example, an enlarged view of a cross section near the second contact portion 54B according to a further modification example is shown. The second contact portion 54B of the present example is different from the second contact portion 54B shown in FIG. 3C in that the plug layer 64 is provided outside the contact hole 54 and above the interlayer dielectric film 38. Another structure may be any configuration shown in the present specification. Note that the illustration of the X-Z cross section that passes through the emitter region 12 on the front surface 21 of the semiconductor substrate 10 is omitted since it is common to that of the X-Z cross section of FIG. 3D, except that the emitter region 12 is provided instead of the contact region 15 of FIG. 3D.

The plug layer 64 may be provided outside the contact hole 54 to be in contact with the upper surface of the first barrier metal layer 60. By forming the plug layer 64 also on the interlayer dielectric film 38, the reliability, such as wire bond and resin sealing, in implementation can be improved.

FIG. 3E is an enlarged view of a cross section of the semiconductor device 100. The cross section in FIG. 3E is an X-Z cross section passing through the contact region 15 on the front surface 21 of the semiconductor substrate 10. In the present example, a structure in which the contact region 15 is positioned at the center of the mesa portion, and the emitter region 12 is provided to be in contact with the trench portion is described as an example. The second contact portion 54B of the present example is different from the second contact portion 54B of FIG. 3A and FIG. 3B in that the second barrier metal layer 68 is provided outside the contact hole 54 and above the interlayer dielectric film 38, and in that an emitter electrode 52 is provided in the contact hole 54 instead of the plug layer 64. The emitter electrode 52 is connected to the front surface 21 of the semiconductor substrate 10 via the contact hole 54. Another structure may be any configuration shown in the present specification.

Even if there is no plug layer 64, by forming the first barrier metal layer 60 also on the interlayer dielectric film 38, the reliability in implementation, such as resin sealing, can be improved.

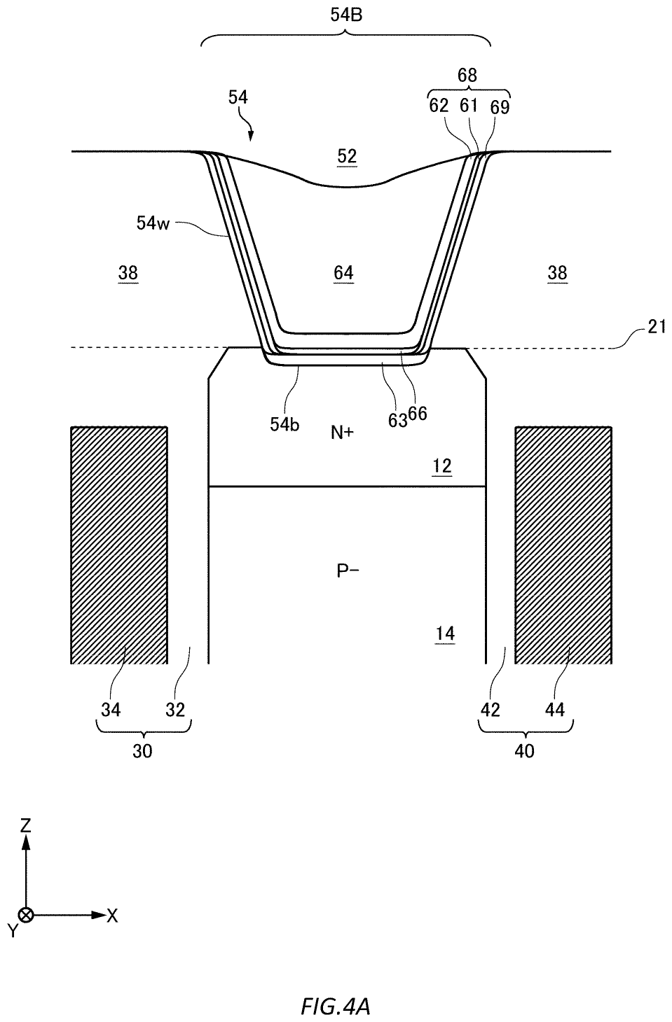

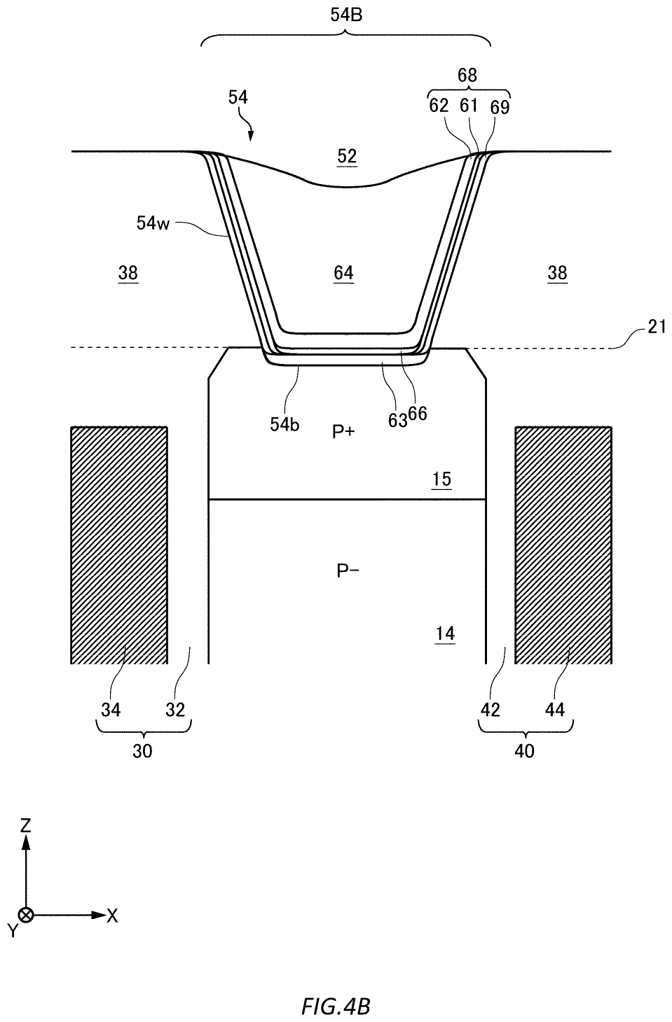

FIG. 4A is an enlarged view of a cross section of the semiconductor device 100. FIG. 4B is an enlarged view of a cross section of the semiconductor device 100. The cross section in FIG. 4A is an X-Z cross section passing through the emitter region 12 on the front surface 21 of the semiconductor substrate 10, and the cross section in FIG. 4B is an X-Z cross section passing through the contact region 15 on the front surface 21. In the present example, an enlarged view of a cross section near the second contact portion 54B according to a modification example is shown. The second contact portion 54B of the present example is different from the second contact portion 54B shown in FIG. 3A to FIG. 3B in the configuration of the second barrier metal layer 68. Herein, the difference between the second contact portions 54B shown in FIG. 3A and FIG. 3B is mainly described, and descriptions about the common elements are accordingly omitted.

The second barrier metal layer 68 of the present example has the metal film 69 and the lower layer barrier metal portion 61 below the upper layer barrier metal portion 62. That is, upon etching in the forming the oxide layer 66 on the first alloy layer 63, the metal film 69 and the lower layer barrier metal portion 61 may remain after thinning without being completely removed. The lower layer barrier metal portion 61 is provided on the metal film 69. The lower layer barrier metal portion 61 includes a nitride of a first metal of a predetermined conductivity. For example, the lower layer barrier metal portion 61 is TiN. The lower layer barrier metal portion 61 is formed by annealing the metal film 69 including the first metal. The lower layer barrier metal portion 61 is TiN formed by annealing a metal film 69 deposited on the side wall of the contact hole 54 as an initial metal film in a nitrogen atmosphere. Alternatively, the metal film 69 may be completely removed by etching, and the lower layer barrier metal portion 61 may be provided on the side wall 54w of the contact hole 54. Alternatively, the lower layer barrier metal portion 61 is completely removed by etching, and the upper layer barrier metal portion 62 may be provided on the metal film 69.

The lower layer barrier metal portion 61 and the first alloy layer 63 may be formed by the same annealing process. For example, by using the metal film 69 deposited on the inner wall of the contact hole 54, a lower layer barrier metal portion 61 of TiN is formed on the side wall 54w of the contact hole 54, and a first alloy layer 63 of titanium silicide is formed on the bottom surface 54b of the contact hole 54. At this time, the lower layer barrier metal portion 61 and the metal film 69 remaining on the side wall 54w or the bottom surface 54b of the contact hole 54 may be thinned by etching, and the lower layer barrier metal portion 61 and the metal film 69 remaining on the first alloy layer 63 provided on the bottom surface 54b of the contact hole 54 may be removed and thinned by etching, and may be used to form the oxide layer 66.

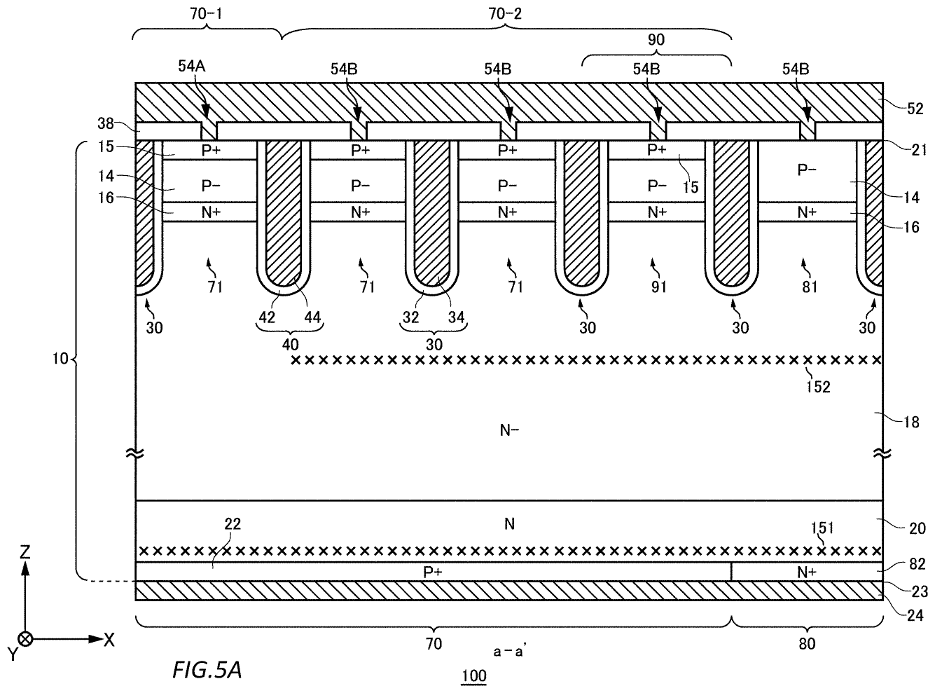

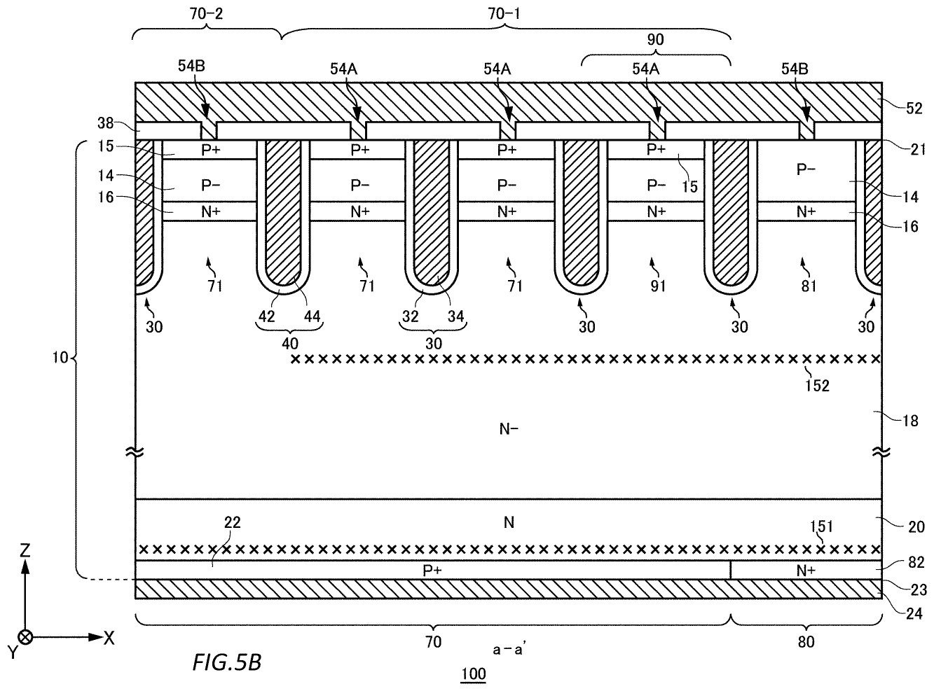

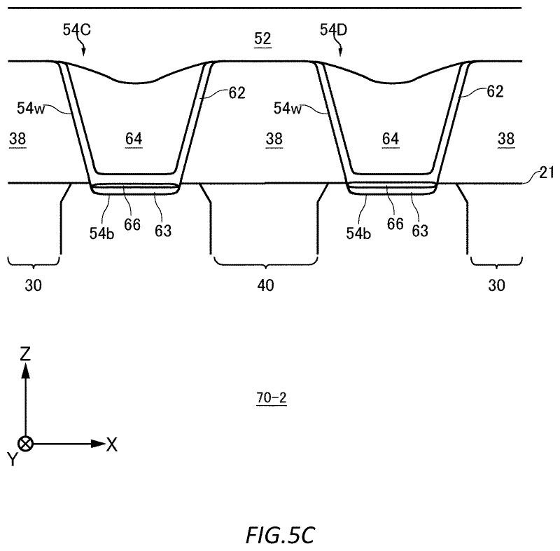

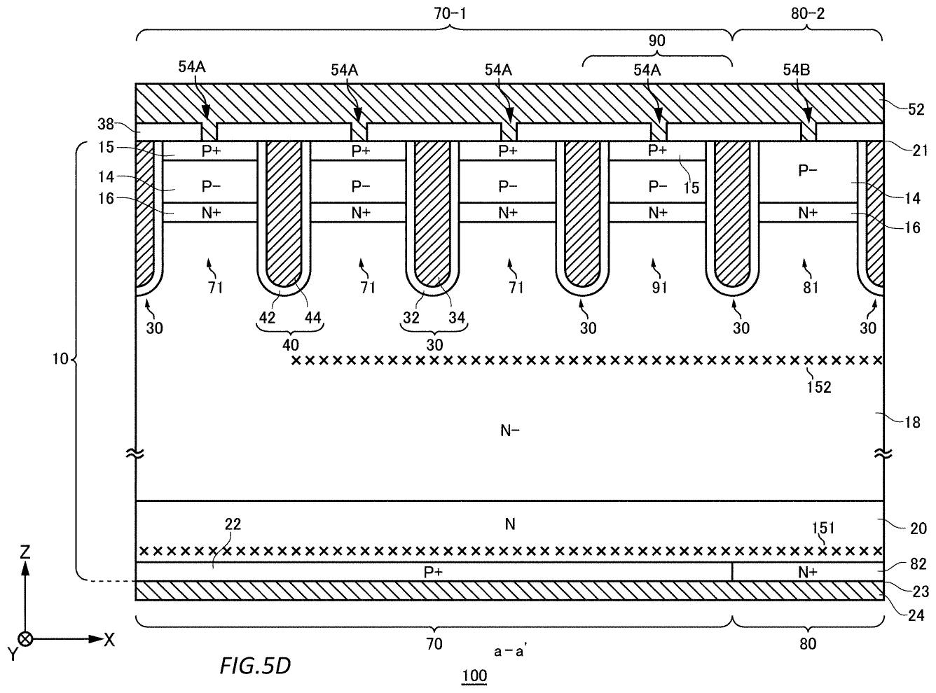

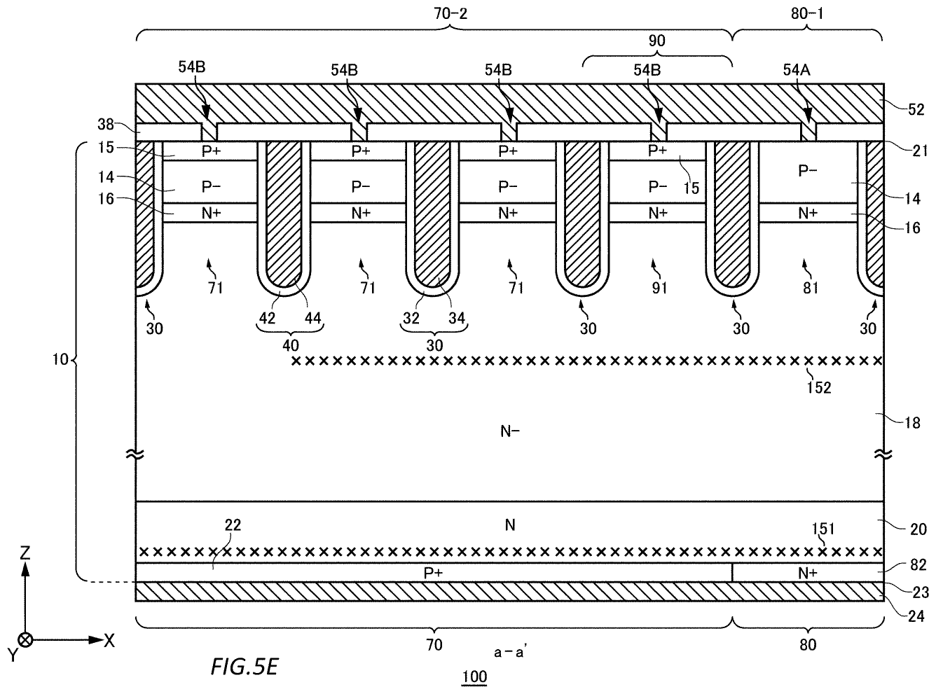

FIG. 5A shows an example of a cross section a-a′ in FIG. 1B. In FIG. 5A, an example of the arrangement of the first contact portion 54A and the second contact portion 54B described above is shown. The transistor portion 70 has a first region 70-1 including a first contact portion 54A, and a second region 70-2 including a second contact portion 54B.

The first region 70-1 is provided to be spaced apart from the diode portion 80, and the second region 70-2 is provided to be adjacent to the diode portion 80. That is, in the transistor portion 70 of the present example, a region including the center in the trench array direction is the first region 70-1, and a region provided between the first region 70-1 and the diode portion 80 is the second region 70-2.

As described above, since the second contact portion 54B has a higher resistance than that of the first contact portion 54A, in the second region 70-2 that is adjacent to the diode portion 80, the hole injection when the diode portion 80 is electrically conducted can be suppressed, and the reverse recovery loss can be suppressed. On the other hand, in the first region 70-1, the oxide layer 66 is not provided on the bottom surface 54b of the contact hole 54, and therefore the contact resistance can be kept good.

The front surface side lifetime control region 152 is provided to be extended to the boundary between the first region 70-1 and the second region 70-2. That is, the front surface side lifetime control region 152 may be provided to be extended from the diode portion 80 to the second region 70-2. The threshold may particularly fall when the front surface side lifetime control region 152 is provided in the second region 70-2, but the falling of the threshold can be suppressed by removing or thinning the metal film 69 or the lower layer barrier metal portion 61 that absorbs hydrogen in the side surface 54w of the contact hole in the second contact portion 54B.

In the diode portion 80, the second contact portion 54B may be provided. That is, the diode portion 80 may be the second region 80-2. By providing the second contact portion 54B with a resistance higher than that of the first contact portion 54A in the diode portion 80, the hole injection when the diode portion 80 is electrically conducted can be suppressed, and the reverse recovery loss can be suppressed.

The thickness of the oxide layer 66 provided in the second contact portion 54B of the diode portion 80 may be greater than the thickness of the oxide layer 66 provided in the second contact portion 54B of the second region 70-2. Thereby, the resistance of the second contact portion 54B of the diode portion 80 can be further increased, the hole injection when the diode portion 80 is electrically conducted can be further suppressed, and the reverse recovery loss can be further suppressed.

One second region 70-2 is provided between the first region 70-1 and the diode portion 80 in FIG. 5A, but a plurality of second regions 70-2 may be provided separately. Also, in another example, the front surface side lifetime control region 152 may be provided in at least a part of the second region 70-2, may not be provided in at least a part of the first region 70-1, or may not be provided in at least a part of the diode portion 80. The front surface side lifetime control region 152 may be provided or may not be provided in the entire surface of the semiconductor device 100. In yet another example, the thickness of the oxide layer 66 of the second contact portion 54B of the diode portion 80 may be less than the thickness of the oxide layer 66 provided in the second contact portion 54B of the first region 70-1. The first contact portion 54A may be provided in the diode portion 80. That is, in the diode portion 80, the first region 80-1 may be provided instead of or in addition to the second region 80-2.

FIG. 5B shows another example of the cross section a-a′ in FIG. 1B. In FIG. 5B, another example of the arrangement of the first contact portion 54A and the second contact portion 54B described above is shown. The transistor portion 70 has a first region 70-1 including a first contact portion 54A, and a second region 70-2 including a second contact portion 54B.

The first region 70-1 is provided to be adjacent to the diode portion 80, and the second region 70-2 is provided to be spaced apart from the diode portion 80. That is, in the transistor portion 70 of the present example, a region including the center in the trench array direction is the second region 70-2, and a region provided between the second region 70-2 and the diode portion 80 is the first region 70-1.

In the first region 70-1 that is adjacent to the diode portion 80, the oxide layer 66 is not provided on the bottom surface 54b of the contact hole 54, and therefore the contact resistance can be kept good. Thereby, the latch-up can be suppressed by improving the extraction of the holes.

The front surface side lifetime control region 152 is provided to be extended to the boundary between the first region 70-1 and the second region 70-2. That is, the front surface side lifetime control region 152 may be provided to be extended from the diode portion 80 to the first region 70-1. The threshold may particularly fall when the front surface side lifetime control region 152 is provided in the first region 70-1, but the falling of the threshold can be suppressed by removing or thinning the metal film 69 or the lower layer barrier metal portion 61 that absorbs hydrogen in the side surface 54w of the contact hole in the second contact portion 54B.

In a top view of the semiconductor substrate 10, the area proportion to the transistor portion 70 of the region in which the front surface side lifetime control region 152 is provided may be less than 0.5. That is, the area proportion of the second region 70-2 in the transistor portion 70 may be higher than the area proportion of the first region 70-1 in the transistor portion 70. In the second region 70-2 that occupies a high area proportion in the transistor portion 70, when the metal film 69 or the lower layer barrier metal portion 61 having a hydrogen absorbing effect is removed or thinned, a variation in the threshold voltage can be particularly suppressed.

In the diode portion 80, the second contact portion 54B may be provided. That is, the diode portion 80 may be the second region 80-2. By providing the second contact portion 54B with a resistance higher than that of the first contact portion 54A in the diode portion 80, the hole injection when the diode portion 80 is electrically conducted can be suppressed, and the reverse recovery loss can be suppressed.

The thickness of the oxide layer 66 provided in the second contact portion 54B of the diode portion 80 may be greater than the thickness of the oxide layer 66 provided in the second contact portion 54B of the second region 70-2. Thereby, the resistance of the second contact portion 54B of the diode portion 80 can be further increased, the hole injection when the diode portion 80 is electrically conducted can be further suppressed, and the reverse recovery loss can be further suppressed.

One first region 70-1 is provided between the second region 70-2 and the diode portion 80 in FIG. 5B, but a plurality of first regions 70-1 may be provided separately. Also, in another example, the front surface side lifetime control region 152 may be provided in at least a part of the first region 70-1, may not be provided in at least a part of the second region 70-2, or may not be provided in at least a part of the diode portion 80. The front surface side lifetime control region 152 may be provided or may not be provided in the entire surface of the semiconductor device 100. In yet another example, the thickness of the oxide layer 66 of the second contact portion 54B of the diode portion 80 may be less than the thickness of the oxide layer 66 provided in the second contact portion 54B of the second region 70-2. The first contact portion 54A may be provided in the diode portion 80. That is, in the diode portion 80, the first region 80-1 may be provided instead of or in addition to the second region 80-2.

FIG. 5C is an enlarged view of a cross section of the semiconductor device 100. FIG. 5C shows an example of the second region 70-2. The configuration of the second region 70-2 shown in FIG. 5C may be applied to either example of FIG. 5A and FIG. 5B. Note that in FIG. 5C, the second contact portion 54B of FIG. 3A or FIG. 3B is shown as the second contact portion 54B, but any other second contact portion 54B described in the present specification may be used.

The second contact portion 54B has a third contact portion 54C, and a fourth contact portion 54D that is provided closer to the diode portion 80 side than the third contact portion 54C. The thickness of the oxide layer 66 of the fourth contact portion 54D is greater than the thickness of the oxide layer 66 of the third contact portion 54C. That is, a plurality of second contact portions 54B provided in the second region 70-2 may have a thicker oxide layer 66 as they approach the diode portion 80. The thickness of the oxide layer 66 can be changed according to the etching time.

Thereby, in a region close to the diode portion 80, the resistance of the second contact portion 54B becomes higher, and therefore the hole injection when the diode portion 80 is electrically conducted can be further suppressed, and the reverse recovery loss can be further suppressed.

FIG. 5D is an enlarged view of a cross section of the semiconductor device 100. FIG. 5D shows an example in which the transistor portion 70 is the first region 70-1 in which the first contact portion 54A is provided, and the diode portion 80 is the second region 80-2 in which the second contact portion 54B is provided. Another structure may be any structure shown in the present specification.

In the present example, in the first region 70-1, by providing the first contact portion 54A, the contact resistance can be kept good, and the extraction of holes can be improved to suppress the latch-up. In the second region 80-2, by providing the second contact portion 54B, the hole injection when the diode portion 80 is electrically conducted can be suppressed, and the reverse recovery loss can be suppressed. When the metal film 69 or the lower layer barrier metal portion 61 having a hydrogen absorbing effect is removed or thinned, a variation in the threshold voltage of the transistor portion 70 can be particularly suppressed.

FIG. 5E is an enlarged view of a cross section of the semiconductor device 100. FIG. 5E shows an example in which the transistor portion 70 is the second region 70-2 in which the second contact portion 54B is provided, and the diode portion 80 is the first region 80-1 in which the first contact portion 54A is provided. Another structure may be any structure shown in the present specification.

In the present example, in the second region 70-2, by providing the second contact portion 54B, the hole injection from the contact region 15 of the transistor portion 70 with a higher concentration than that of the base region 14 of the diode portion 80 when the diode portion 80 is electrically conducted can be suppressed, and the reverse recovery loss can be suppressed. When the metal film 69 or the lower layer barrier metal portion 61 having a hydrogen absorbing effect is removed or thinned, a variation in the threshold voltage can be particularly suppressed. In the first region 80-1, by providing the first contact portion 54A, the contact resistance can be kept good, and the conduction of the diode portion 80 and the characteristic during reverse recovery can be adjusted.

Examples shown in FIG. 5D, FIG. 5E, may be applied in combination with FIGS. 5A, 5B, and 5C. That is, the first region 70-1 and the second region 70-2 may be provided in the transistor portion 70, and the first region 80-1 and the second region 80-2 may be provided in the diode portion 80. By appropriately arranging the first region 70-1, 80-1, and the second region 70-2, 80-2 in accordance with the usage or specification, it is possible to perform suppression of variation in the threshold voltage of the transistor portion 70, suppression of the latch-up, conduction of the diode portion 80, and adjustment of the characteristic during reverse recovery. Also, the first region 70-1, 80-1, and the second region 70-2, 80-2 are described to be alternately arranged along the array direction of the trench in the example, but they may be alternately arranged in a direction along the extending direction of the trench.

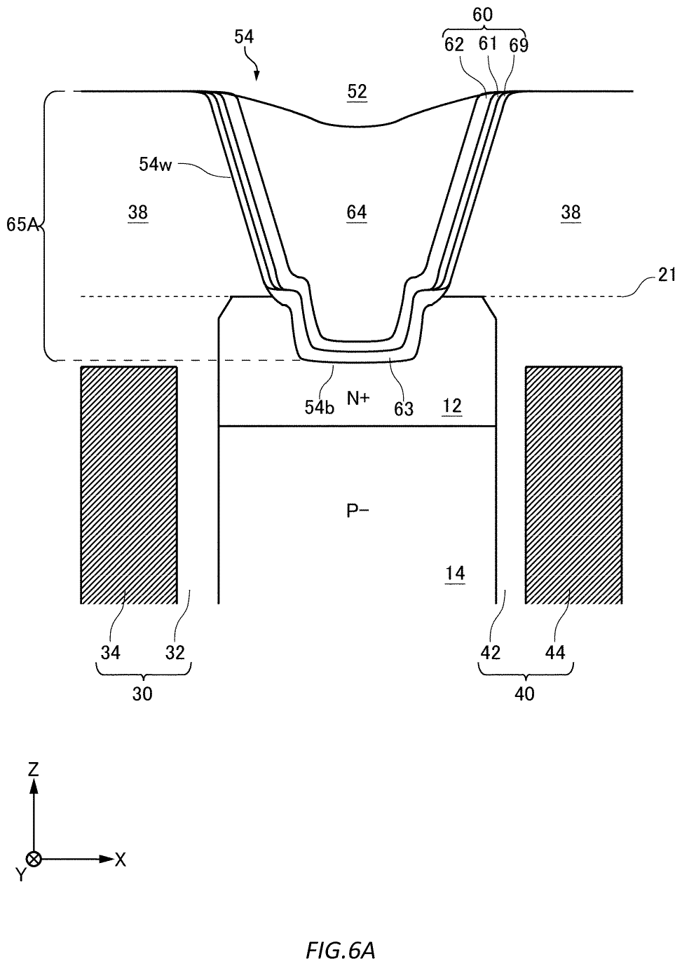

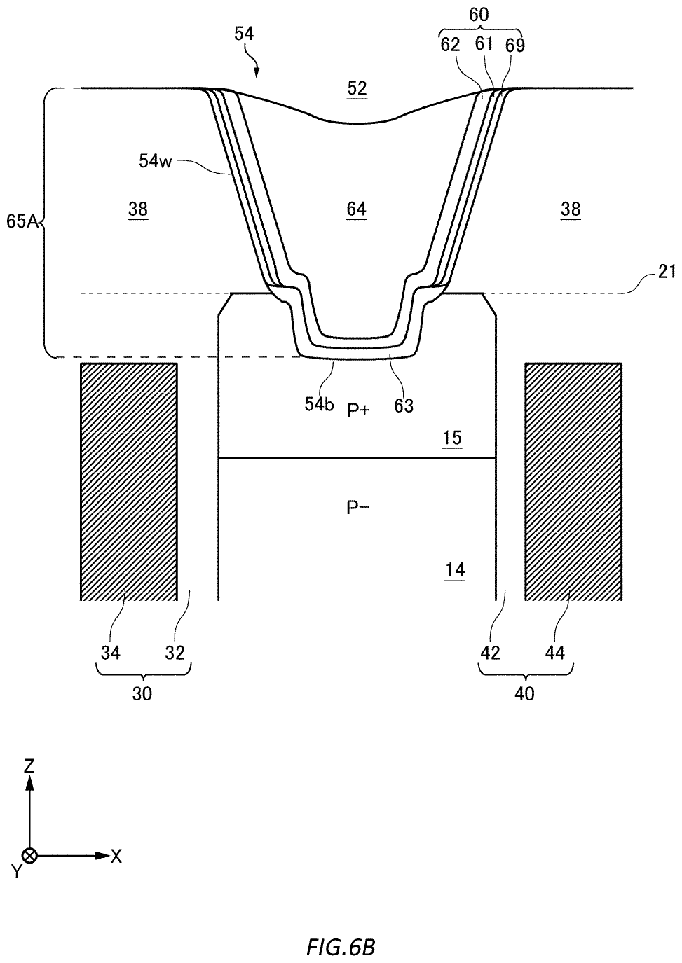

FIG. 6A is an enlarged view of a cross section of the semiconductor device 100. FIG. 6B is an enlarged view of a cross section of the semiconductor device 100. FIG. 6A and FIG. 6B show an enlarged view of the cross section near the contact hole 54. The cross section of FIG. 6A is an X-Z cross section passing through the emitter region 12 on the front surface 21 of the semiconductor substrate 10. The cross section in FIG. 6B is an X-Z cross section passing through the contact region 15 on the front surface 21 of the semiconductor substrate 10. The semiconductor device 100 of the present example is different from the semiconductor device 100 comprising the first contact portion 54A shown in FIG. 2A and FIG. 2B in that it comprises the first trench contact portion 65A. Another structure may be any configuration shown in the present specification.

The first trench contact portion 65A has a contact hole 54, and is provided to be extended in a depth direction of the semiconductor substrate 10 from the front surface 21 of the semiconductor substrate 10. The lower end of the first trench contact portion 65A of the present example, that is, the bottom surface 54b of the contact hole 54 is shallower than the lower end of the emitter region 12. The lower end of the first trench contact portion 65A may be deeper than the lower end of the emitter region 12. The lower end of the first trench contact portion 65A of the present example is shallower than the upper end of the gate conductive portion 44. The lower end of the first trench contact portion 65A may be deeper than the upper end of the gate conductive portion 44.

Although the interlayer dielectric film 38 of the present example includes one layer of a dielectric film, the interlayer dielectric film 38 may alternatively include a stacking structure formed of a plurality of stacked dielectric films. By providing the first trench contact portion 65A, the semiconductor device 100 of the present example can increase the area in contact with the semiconductor substrate 10 to reduce the contact resistance. By providing the first trench contact portion 65A in the transistor portion 70, the extraction of holes can be facilitated, to suppress the latch-up.

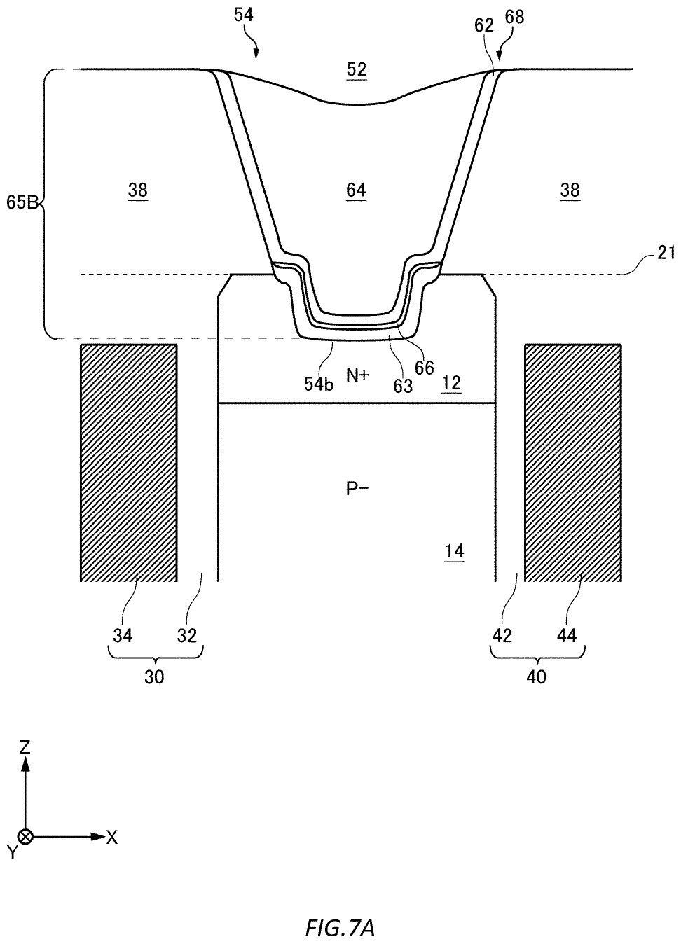

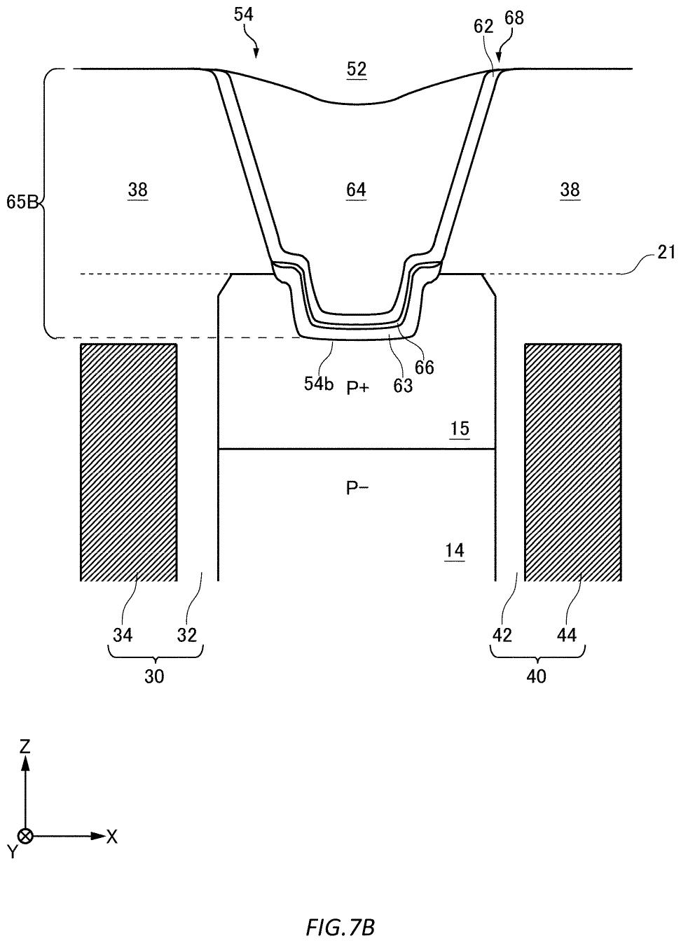

FIG. 7A is an enlarged view of a cross section of the semiconductor device 100. FIG. 7B is an enlarged view of a cross section of the semiconductor device 100. FIG. 7A and FIG. 7B show an enlarged view of the cross section near the contact hole 54. The cross section of FIG. 7A is an X-Z cross section passing through the emitter region 12 on the front surface 21 of the semiconductor substrate 10. The cross section in FIG. 7B is an X-Z cross section passing through the contact region 15 on the front surface 21 of the semiconductor substrate 10. The semiconductor device 100 of the present example is different from the semiconductor device 100 comprising the second contact portion 54B shown in FIG. 3A and FIG. 3B in that it comprises the second trench contact portion 65B. Another structure may be any configuration shown in the present specification.

The second trench contact portion 65B has a contact hole 54, and is provided to be extended in a depth direction of the semiconductor substrate 10 from the front surface 21 of the semiconductor substrate 10. The lower end of the second trench contact portion 65B of the present example, that is, the bottom surface 54b of the contact hole 54 is shallower than the lower end of the emitter region 12. The lower end of the second trench contact portion 65B may be deeper than the lower end of the emitter region 12. The lower end of the second trench contact portion 65B of the present example is shallower than the upper end of the gate conductive portion 44. The lower end of the second trench contact portion 65B may be deeper than the upper end of the gate conductive portion 44.

Although the interlayer dielectric film 38 of the present example includes one layer of a dielectric film, the interlayer dielectric film 38 may alternatively include a stacking structure formed of a plurality of stacked dielectric films. By providing the second trench contact portion 65B, the semiconductor device 100 of the present example can increase the area in contact with the semiconductor substrate 10 to reduce the contact resistance. By providing the second trench contact portion 65B in the transistor portion 70, the extraction of holes can be facilitated, to suppress the latch-up.

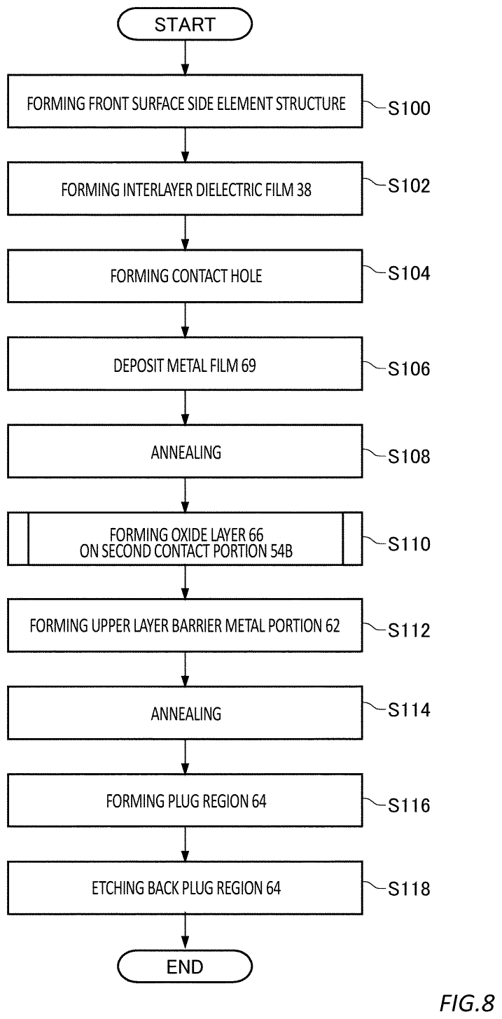

FIG. 8 is a flowchart showing an example of a process of manufacturing a semiconductor device 100. In step S100, an element structure on the front surface 21 side of the semiconductor device 100 is formed. Step S100 may include a process of forming the dummy trench portion 30 and the gate trench portion 40 as the element structure on the front surface 21 side. Step S100 may include a process of forming, as the element structure on the front surface 21 side, the base region 14, the emitter region 12, the contact region 15, and the like by performing ion implantation with respect to the semiconductor substrate 10.

In step S102, the interlayer dielectric film 38 is formed above the semiconductor substrate 10. The interlayer dielectric film 38 may be formed by stacking a plurality of dielectric films. In step S104, the interlayer dielectric film 38 is etched to form contact holes. In step S104, a contact hole such as a contact hole 54, a contact hole 55, and a contact hole 56 may be formed on the interlayer dielectric film 38.

In step S106, a metal film 69 for forming the lower layer barrier metal portion 61 and the first alloy layer 63 is deposited. In the present example, the metal film 69 is deposited on the side wall 54w and the bottom surface 54b of the contact hole 54. That is, the metal film 69 is formed to be in contact with the interlayer dielectric film 38 and the semiconductor substrate 10. For example, the metal film 69 is a Ti film deposited by sputtering. The film thickness of the metal film 69 may be 1 nm or more and 100 nm or less.

In step S108, the semiconductor substrate 10 is annealed in a nitrogen atmosphere. Thereby, the lower layer barrier metal portion 61 is formed on the side wall 54w of the contact hole 54, and the first alloy layer 63 is formed on the bottom surface 54b. In this manner, the metal film 69 that is in contact with the interlayer dielectric film 38 is the lower layer barrier metal portion 61, and the metal film 69 that is in contact with the semiconductor substrate 10 is the first alloy layer 63. The lower layer barrier metal portion 61 of the present example is a dense TiN film formed by annealing the Ti film of the side wall 54w of the contact hole 54. The first alloy layer 63 of the present example is a titanium silicide film formed by annealing the Ti film of the bottom surface 54b of the contact hole 54. An annealing temperature may be 300° C. or more and 1100° C. or less. The annealing for forming the lower layer barrier metal portion 61 may be performed before the upper layer barrier metal portion 62 is formed.

In step S110, after forming the first alloy layer 63 on the bottom surface 54b of the contact hole 54, the oxide layer 66 is formed on the second contact portion 54B. The oxide layer 66 may be formed before forming the upper layer barrier metal portion 62. The oxide layer 66 is formed on the upper surface of the first alloy layer 63 in the contact hole 54. The oxide layer 66 may be formed entirely on the exposed surface of the first alloy layer 63 in the contact hole 54. The step of forming the oxide layer 66 may include a step for wet etching, or may include a step for dry etching.

When forming the oxide layer 66 by etching, in the process of forming the oxide layer 66, the metal film 69 and the lower layer barrier metal portion 61 remaining on the side wall 54w of the contact hole 54 and that are unreacted may be etched. Thereby, the metal film 69 and the lower layer barrier metal portion 61 may be adjusted to have a predetermined film thickness from the side wall 54w of the contact hole 54. The lower layer barrier metal portion 61 may be etched to have a film thickness of 1 nm or more and 10 nm or less. The metal film 69 or the lower layer barrier metal portion 61 may be completely removed by etching. That is, a configuration obtained by completely removing the metal film 69 and the lower layer barrier metal portion 61 corresponds to the second contact portion 54B of FIG. 3A and FIG. 3B, and a configuration in which the metal film 69 does not remain and that is obtained by thinning the lower layer barrier metal portion 61 to a predetermined film thickness corresponds to the second contact portion 54B of FIG. 3C and FIG. 3D.

Note that step S110 is a process that forms the oxide layer 66 in the second contact portion 54B, and may not be applied to the first contact portion 54A. Therefore, in the first contact portion 54A, the oxide layer 66 may not be formed, and the metal film 69 may remain on the side wall 54w of the contact hole 54. Therefore, the oxide layer 66 is formed, and the second contact portion 54B from which the metal film 69 is removed has a higher resistance than that of the first contact portion 54A.

In step S112, the upper layer barrier metal portion 62 is formed. The upper layer barrier metal portion 62 may be formed by stacking on the first alloy layer 63 in the first contact portion 54A, and formed by stacking on the oxide layer 66 in the second contact portion 54B. The upper layer barrier metal portion 62 may be formed by stacking on the metal film 69 or the lower layer barrier metal portion 61 in the side wall 54w of the contact hole 54. The upper layer barrier metal portion 62 may be formed to be in contact with the interlayer dielectric film 38 on the side wall 54w of the contact hole 54 when the metal film 69 or the lower layer barrier metal portion 61 is completely removed. The upper layer barrier metal portion 62 of the present example is a TiN film formed by sputtering.

In step S114, the semiconductor substrate 10 is annealed in a nitrogen atmosphere. An annealing condition in step S114 may be the same as or different from the annealing condition in step S108. The annealing of the present example is performed after the upper layer barrier metal portion 62 is formed. The annealing of the upper layer barrier metal portion 62 may be performed before the plug layer 64 is formed. Note that step S114 may not be performed.

In step S116, the plug layer 64 is formed. In the present example, tungsten is formed so as to fill inside the contact hole 54 by a CVD (Chemical Vapor Deposition) method.

The oxide layer 66 of the second contact portion 54B may be provided on the upper surface of the first alloy layer 63, and may function as a metal-diffusion-prevention layer upon forming the plug layer 64. By providing the oxide layer 66, penetration of the plug layer 64 into the first alloy layer 63 can be prevented when the plug layer 64 is formed by CVD.

In step S118, the plug layer 64 is etched back. Accordingly, an unnecessary tungsten film outside the contact hole 54 may be removed. Etching back may be performed by dry etching or chemical mechanical polishing (CMP). When the tungsten film is removed, the metal film 69, the lower layer barrier metal portion 61, and the upper layer barrier metal portion 62 on the interlayer dielectric film 38 may be removed. The metal film 69, the lower layer barrier metal portion 61, and the upper layer barrier metal portion 62 on the interlayer dielectric film 38 may be removed in another process that is different from the etching back of the plug layer 64. The metal film 69, the lower layer barrier metal portion 61, and the upper layer barrier metal portion 62 on the interlayer dielectric film 38 may not be removed. Note that, step S118 may be omitted and the plug layer 64 may remain on the outside of the contact hole 54. Also, step S116 and step S118 can be omitted such that the plug layer 64 may not be formed inside the contact hole 54 and on the upper portion of the interlayer dielectric film 38.

After step S118, the emitter electrode 52 may be formed above the semiconductor substrate 10. Further, after step S118, the members on the back surface 23 side such as the collector electrode 24 may be formed. After step S118, the back surface side lifetime control region 151 and the front surface side lifetime control region 152 may be formed.

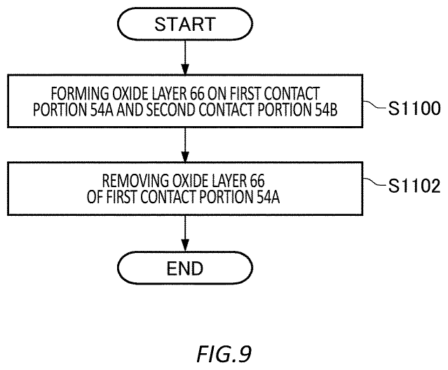

FIG. 9 is a flow of a different process of manufacturing of step S110 shown in FIG. 8. In step S1100, an oxide layer 66 is formed, on the bottom surface 54b, along with both the first contact portion 54A and the second contact portion 54B. The formation of the oxide layer 66 may be performed by etching the first alloy layer 63. Also, the formation of the oxide layer 66 may be performed by depositing the oxide film or oxidizing by heating, or the oxide layer 66 may be formed at a position other than the bottom surface 54b. When the formation of the oxide layer is performed by depositing the oxide film, the oxide may be an oxide of an element forming the first alloy layer, or may be a different oxide. In a step upon completion of step S1100, configurations of the first contact portion 54A and the second contact portion 54B may be the same, or the thickness of each unit may be the same. Then, in step S1102, the oxide film of the bottom surface 54b is removed in the first contact portion 54A. When the oxide layer 66 that is not required is formed inside the contact hole 54 of the first contact portion 54A, the second contact portion 54B or surrounding thereof, or in another region, the oxide layer 66 may be removed, or may be removed simultaneously with the oxide film of the bottom surface 54b. This method can also form a structure that does not have the oxide layer 66 in the first contact portion 54A while forming the oxide layer 66 in the second contact portion 54B. In a step upon completion of step S1102, in association with the removal of the oxide film that is not required, the thickness or the configuration of each unit configuring the first contact portion 54A and the second contact portion 54B may be different.

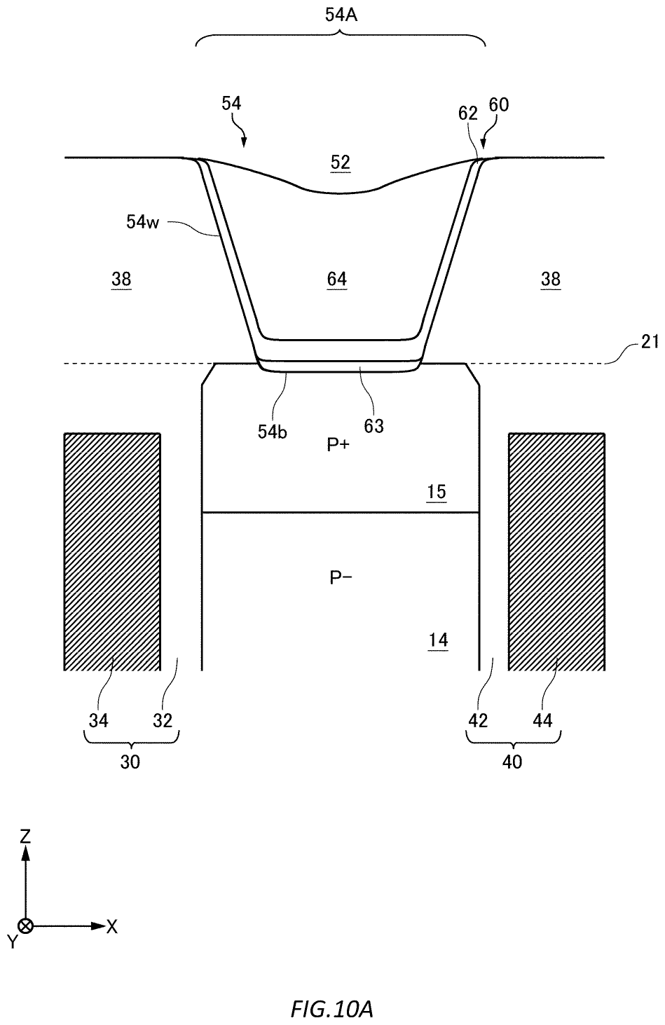

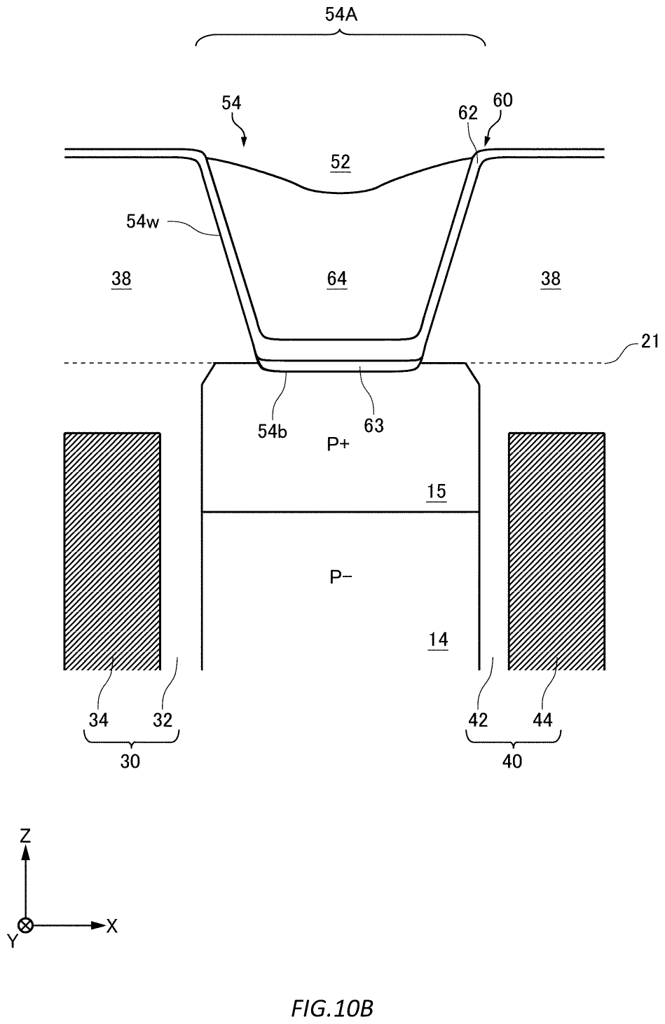

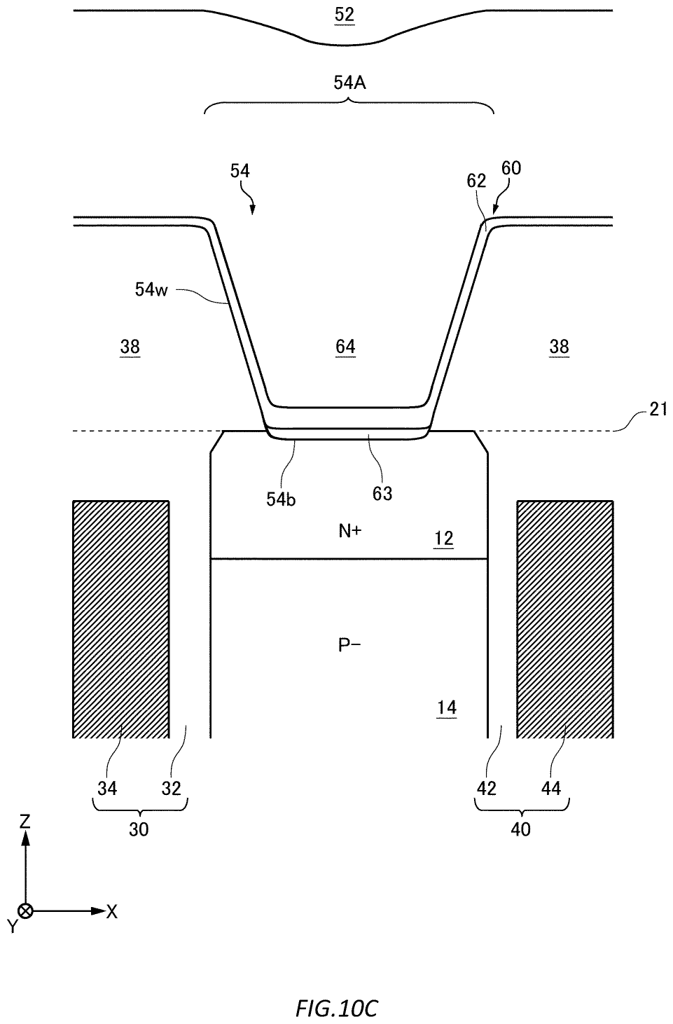

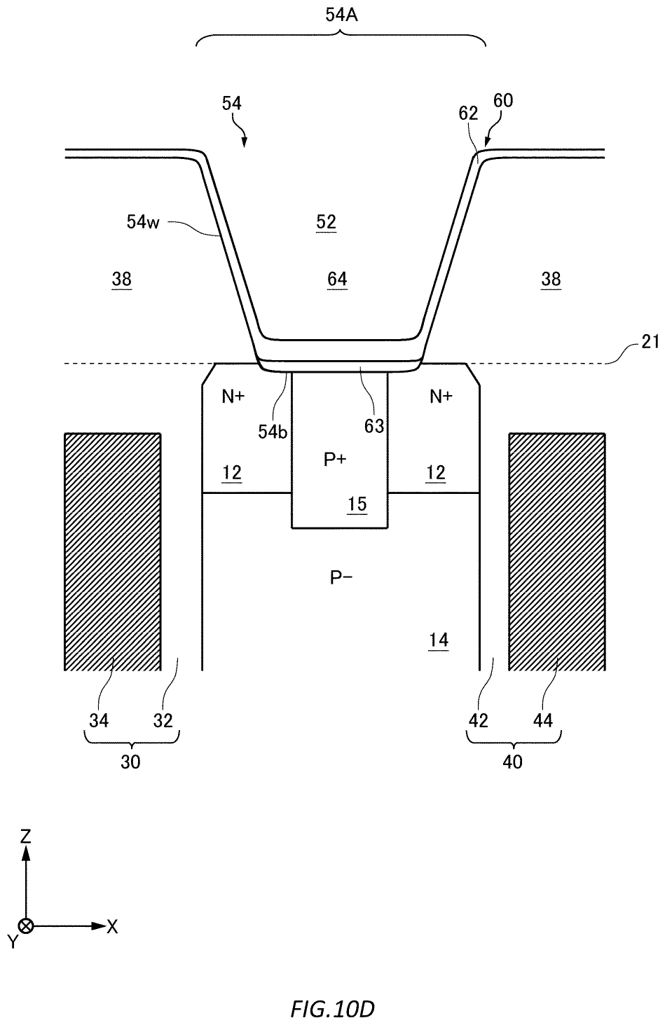

FIG. 10A is an enlarged view of a cross section of the semiconductor device 100. The cross section in FIG. 10A is an X-Z cross section passing through the contact region 15 on the front surface 21 of the semiconductor substrate 10. In the present example, an enlarged view of a cross section near the first contact portion 54A according to the modification example is shown. The first contact portion 54A of the present example is different from the first contact portion 54A shown in FIG. 2B in the configuration of the first barrier metal layer 60. Herein, the difference between the first contact portions 54A shown in FIG. 2B is mainly described, and descriptions about the common elements are accordingly omitted.

The first contact portion 54A of FIG. 10A is obtained by, in the flow of the process of manufacturing shown in FIG. 8 and FIG. 9, forming the oxide layer 66 by the etching of the first alloy layer 63, and then removing the oxide layer 66. The first barrier metal layer 60 of the present example does not have the metal film 69 and the lower layer barrier metal portion 61 below the upper layer barrier metal portion 62. That is, in this example, upon etching in the forming of the oxide layer 66 on the first alloy layer 63, the metal film 69 and the lower layer barrier metal portion 61 are completely removed.

Note that the illustration of the X-Z cross section that passes through the emitter region 12 on the front surface 21 of the semiconductor substrate 10 is omitted since it is common to that of the X-Z cross section of FIG. 10A, except that the emitter region 12 is provided instead of the contact region 15 of FIG. 10A. Also, in the etching upon forming the oxide layer 66 on the first alloy layer 63, if the metal film 69 and the lower layer barrier metal portion 61 remain without being completely removed, the structure is similar to that shown in FIG. 2B.

The cross section in FIG. 10B is an X-Z cross section passing through the contact region 15 on the front surface 21 of the semiconductor substrate 10. In the present example, an enlarged view of a cross section near the first contact portion 54A according to the modification example is shown. The first contact portion 54A of the present example is different from the first contact portion 54A shown in FIG. 10A in that the first barrier metal layer 60 is provided outside the contact hole 54 and above the interlayer dielectric film 38. Another structure may be any configuration shown in the present specification.

The first contact portion 54A of FIG. 10B is obtained by, in the flow of the process of manufacturing shown in FIG. 8 and FIG. 9, forming the oxide layer 66 by the etching of the first alloy layer 63, and then removing the oxide layer 66. The first barrier metal layer 60 of the present example does not have the metal film 69 and the lower layer barrier metal portion 61 below the upper layer barrier metal portion 62. That is, even in the structure in which the first barrier metal layer 60 is provided outside of the contact hole 54 and above the interlayer dielectric film 38, in the etching upon forming the oxide layer 66 on the first alloy layer 63, the metal film 69 and the lower layer barrier metal portion 61 may be completely removed.

Note that the illustration of the X-Z cross section that passes through the emitter region 12 on the front surface 21 of the semiconductor substrate 10 is omitted since it is common to that of the X-Z cross section of FIG. 10B, except that the emitter region 12 is provided instead of the contact region 15 of FIG. 10B. Also, in the etching upon forming the oxide layer 66 on the first alloy layer 63, if the metal film 69 and the lower layer barrier metal portion 61 remain without being completely removed, the structure is similar to that shown in FIG. 2C.

The cross section in FIG. 10C is an X-Z cross section passing through the contact region 15 on the front surface 21 of the semiconductor substrate 10. In the present example, an enlarged view of a cross section near the first contact portion 54A according to the modification example is shown. The first contact portion 54A of the present example is different from the first contact portion 54A shown in FIG. 10B in that the plug layer 64 is provided outside the contact hole 54 and above the interlayer dielectric film 38. Another structure may be any configuration shown in the present specification.

The first contact portion 54A of FIG. 10C is obtained by, in the flow of the process of manufacturing shown in FIG. 8 and FIG. 9, forming the oxide layer 66 by the etching of the first alloy layer 63, and then removing the oxide layer 66. The first barrier metal layer 60 of the present example does not have the metal film 69 and the lower layer barrier metal portion 61 below the upper layer barrier metal portion 62. That is, even in the structure in which the plug layer 64 is provided outside of the contact hole 54 and above the interlayer dielectric film 38, in the etching upon forming the oxide layer 66 on the first alloy layer 63, the metal film 69 and the lower layer barrier metal portion 61 may be completely removed.

Note that the illustration of the X-Z cross section that passes through the emitter region 12 on the front surface 21 of the semiconductor substrate 10 is omitted since it is common to that of the X-Z cross section of FIG. 10C, except that the emitter region 12 is provided instead of the contact region 15 of FIG. 10C. Also, in the etching upon forming the oxide layer 66 on the first alloy layer 63, if the metal film 69 and the lower layer barrier metal portion 61 remain without being completely removed, the structure is similar to that shown in FIG. 2D.

The cross section in FIG. 10D is an X-Z cross section passing through the contact region 15 on the front surface 21 of the semiconductor substrate 10. In the present example, an enlarged view of a cross section near the first contact portion 54A according to the modification example is shown. The first contact portion 54A of the present example is different from the first contact portion 54A shown in FIG. 10B in that the first barrier metal layer 60 is provided outside the contact hole 54 and above the interlayer dielectric film 38, and there is no plug layer 64 in the contact hole 54. Another structure may be any configuration shown in the present specification.

The first contact portion 54A of FIG. 10D is obtained by, in the flow of the process of manufacturing shown in FIG. 8 and FIG. 9, forming the oxide layer 66 by the etching of the first alloy layer 63, and then removing the oxide layer 66. The first barrier metal layer 60 of the present example does not have the metal film 69 and the lower layer barrier metal portion 61 below the upper layer barrier metal portion 62. That is, even in the structure in which the first barrier metal layer 60 is provided outside the contact hole 54 and above the interlayer dielectric film 38, and there is no plug layer 64 in the contact hole 54, in the etching upon forming the oxide layer 66 on the first alloy layer 63, the metal film 69 and the lower layer barrier metal portion 61 may be completely removed.

Also, in the etching upon forming the oxide layer 66 on the first alloy layer 63, if the metal film 69 and the lower layer barrier metal portion 61 remain without being completely removed, the structure is similar to that shown in FIG. 2E.

In the above example, an example in which, in the mesa portion of the transistor portion, the first contact portion 54A does not have the oxide layer 66 on the emitter region 12 and the contact region 15 in a similar manner is described by using an example in which the second contact portion 54B has the oxide layer 66 on the emitter region 12 and the contact region 15 in a similar manner, but it is not limited thereto. In the transistor portion 70, the first contact portion 54A and the second contact portion 54B may be distinguished according to the presence or absence of the oxide layer 66 on the contact region 15.

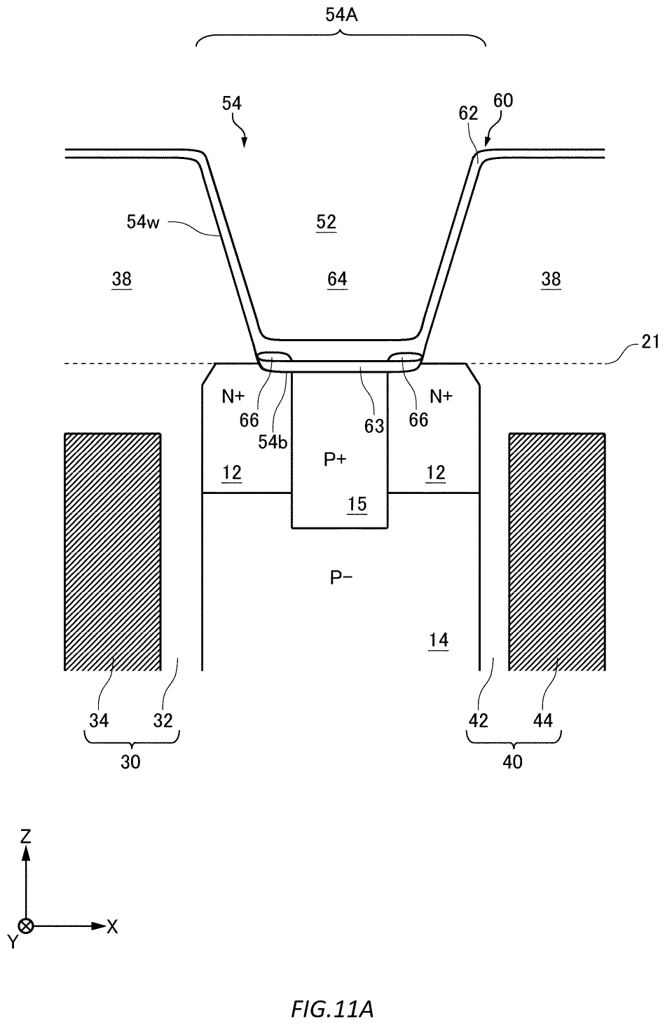

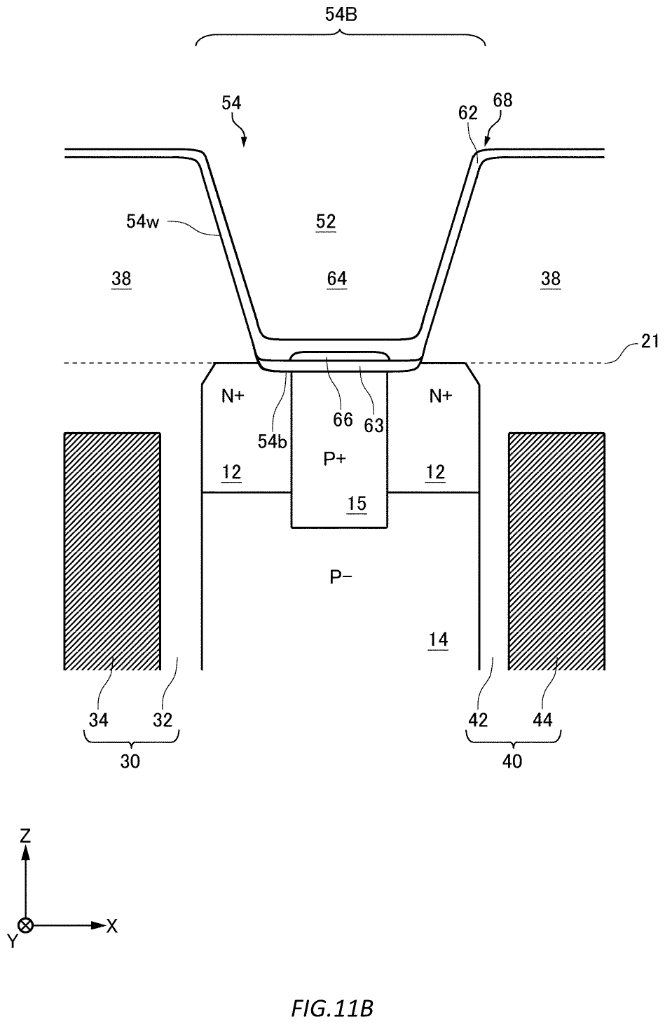

The cross section in FIG. 11A is an X-Z cross section passing through the contact region 15 on the front surface 21 of the semiconductor substrate 10. In the present example, an enlarged view of a cross section near the first contact portion 54A according to the modification example is shown. In the present example, a structure in which the contact region 15 is positioned at the center of the mesa portion, and the emitter region 12 is provided to be in contact with the trench portion is described as an example. The present example is different from the structure shown in FIG. 10D in that the oxide layer 66 is on the emitter region 12. Another structure may be any configuration shown in the present specification. That is, the lower layer barrier metal portion 61, the metal film 69, the first barrier metal layer 60, the plug layer 64, and the emitter electrode 52 may be any configuration shown in the present specification.

The first contact portion 54A of FIG. 11A is obtained by, in the flow of the process of manufacturing shown in FIG. 8 and FIG. 9, forming the oxide layer 66 by the etching of the first alloy layer 63, and removing the oxide layer 66 at the upper portion of the contact region 15 in the first contact portion 54A.

The cross section in FIG. 11B is an X-Z cross section passing through the contact region 15 on the front surface 21 of the semiconductor substrate 10. In the present example, an enlarged view of a cross section near the second contact portion 54B according to a modification example is shown. In the present example, a structure in which the contact region 15 is positioned at the center of the mesa portion, and the emitter region 12 is provided to be in contact with the trench portion is described as an example. The present example is different from the structure shown in FIG. 3E in that no oxide layer 66 is on the emitter region 12. Another structure may be any configuration shown in the present specification. That is, the lower layer barrier metal portion 61, the metal film 69, the second barrier metal layer 68, the plug layer 64, and the emitter electrode 52 may be any configuration shown in the present specification.

The second contact portion 54B of FIG. 11B is obtained by, in the flow of the process of manufacturing shown in FIG. 8 and FIG. 9, forming the oxide layer 66 by the etching of the first alloy layer 63, and removing the oxide layer 66 also at the upper portion of the emitter region 12 of the second contact portion 54B upon removing the oxide layer 66 in the first contact portion 54A.

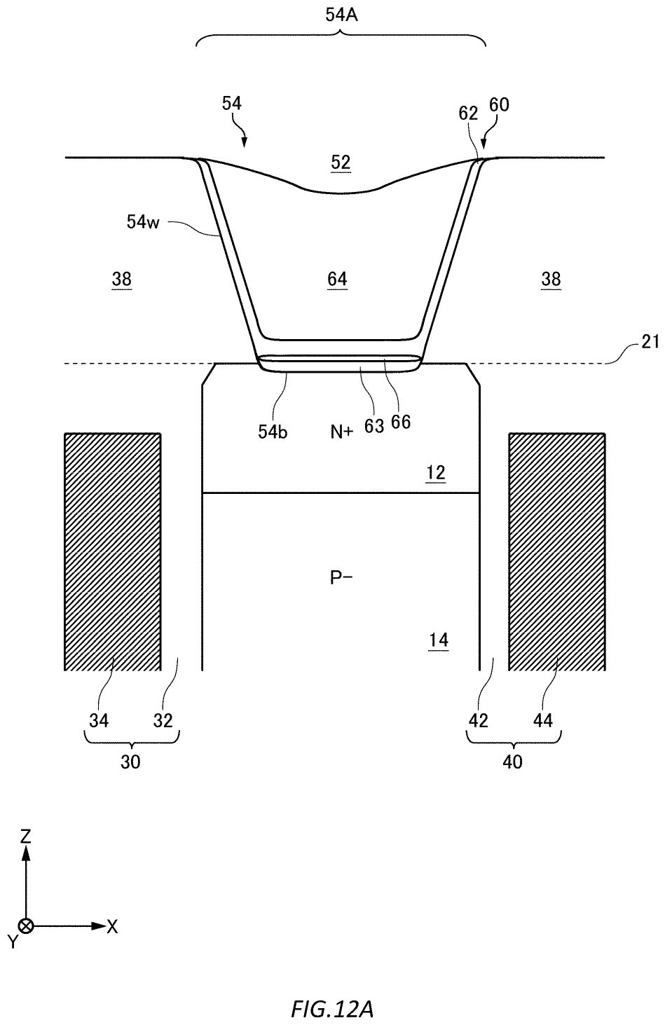

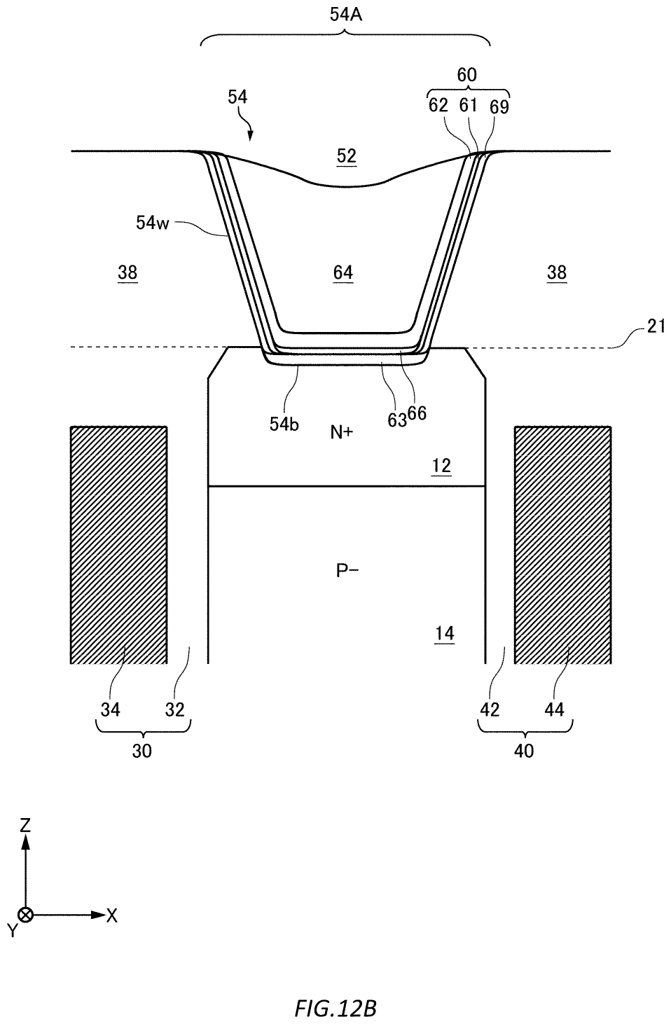

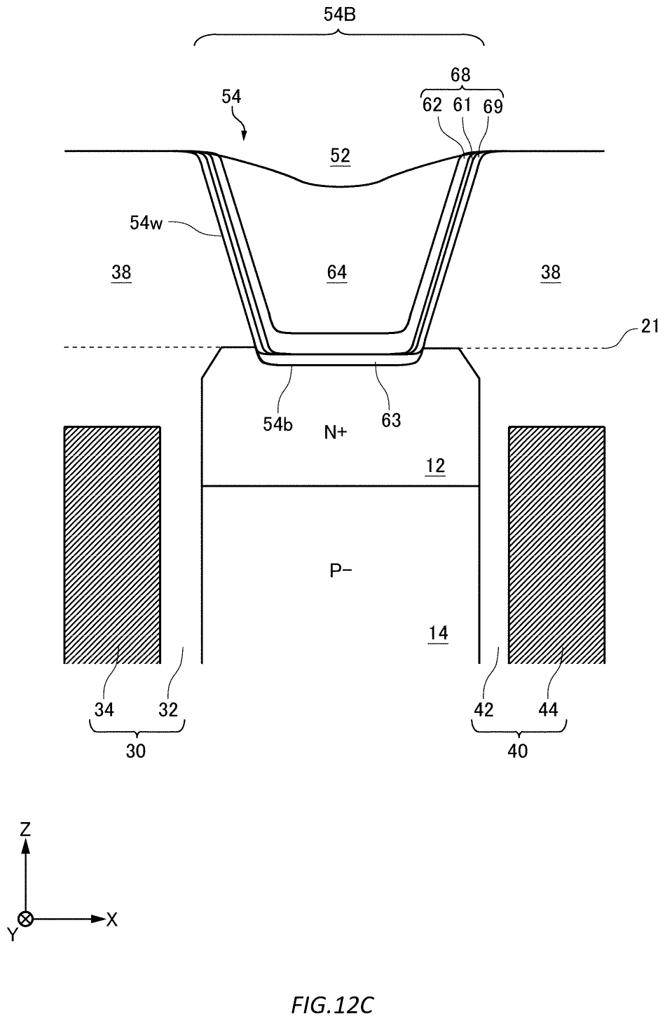

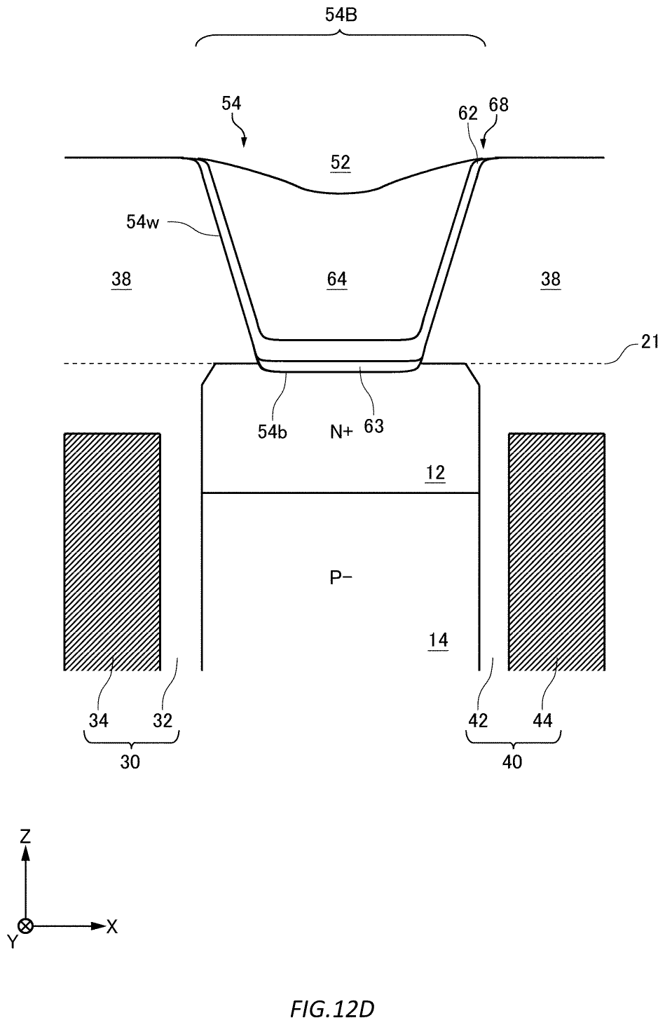

The cross section of FIG. 12A is an X-Z cross section passing through the emitter region 12 on the front surface 21 of the semiconductor substrate 10. In the present example, an enlarged view of a cross section near the first contact portion 54A according to the modification example is shown. In the present example, a structure in which the contact region 15 and the emitter region 12 are alternately arranged along the trench portion is described as an example. The present example is different from the example in which the structure shown in FIG. 10A is applied to the upper portion of the emitter region 12 in that it has the oxide film on the emitter region 12. Another structure may be any configuration shown in the present specification. That is, the first barrier metal layer 60, the plug layer 64, and the emitter electrode 52 may be any configuration shown in the present specification.

The first contact portion 54A of FIG. 12A is obtained by, in the flow of the process of manufacturing shown in FIG. 8 and FIG. 9, forming the oxide layer 66 by the etching of the first alloy layer 63, and removing the oxide layer 66 at the upper portion of the contact region 15 in the first contact portion 54A. At this time, the X-Z cross section passing through the contact region 15 is similar to that of FIG. 10A.

The cross section of FIG. 12B is an X-Z cross section passing through the emitter region 12 on the front surface 21 of the semiconductor substrate 10. In the present example, an enlarged view of a cross section near the first contact portion 54A according to the modification example is shown. In the present example, a structure in which the contact region 15 and the emitter region 12 are alternately arranged along the trench portion is described as an example. The present example is different from FIG. 2A in that the oxide film is on the emitter region 12. Another structure may be any configuration shown in the present specification. That is, the first barrier metal layer 60, the plug layer 64, and the emitter electrode 52 may be any configuration shown in the present specification.

The first contact portion 54A of FIG. 12B is obtained by, in the flow of the process of manufacturing shown in FIG. 8 and FIG. 9, forming the oxide layer 66 by the etching of the first alloy layer 63, and removing the oxide layer 66 at the upper portion of the contact region 15 in the first contact portion 54A. At this time, the X-Z cross section passing through the contact region 15 is similar to that of FIG. 2B. In the first contact portion 54A of the emitter region 12 and the contact region 15 shown in FIG. 12A and FIG. 10A, the lower layer barrier metal portion 61 and the metal film 69 are completely removed, but in the example shown in FIG. 12B and the FIG. 2B, an example in which the lower layer barrier metal portion 61 and the metal film 69 remain without completely removed is shown. Alternatively, the oxide layer 66 may be formed by a method that is performed without etching the first alloy layer 63, for example, a method in which the first alloy layer 63 is formed by deposition or the like, and then partially removed.

Otherwise, the X-Z cross section passing through the emitter region 12 and the contact region 15 of the first contact portion 54A may be similar to that shown in FIG. 12A and FIG. 2A, or FIG. 12B and FIG. 10A.

The cross section of FIG. 12C is an X-Z cross section passing through the emitter region 12 on the front surface 21 of the semiconductor substrate 10. In the present example, an enlarged view of a cross section near the second contact portion 54B according to a modification example is shown. In the present example, a structure in which the contact region 15 and the emitter region 12 are alternately arranged along the trench portion is described as an example. The present example is different from FIG. 4A in that there is no oxide layer 66 is on the emitter region 12. Another structure may be any configuration shown in the present specification. That is, the second barrier metal layer 68, the plug layer 64, and the emitter electrode 52 may be any configuration shown in the present specification.

The second contact portion 54B of FIG. 12C is an example in which the oxide layer 66 is formed by etching only the first alloy layer 63 on the contact region 15 of the second contact portion 54B in the flow of the process of manufacturing shown in FIG. 8. Alternatively, the second contact portion 54B of FIG. 12C is obtained by, in the flow of the process of manufacturing shown in FIG. 8 and FIG. 9, forming the oxide layer 66 by the etching of the first alloy layer 63, and removing the oxide layer 66 also at the upper portion of the emitter region 12 of the second contact portion 54B upon removing the oxide layer 66 in the first contact portion 54A, and is an example in which the lower layer barrier metal portion 61 or the metal film 69 remains without being completely removed. Alternatively, the oxide layer 66 may be formed by a method that is performed without etching the first alloy layer 63, for example, a method in which the first alloy layer 63 is formed by deposition or the like, and then partially removed. At this time, the X-Z cross section passing through the contact region 15 is similar to that of FIG. 3B or FIG. 4B.

The cross section of FIG. 12D is an X-Z cross section passing through the emitter region 12 on the front surface 21 of the semiconductor substrate 10. In the present example, an enlarged view of a cross section near the second contact portion 54B according to a modification example is shown. In the present example, a structure in which the contact region 15 and the emitter region 12 are alternately arranged along the trench portion is described as an example. The present example is different from FIG. 3A in that there is no oxide layer 66 is on the emitter region 12. Another structure may be any configuration shown in the present specification. That is, the second barrier metal layer 68, the plug layer 64, and the emitter electrode 52 may be any configuration shown in the present specification.

The second contact portion 54B of FIG. 12D is obtained by, in the flow of the process of manufacturing shown in FIG. 8 and FIG. 9, forming the oxide layer 66 by the etching of the first alloy layer 63, and removing the oxide layer 66 also at the upper portion of the emitter region 12 of the second contact portion 54B upon removing the oxide layer 66 in the first contact portion 54A. At this time, the X-Z cross section passing through the contact region 15 is similar to that of FIG. 3B.

Otherwise, the X-Z cross section passing through the emitter region 12 and the contact region 15 of the second contact portion 54B may be similar to that shown in FIG. 12D and FIG. 4B.

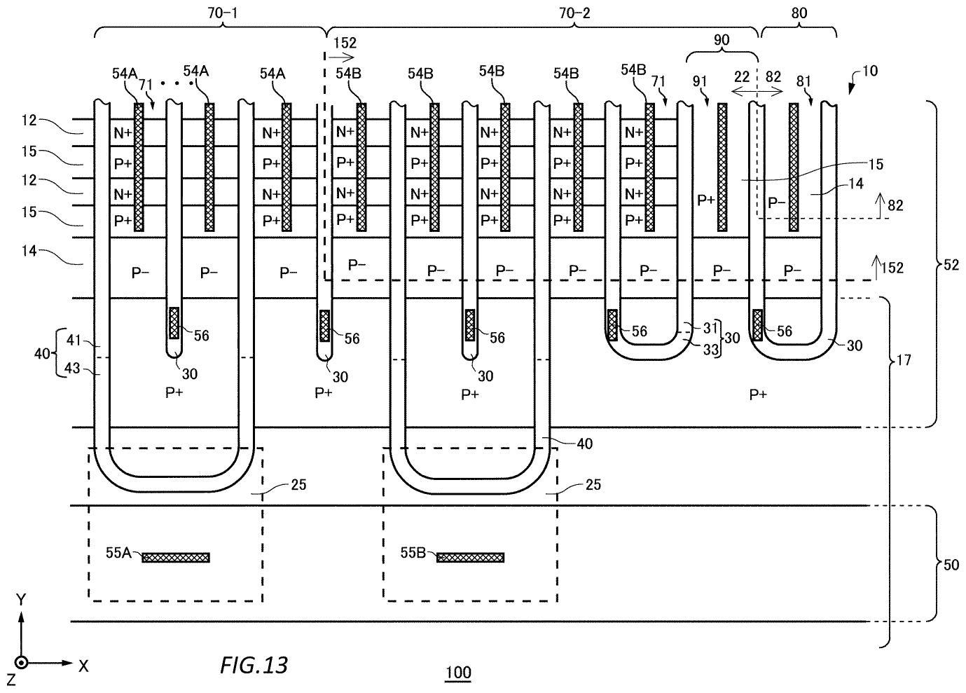

FIG. 13 shows another example of a top view of the semiconductor device 100. The present figure is an enlarged view of the upper surface of the region A in FIG. 1A. Each of the first contact portion 55A and the second contact portion 55B of the present example refers to a region including a contact hole 55 and an inside structure thereof, and has a common structure with that of the first contact portion 54A and the second contact portion 54B. The first contact portion 55A of the present example is electrically connected to the gate trench portion 40 provided in the first region 70-1 via the connection portion 25, and the second contact portion 55B of the present example is electrically connected to the gate trench portion 40 provided in the second region 70-2 via the connection portion 25.

The first contact portion 55A and the second contact portion 55B of the present example are provided below the gate metal layer 50, and are electrically connected to the gate metal layer 50. That is, the first contact portion 55A of the present example electrically connects the gate trench portion 40 provided in the first region 70-1 to the gate metal layer 50, and the second contact portion 55B of the present example electrically connects the gate trench portion 40 provided in the second region 70-2 to the gate metal layer 50. The connection portion 25 of the present example is not provided to be extended in the X axis direction as in FIG. 1B, but is provided in accordance with each contact hole 55.

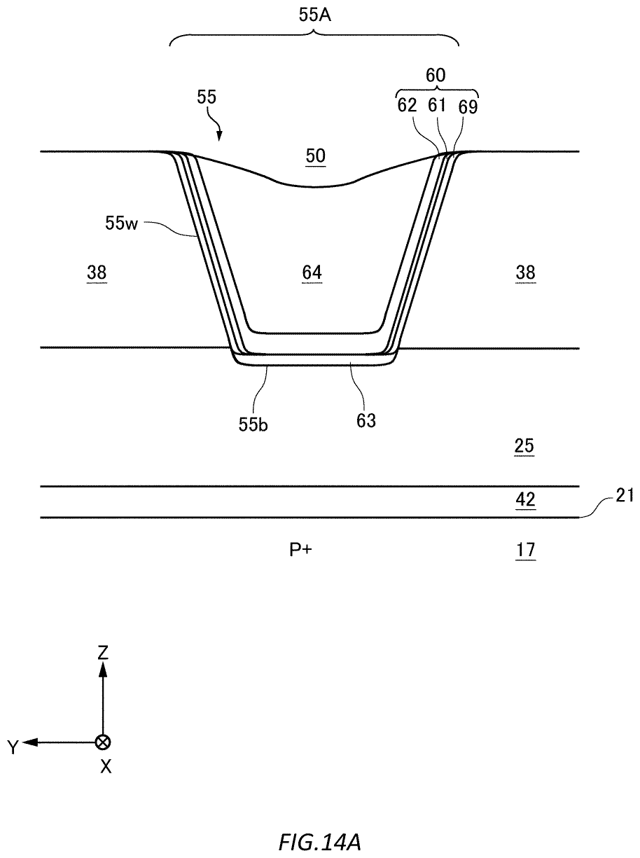

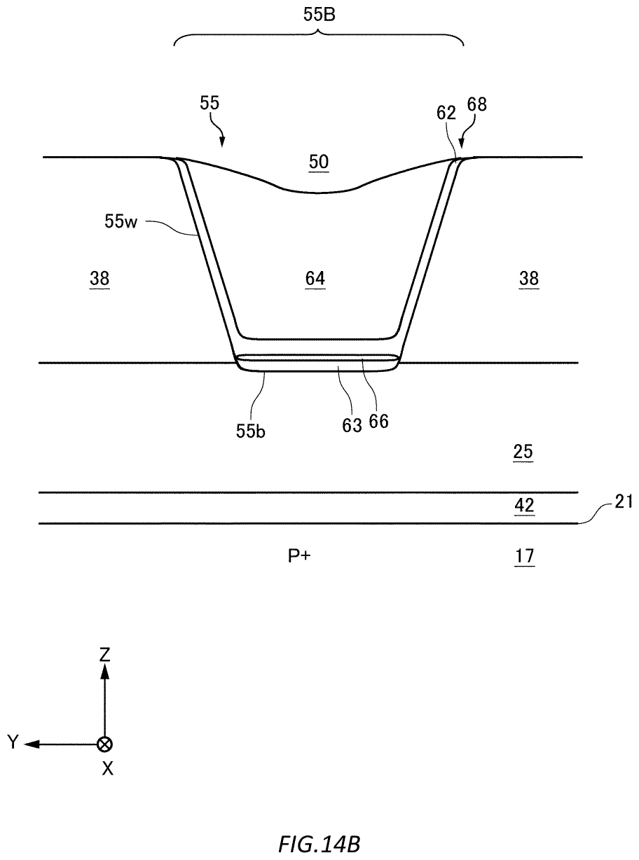

FIG. 14A is an enlarged view of a cross section of the semiconductor device 100. FIG. 14A is a Y-Z cross section near the first contact portion 55A shown in FIG. 13. The first contact portion 55A of the present example comprises a contact hole 55, a first barrier metal layer 60, a first alloy layer 63, and a plug layer 64. In the present specification, for convenience, an inner wall among the inner walls of the contact hole 55, which is upper than the front surface 21 of the semiconductor substrate 10 is described as a side wall 55w, and an inner wall among the inner walls of the contact hole 55, which is lower than the front surface 21 of the semiconductor substrate 10 is described as a bottom surface 55b. The first contact portion 55A of the present example has a structure similar to that of the first contact portion 54A of FIG. 2A. The first contact portion 55A of the present example may have a structure such as the first contact portion 54A or the first trench contact portion 65A described by using FIG. 2B and figures after FIG. 2B.

The first contact portion 55A of the present example is in contact with the connection portion 25 at the bottom surface 55b of the contact hole 55. The connection portion 25 may be provided on the front surface 21 of the semiconductor substrate 10 via the gate dielectric film 42. The connection portion 25 may be provided above the well region 17. The first contact portion 55A of the present example electrically connects the gate metal layer 50 to the connection portion 25.

FIG. 14B is an enlarged view of a cross section of the semiconductor device 100. FIG. 14B is a Y-Z cross section near the second contact portion 55B shown in FIG. 13. The second contact portion 55B of the present example comprises a contact hole 55, a second barrier metal layer 68, a first alloy layer 63, a plug layer 64, and an oxide layer 66. The second contact portion 55B of the present example has a structure similar to that of the second contact portion 54B of FIG. 3A. The second contact portion 55B of the present example may have a structure such as the second contact portion 54B or the second trench contact portion 65B described by using FIG. 3B and figures after FIG. 3B.

The second contact portion 55B of the present example is in contact with the connection portion 25 at the bottom surface 55b of the contact hole 55. The connection portion 25 may be provided on the front surface 21 of the semiconductor substrate 10 via the gate dielectric film 42. The connection portion 25 may be provided above the well region 17. The second contact portion 55B of the present example electrically connects the gate metal layer 50 to the connection portion 25.

In this manner, by further providing the first contact portion 55A and the second contact portion 55B, it is possible to finely perform suppression of variation in the threshold voltage of the transistor portion 70, suppression of the latch-up, conduction of the diode portion 80, and adjustment of the characteristic during reverse recovery.

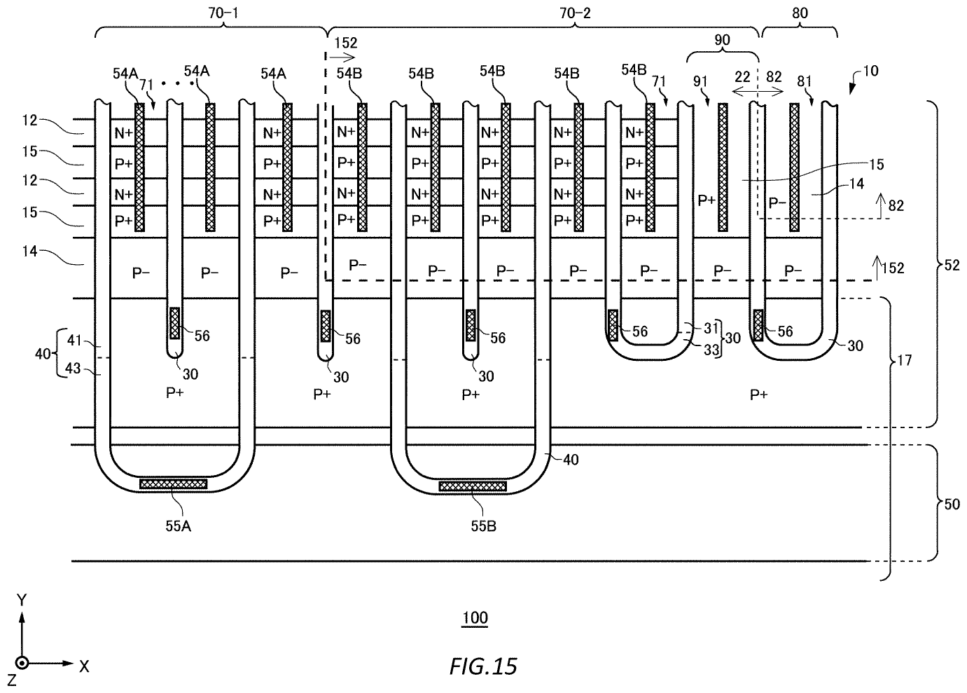

FIG. 15 shows another example of a top view of the semiconductor device 100. The present figure is an enlarged view of the upper surface of the region A in FIG. 1A. The semiconductor device 100 of FIG. 15 is different from that of FIG. 13 in that the first contact portion 55A and the second contact portion 55B are provided above the gate trench portion 40. Herein, descriptions common with those of the semiconductor device 100 shown in FIG. 13 are omitted, and differences are mainly described.

The semiconductor device 100 of the present example is not provided with the connection portion 25. The first contact portion 55A of the present example is connected to the gate trench portion 40 provided in the first region 70-1, and the second contact portion 54B of the present example is connected to the gate trench portion 40 provided in the second region 70-2. That is, the first contact portion 55A of the present example electrically connects the gate trench portion 40 provided in the first region 70-1 to the gate metal layer 50, and the second contact portion 55B of the present example electrically connects the gate trench portion 40 provided in the second region 70-2 to the gate metal layer 50.

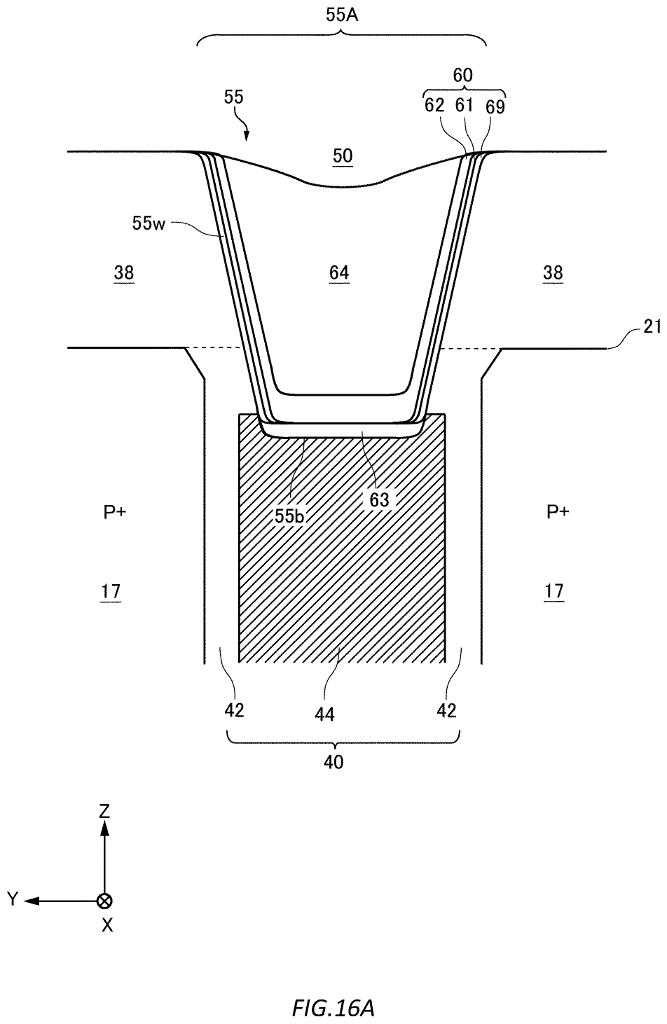

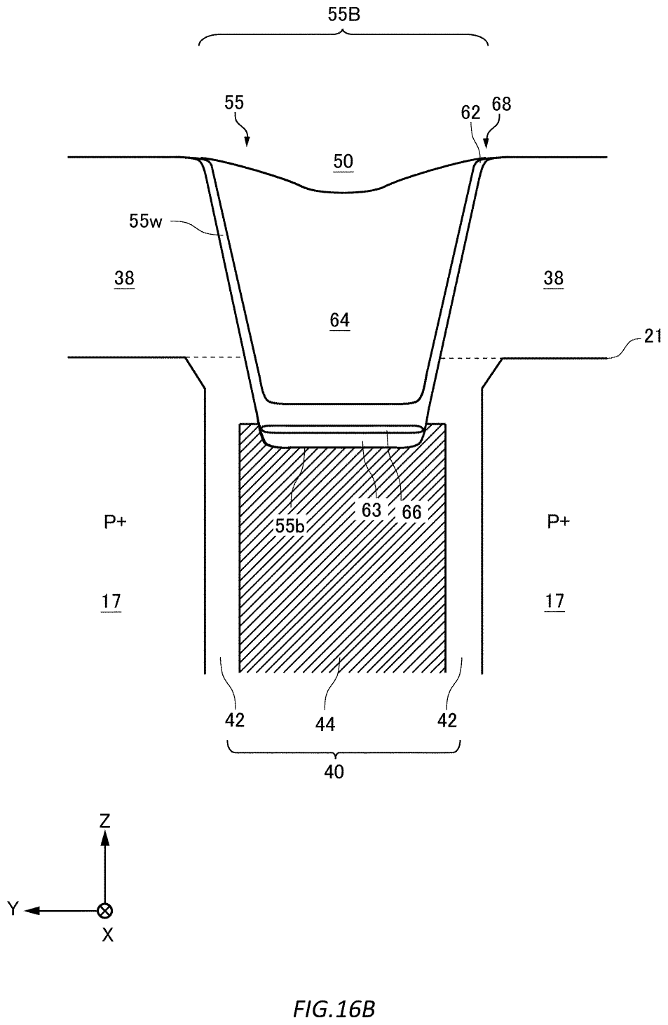

FIG. 16A is an enlarged view of a cross section of the semiconductor device 100. FIG. 16A is a Y-Z cross section near the first contact portion 55A shown in FIG. 15. The first contact portion 55A of the present example is in contact with the gate conductive portion 44 of the gate trench portion 40 at the bottom surface 55b of the contact hole 55. That is, the first contact portion 55A of the present example is directly coupled to the gate trench portion 40, and electrically connects the gate trench portion 40 to the gate metal layer 50.

FIG. 16B is an enlarged view of a cross section of the semiconductor device 100. FIG. 16B is a Y-Z cross section near the second contact portion 55B shown in FIG. 15. The second contact portion 55B of the present example is in contact with the gate conductive portion 44 of the gate trench portion 40 at the bottom surface 55b of the contact hole 55. That is, the second contact portion 55B of the present example is directly coupled to the gate trench portion 40, and electrically connects the gate trench portion 40 to the gate metal layer 50.

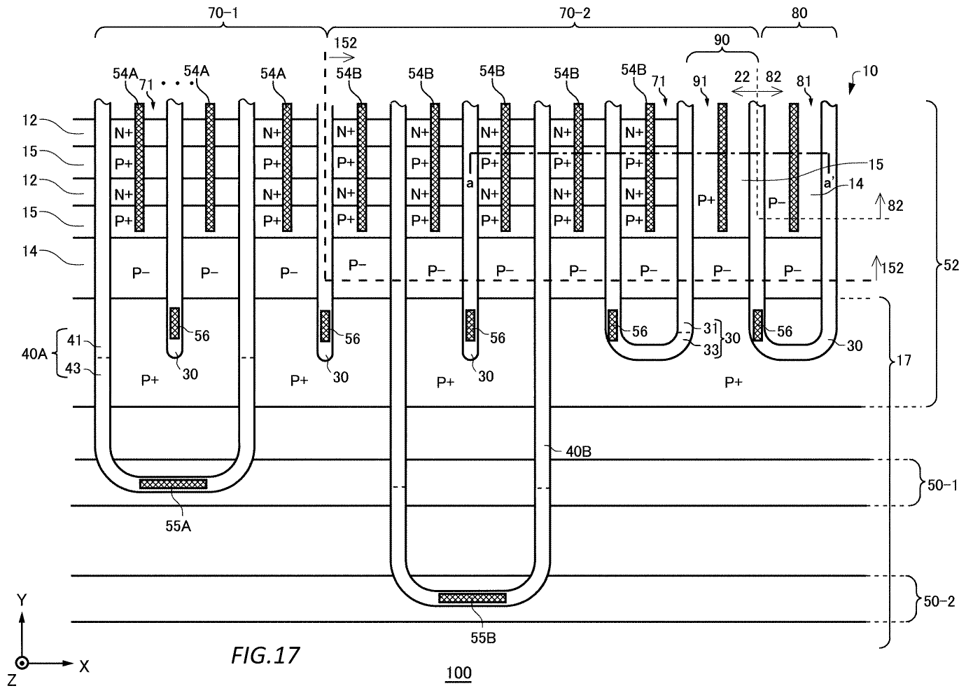

FIG. 17 shows another example of a top view of the semiconductor device 100. The present figure is an enlarged view of the upper surface of the region A in FIG. 1A. The gate trench portion 40 of FIG. 17 is different from that of FIG. 13 in that it has a first gate trench portion 40A, and a second gate trench portion 40B that extends further than the first gate trench portion 40A. Also, the gate metal layer 50 of the present example has a first gate metal layer 50-1, and a second gate metal layer 50-2 that extends outside (in FIG. 17, a negative side in the Y axis direction) further than the first gate metal layer 50-1 in a top view of the semiconductor substrate 10. Herein, descriptions common with those of the semiconductor device 100 shown in FIG. 15 are omitted, and differences are mainly described.

The first gate trench portion 40A of the present example is the gate trench portion 40 provided in the first region 70-1 of the transistor portion 70, and the second gate trench portion 40B of the present example is the gate trench portion 40 provided in the second region 70-2 of the transistor portion 70. The first gate trench portion 40A of the present example is electrically connected to the first gate metal layer 50-1 via the first contact portion 55A, and the second gate trench portion 40B of the present example extends beyond the first gate metal layer 50-1 in a top view of the semiconductor substrate 10, and is electrically connected to the second gate metal layer 50-2 via the second contact portion 55B. Note that each of the first region 70-1 and the second region 70-2 of the present example is provided with both the first gate metal layer 50-1 and the second gate metal layer 50-2, but only one of the first gate metal layer 50-1 and the second gate metal layer 50-2 may be provided.

That is, in the present example, each of the gate trench portion 40 provided in the first region 70-1 of the transistor portion 70 and the gate trench portion 40 provided in the second region 70-2 are electrically connected to gate metal layers 50 that are different from each other. Thereby, it is possible to finely perform suppression of variation in the threshold voltage of the transistor portion 70, suppression of the latch-up, conduction of the diode portion 80, and adjustment of the characteristic during reverse recovery.

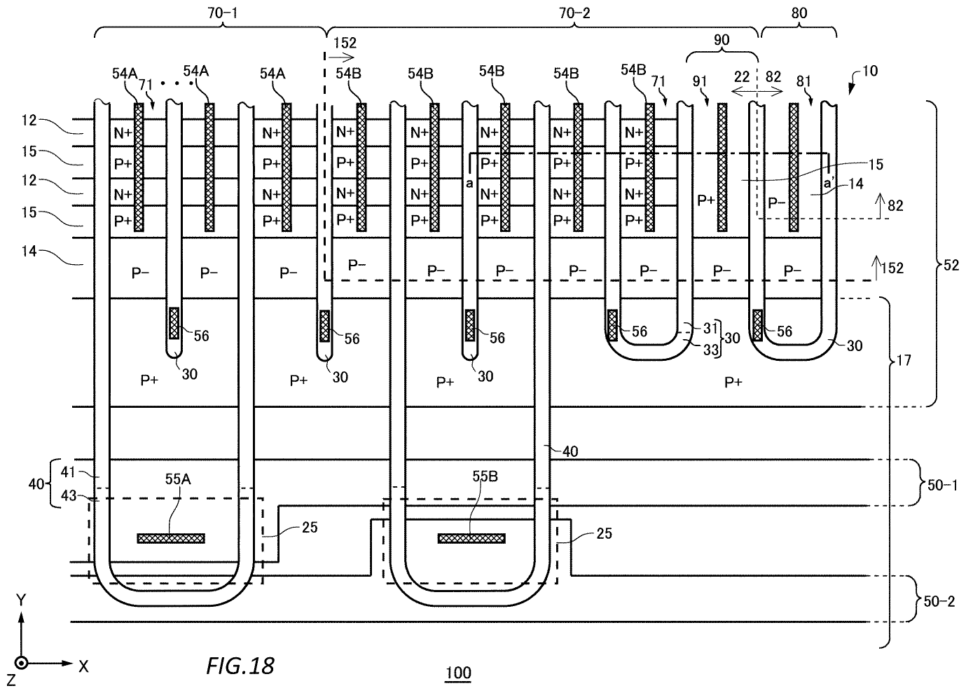

FIG. 18 shows another example of a top view of the semiconductor device 100. The present figure is an enlarged view of the upper surface of the region A in FIG. 1A. The semiconductor device 100 of FIG. 18 is common with FIG. 13 in that it comprises the connection portion 25, but is different from FIG. 13 in that the gate metal layer 50 has a first gate metal layer 50-1, and a second gate metal layer 50-2 that extends to the outside (in FIG. 18, a negative side in the Y axis direction) further than the first gate metal layer 50-1 in a top view of the semiconductor substrate 10. Also, the semiconductor device 100 of FIG. 18 is common with FIG. 17 in that it comprises a plurality of gate metal layers 50, but is different from FIG. 17 in that a plurality of gate trench portions 40 have the same length in the extending direction (the Y axis direction). Herein, descriptions common with those of the semiconductor device 100 shown in FIG. 13 or FIG. 17 are omitted, and differences are mainly described.

The first contact portion 55A of the present example is connected to the gate trench portion 40 provided in the first region 70-1 via the connection portion 25. As shown in FIG. 14A, the first contact portion 55A of the present example is in contact with the connection portion 25 at the bottom surface 55b of the contact hole 55. The second contact portion 54B of the present example is connected to the gate trench portion 40 provided in the second region 70-2 via the connection portion 25. As shown in FIG. 14B, the second contact portion 54B of the present example is in contact with the connection portion 25 at the bottom surface 55b of the contact hole 55.

The first gate metal layer 50-1 of the present example may extend in the same direction as the second gate metal layer 50-2 (in FIG. 18, the X axis direction), and have a protrusion on the second gate metal layer 50-2 side in a top view of the semiconductor substrate 10, and the first contact portion 55A of the present example may be provided below the protrusion of the first gate metal layer 50-1. The second gate metal layer 50-2 of the present example may have a protrusion on the first gate metal layer 50-1 side, and the second contact portion 54B of the present example may be provided below the protrusion of the second gate metal layer 50-2. The first contact portion 55A and the second contact portion 54B of the present example may be provided at the same position in the Y axis direction.

The first contact portion 55A and the second contact portion 55B of the present example electrically connect the different gate metal layer and connection portion 25. The first contact portion 55A of the present example is provided below the protrusion of the first gate metal layer 50-1, and is electrically connected to the first gate metal layer 50-1. The second contact portion 55B of the present example is provided below the protrusion of the second gate metal layer 50-2, and is electrically connected to the second gate metal layer 50-2. That is, the first contact portion 55A of the present example electrically connects the gate trench portion 40 provided in the first region 70-1 to the first gate metal layer 50-1, and the second contact portion 55B of the present example electrically connects the gate trench portion 40 provided in the second region 70-2 to the second gate metal layer 50-2.

In this manner, without providing the gate trench portion 40 having a different length, by providing a protrusion to each of the first gate metal layer 50-1 and the second gate metal layer 50-2, the plurality of gate trench portions 40 can be electrically connected to each of the plurality of gate metal layers 50.

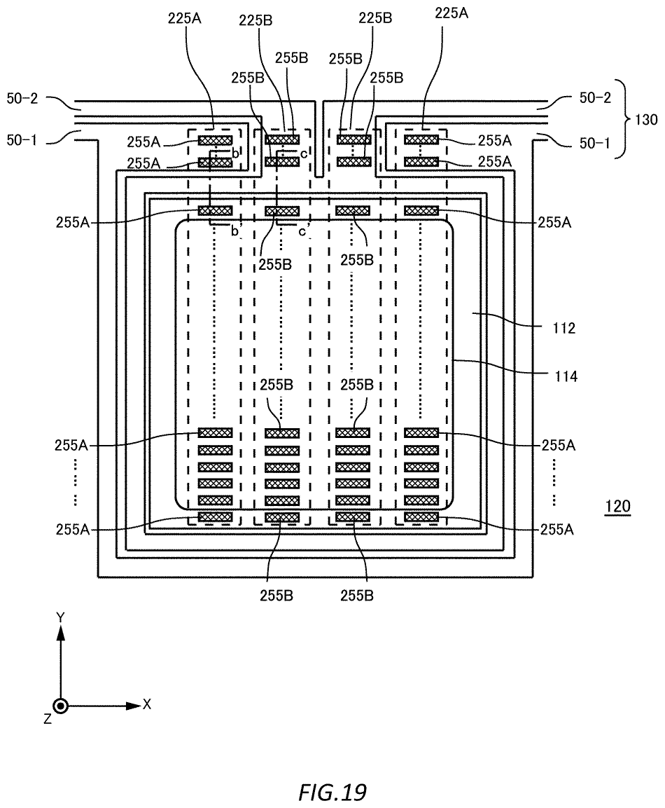

FIG. 19 shows an example of a top view of the gate pad 112. In the semiconductor device 100 of FIG. 19, the gate metal layer 50 includes the first gate metal layer 50-1 and the second gate metal layer 50-2 as shown in FIG. 17 or FIG. 18, but in another example, only one gate metal layer 50 may be connected to the gate pad 112. The gate pad 112, the first gate metal layer 50-1, and the second gate metal layer 50-2 of the present example are provided to be spaced apart from each other.

Similar to the emitter electrode 52, the gate pad 112 of the present example may be an electrode including a metal such as aluminum. The gate pad 112 is provided to be separated from the emitter electrode 52 in a top view of the semiconductor substrate 10. A protective film such as polyimide may be provided between each of the gate pad 112, the emitter electrode 52, the first gate metal layer 50-1, the second gate metal layer 50-2, on a part of the gate pad 112 and the emitter electrode 52, and above the first gate metal layer 50-1 and second gate metal layer 50-2, however, in FIG. 19, illustrations of the components other than the boundary that indicates an open region 114 of the gate pad 112 are omitted. In the upper surface of the gate pad 112, an open region 114 exposed by an opening of the protective film is included.

The semiconductor device 100 of the present example comprises a connection portion 225 provided below the gate pad 112. The connection portion 225 of the present example is provided above the front surface 21 of the semiconductor substrate 10 via an dielectric film or the like such as an oxide film. The connection portion 225 of the present example is a conductive material such as polysilicon doped with impurities. The connection portion 225 in the present example is polysilicon (N+) doped with impurities of the N type. The connection portion 225 of the present example may have a configuration that is the same as that of the connection portion 25. In another example, the connection portion 225 may be formed in a different process from the connection portion 25, or may have a different configuration, including the dielectric film below.

The connection portion 225 of the present example has a first connection portion 225A and a second connection portion 225B. The first connection portion 225A of the present example is electrically connected to the first gate metal layer 50-1, and the second connection portion 225B of the present example is electrically connected to the second gate metal layer 50-2.

Below the connection portion 225, the first contact portion 255A and the second contact portion 255B are provided. Each of the first contact portion 255A and the second contact portion 255B of the present example refers to a region including a contact hole 255 that is provided to pass through the interlayer dielectric film 38 and an inside structure thereof, and has a common structure with that of the first contact portion 55A and the second contact portion 55B. The first contact portion 255A of the present example electrically connects the first connection portion 225A to the first gate metal layer 50-1, and the second contact portion 255B of the present example electrically connects the second connection portion 225B to the second gate metal layer 50-2.

The first connection portion 225A and the second connection portion 225B of the present example may be provided below the open region 114 of the gate pad 112. In another example, the connection portion 225 may not be provided below the open region 114. The first contact portion 255A and the second contact portion 255B of the present example may be provided below the open region 114 of the gate pad 112 and below the protective film. In another example, in the gate pad 112, the first contact portion 255A or the second contact portion 255B may be only provided in either below the open region 114 or below the protective film. Each of the first connection portion 225A and the second connection portion 225B of the present example is formed to have the same outline, and the first contact portion 255A and the second contact portion 255B are provided at relatively the same position in the Y axis direction. In another example, the first contact portion 255A and the second contact portion 255B may be provided at a relatively different location in the Y axis direction of the first connection portion 225A and the second connection portion 225B, or the first connection portion 225A and the second connection portion 225B may be configured to have different shapes.

The first connection portion 225A and the second connection portion 225B of the present example protrude, from the gate pad 112, in an orientation opposite to the active portion 120 (a positive side in the Y axis direction, the end side 102 side), and are connected to the first gate metal layer 50-1 and the second gate metal layer 50-2, by the first contact portion 255A and the second contact portion 255B. In another example, the connection portion 225 may protrude to the active portion 120 side from the gate pad 112. The first connection portion 225A and the second connection portion 225B of the present example are respectively connected to the gate pad 112, the first gate metal layer 50-1, and the second gate metal layer 50-2, by the first contact portion 255A and the second contact portion 255B. In another example, only one of a contact hole 255 connecting the first gate metal layer 50-1 and the second gate metal layer 50-2 or a contact hole 255 connecting the gate pad 112 may have separate structures like the first contact portion 255A and the second contact portion 255B.

The first contact portion 255A and the second contact portion 255B of the present example have a longitudinal length in the X axis direction. In another example, the longitudinal length may be included in any direction, may cross each other, or may have curvature. Note that in the present example, the first contact portion 255A and the second contact portion 255B are provided near the gate pad 112, and therefore, it is possible to perform the adjustment of characteristic finely even if a contact hole 55 that connects a gate trench portion 40 provided in the first region 70-1 to the first gate metal layer 50-1 or the connection portion 25, and each contact hole 55 that connects the gate trench portion 40 provided in the second region 70-2 to the second gate metal layer 50-2 or the connection portion 25, does not have separate structures like the first contact portion 55A and second contact portion 55B.

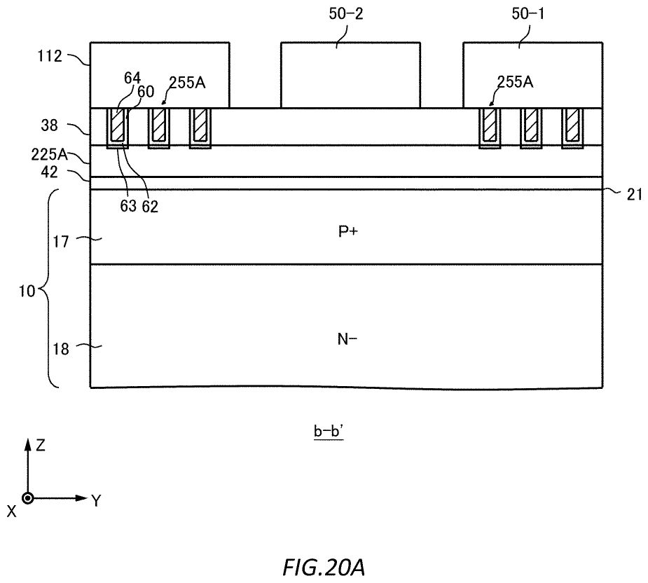

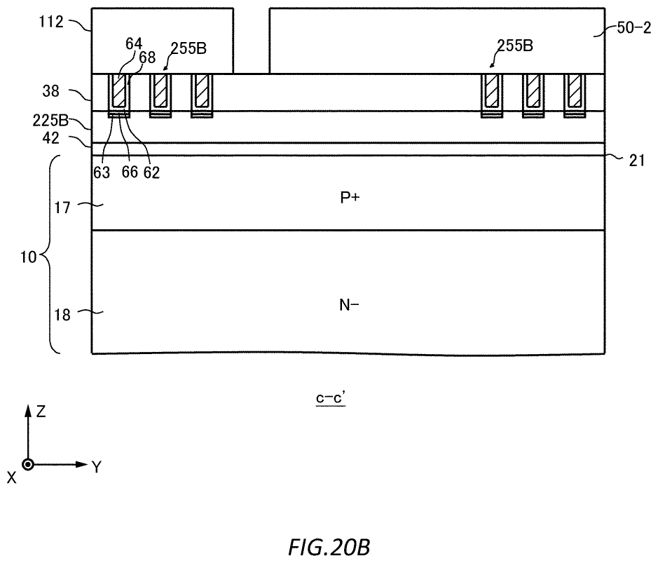

FIG. 20A shows an example of the cross section b-b′ in FIG. 19. The cross section b-b′ is a Y-Z cross section passing through the gate pad 112 and the first gate metal layer 50-1. The gate pad 112 and the first gate metal layer 50-1 of the present example are provided to be spaced apart from each other. The first contact portion 255A of the present example has a structure similar to that of the first contact portion 54A or the first trench contact portion 65A described by using FIG. 2A and figures after FIG. 2A.

The gate pad 112 of the present example is electrically connected to the first connection portion 225A via the first contact portion 255A. The first connection portion 225A may be provided on the front surface 21 of the semiconductor substrate 10 via the gate dielectric film 42. Also, the first gate metal layer 50-1 of the present example is also electrically connected to the first connection portion 225A via the first contact portion 255A. Thereby, the gate pad 112 of the present example is electrically connected to the first gate metal layer 50-1 while being provided to be spaced apart from the first gate metal layer 50-1.

FIG. 20B shows an example of the cross section c-c′ in FIG. 19. The cross section c-c′ is a Y-Z cross section passing through the gate pad 112 and the second gate metal layer 50-2. The gate pad 112 and the second gate metal layer 50-2 of the present example are provided to be spaced apart from each other. The second contact portion 255B of the present example has a structure similar to that of the second contact portion 54B or the second trench contact portion 65B described by using FIG. 3A and figures after FIG. 3A.

In FIG. 20B, the gate pad 112 is electrically connected to the second connection portion 225B via the second contact portion 255B. The second connection portion 225B may be provided on the front surface 21 of the semiconductor substrate 10 via the gate dielectric film 42. Also, the second gate metal layer 50-2 of the present example is also electrically connected to the second connection portion 225B via the second contact portion 255B. Thereby, the gate pad 112 of the present example is electrically connected to the second gate metal layer 50-2 while being provided to be spaced apart from the second gate metal layer 50-2.

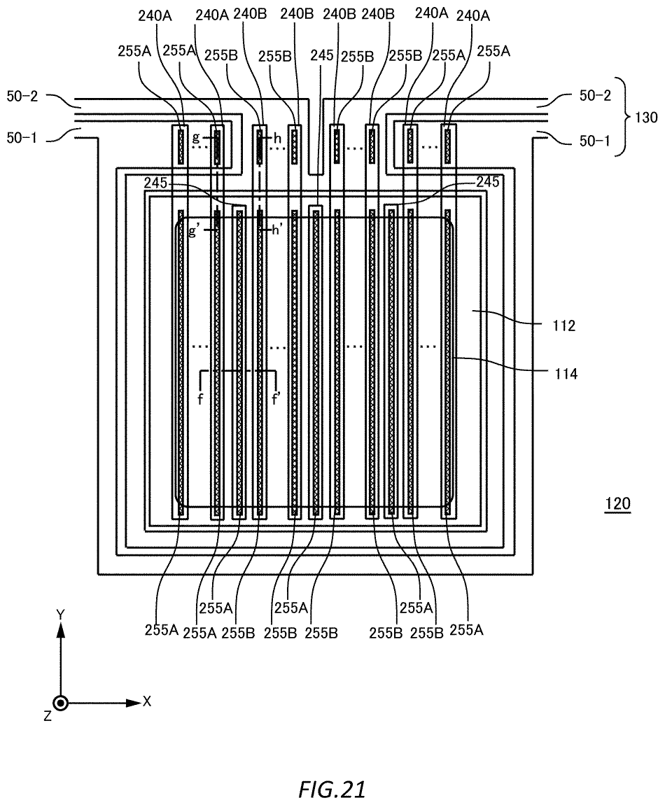

FIG. 21 shows another example of a top view of the gate pad 112. FIG. 21 is different from FIG. 19 in that at least one or more connection trench portion 240 instead of the connection portion 225 is included, that is, a first connection trench portion 240A and a second connection trench portion 240B instead of the first connection portion 225A and the second connection portion 225B are included. The connection trench portion 240 has a connection trench provided on the front surface 21 of the semiconductor substrate 10, a connection trench dielectric film 242 such as an oxide film, and a conductive connection trench conductive portion 244. The connection trench dielectric film 242 of the present example is formed to cover the inner wall of the connection trench. Inside the connection trench, the connection trench conductive portion 244 of the present example is formed closer to the inside than the connection trench dielectric film 242. The connection trench conductive portion 244 of the present example is insulated from the semiconductor substrate 10 via the connection trench dielectric film 242 or the like. The connection trench conductive portion 244 may be polysilicon or the like doped with impurities. The connection trench conductive portion 244 of the present example is polysilicon (N+) doped with impurities of the N type. For another component, a structure described by using FIG. 19, FIG. 20A, and FIG. 20B may be included.

Below the first gate metal layer 50-1 of the present example, the first contact portion 255A is provided, and below the second gate metal layer 50-2 of the present example, the second contact portion 255B is provided. Below the gate pad 112 of the present example, the first contact portion 255A and the second contact portion 255B are provided.

Below the first contact portion 255A provided below the first gate metal layer 50-1 and the first contact portion 255A provided below the gate pad 112, the first connection trench portion 240A is provided. Thereby, the gate pad 112 of the present example is electrically connected to the first gate metal layer 50-1 via the first connection trench conductive portion 244A and the first contact portion 255A. Similarly, below the second contact portion 255B provided below the second gate metal layer 50-2 and the second contact portion 255B provided below the gate pad 112, the second connection trench portion 240B is provided. Thereby, the gate pad 112 of the present example is electrically connected to the second gate metal layer 50-2 via the second connection trench conductive portion 244B and the second contact portion 255B.

The connection trench portion 240 may be simultaneously formed with the gate trench portion 40, and may be insulated from the semiconductor substrate 10 by the gate dielectric film 42 and have the gate conductive portion 44 inside. In another example, the connection trench portion 240 may be formed separately from the gate trench portion 40, to have a different structure. The connection trench portion 240 of the present example is formed to have a striped shape spaced apart from each other in a top view of the semiconductor substrate 10. In another example, each connection trench portion 240 may be bent, branched or crossed at the end portion or halfway in a top view of the semiconductor substrate 10.

Below the gate pad 112, the connection trench portion 240 of the present example is provided between the first connection trench portion 240A and the second connection trench portion 240B in a top view of the semiconductor substrate 10, and has a dummy connection trench portion 245 that is only connected to the gate pad 112. The dummy connection trench portion 245 has a dummy connection trench provided on the front surface 21 of the semiconductor substrate 10, a connection trench dielectric film 242, and a conductive dummy connection trench conductive portion 249. The connection trench dielectric film 242 of the present example is formed to cover the inner wall of the dummy connection trench. Inside the dummy connection trench, the dummy connection trench conductive portion 249 of the present example is formed closer to the inside than the connection trench dielectric film 242. The dummy connection trench portion 245 of the present example is insulated from the semiconductor substrate 10 via the connection trench dielectric film 242 or the like. The dummy connection trench conductive portion 249 may be polysilicon doped with impurities.

In another example, the dummy connection trench portion 245 may be provided only below the open region 114 of the gate pad 112, or may be provided to outside of the gate pad 112. In another example, the dummy connection trench portion 245 may be provided, in a top view of the semiconductor substrate 10, between the first connection trench portions 240A or between the second connection trench portions 240B, or outside the first connection trench portion 240A or the second connection trench portion 240B. Above the dummy connection trench portion 245 of the present example, a contact hole 255 having the same size as that of the first contact portion 255A or the second contact portion 255B provided above the first connection trench portion 240A or the second connection trench portion 240B is provided, but in another example, a contact hole 255 with a different size from that of the first contact portion 255A or the second contact portion 255B provided above the first connection trench portion 240A or the second connection trench portion 240B may be provided. In the present example, the first contact portion 255A is provided above the dummy connection trench portion 245, but in another example, the second contact portion 255B may be provided and the contact hole 255 may not be provided. In another example, the dummy connection trench portion 245 may not be provided.

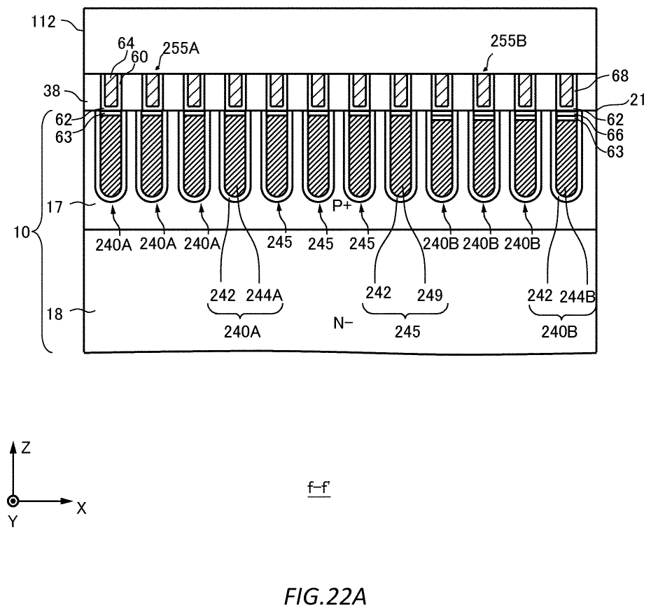

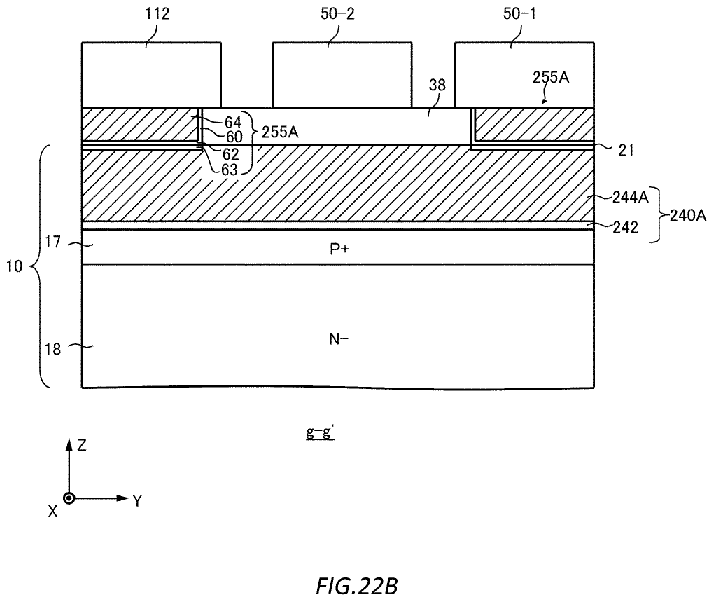

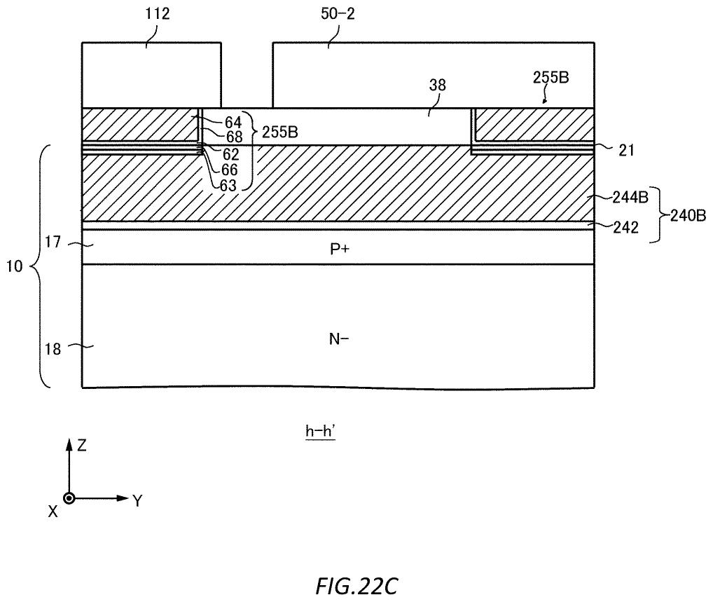

FIG. 22A shows an example of the cross section f-f′ in FIG. 21. The cross section f-f′ is an X-Z cross section passing through the gate pad 112, the first connection trench portion 240A, the second connection trench portion 240B, and the dummy connection trench portion 245. Above the first connection trench portion 240A provided below the gate pad 112, the first contact portion 255A is provided. The first contact portion 255A of the present example may have a structure such as the first contact portion 54A or the first trench contact portion 65A described by using FIG. 2A and figures after FIG. 2A. Thereby, the gate pad 112 of the present example is electrically connected to the first gate metal layer 50-1 via the first connection trench conductive portion 244A and the first contact portion 255A. Similarly, above the second connection trench portion 240B provided below the gate pad 112, the second contact portion 255B is provided. The second contact portion 255B of the present example may have a structure such as the second contact portion 54B or the second trench contact portion 65B described by using FIG. 3A and figures after FIG. 3A. Thereby, the gate pad 112 of the present example is electrically connected to the second gate metal layer 50-2 via the second connection trench conductive portion 244B and the second contact portion 255B.

FIG. 22B shows an example of cross section g-g′ in FIG. 21. The cross section g-g′ is a Y-Z cross section passing through the gate pad 112 and the first gate metal layer 50-1. The gate pad 112 and the first gate metal layer 50-1 of the present example are provided to be spaced apart from each other.

The gate pad 112 of the present example is electrically connected to the first connection trench conductive portion 244A via the first contact portion 255A. The first connection trench conductive portion 244A may be provided on the front surface 21 of the semiconductor substrate 10 via the connection trench dielectric film 242. Also, the first gate metal layer 50-1 of the present example is also electrically connected to the first connection portion 225A via the first contact portion 255A. Thereby, the gate pad 112 of the present example is electrically connected to the first gate metal layer 50-1 while being provided to be spaced apart from the first gate metal layer 50-1.

FIG. 22C shows an example of the cross section h-h′ in FIG. 21. The cross section h-h′ is a Y-Z cross section passing through the gate pad 112 and the second gate metal layer 50-2. The gate pad 112 and the second gate metal layer 50-2 of the present example are provided to be spaced apart from each other.

In FIG. 22C, the gate pad 112 is electrically connected to the second connection trench conductive portion 244B via the second contact portion 255B. The second connection trench conductive portion 244B may be provided on the front surface 21 of the semiconductor substrate 10 via the connection trench dielectric film 242. Also, the second gate metal layer 50-2 of the present example is also electrically connected to the second connection portion 225B via the second contact portion 255B. Thereby, the gate pad 112 of the present example is electrically connected to the second gate metal layer 50-2 while being provided to be spaced apart from the second gate metal layer 50-2.

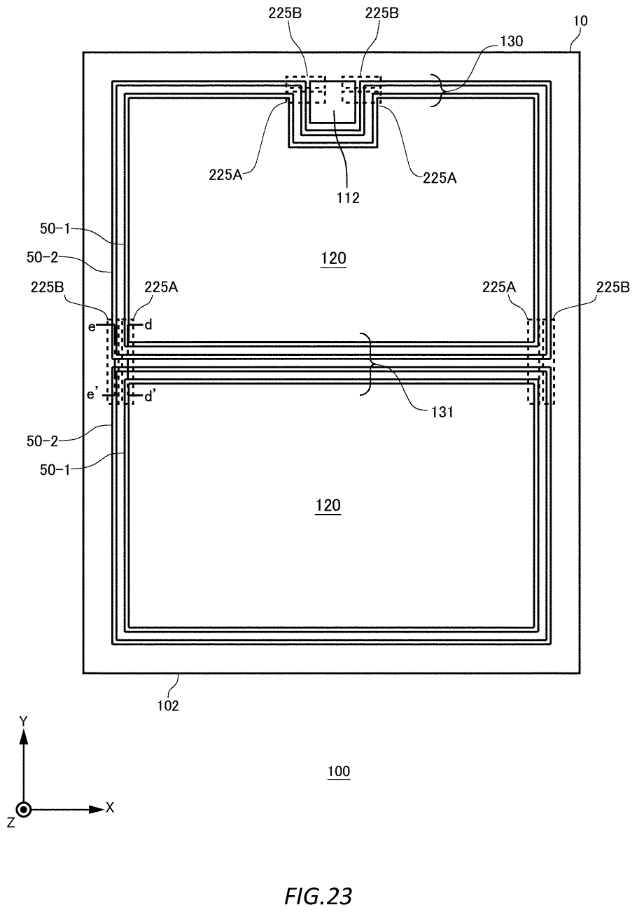

FIG. 23 shows another example of a top view of the semiconductor device 100. The semiconductor device 100 of FIG. 23 has two active portions 120 arranged side by side in the Y axis direction, and is provided to have the first gate metal layer 50-1 and the second gate metal layer 50-2 surrounding each active portion 120 in a top view of the semiconductor substrate 10. Herein, surrounding is not limited to that the first gate metal layer 50-1 and the second gate metal layer 50-2 continuously circulates, but may mean that there is a region in which the gate metal layer 50 is not extending, as long as the gate trench portion 40 of the active portion 120 is arranged to be connected to at least any of the first gate metal layer 50-1 or the second gate metal layer 50-2. In the active portion 120, an emitter electrode 52 is provided above the semiconductor substrate 10, but illustration thereof is omitted in FIG. 23. The emitter electrode 52, and the first gate metal layer 50-1 and the second gate metal layer 50-2 are provided to be spaced apart from each other. In the present example, in a top view of the semiconductor substrate 10, the first gate metal layer 50-1 is provided inside (the active portion 120 side), and the second gate metal layer 50-2 is provided outside (the end side 102 side).

The first gate metal layer 50-1 and the second gate metal layer 50-2 surrounding the active portion 120 on the positive side in the Y axis direction are electrically connected to the gate pad 112 via the first connection portion 225A and the second connection portion 225B, respectively. Similar to FIG. 20A, the first connection portion 225A of the present example is electrically connected to the gate pad 112 and the first gate metal layer 50-1 via the first contact portion 255A. Similar to FIG. 20B, the second connection portion 225B of the present example is electrically connected to the gate pad 112 and the second gate metal layer 50-2 via the second contact portion 255B.

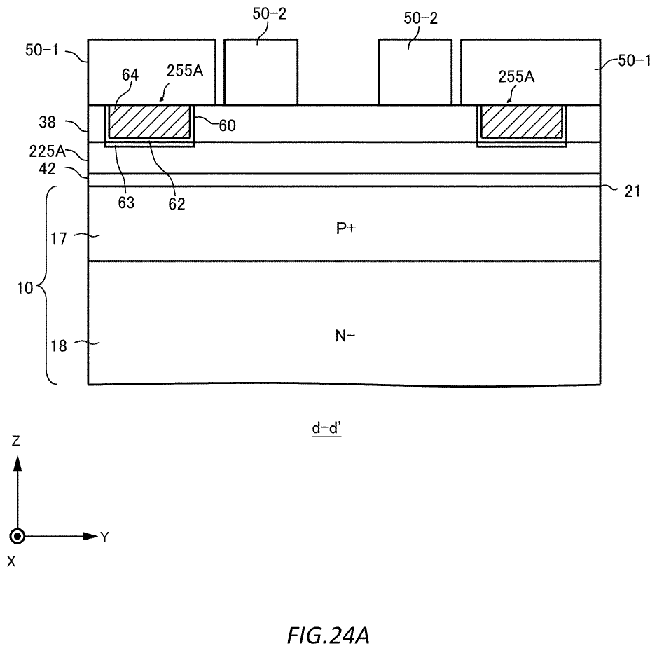

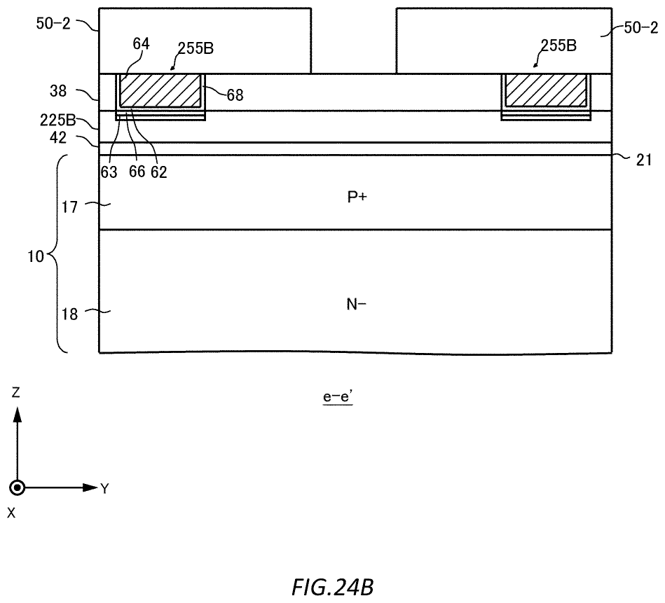

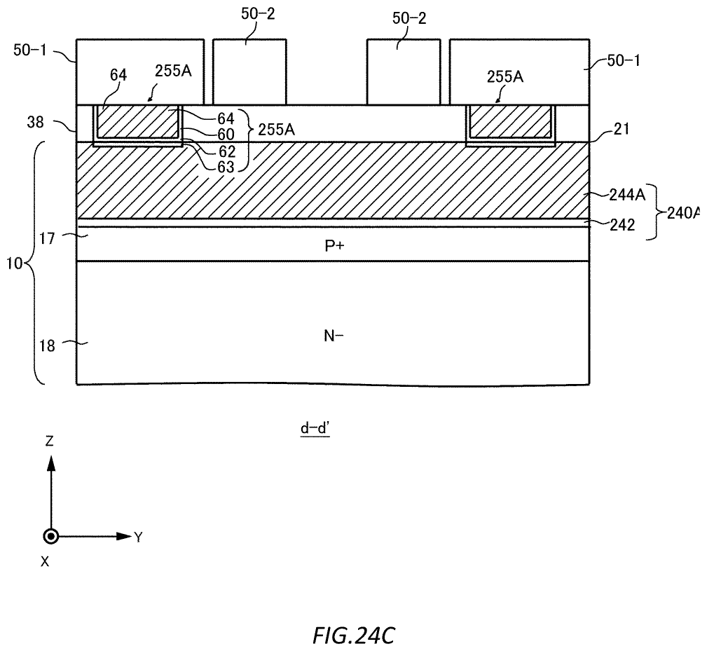

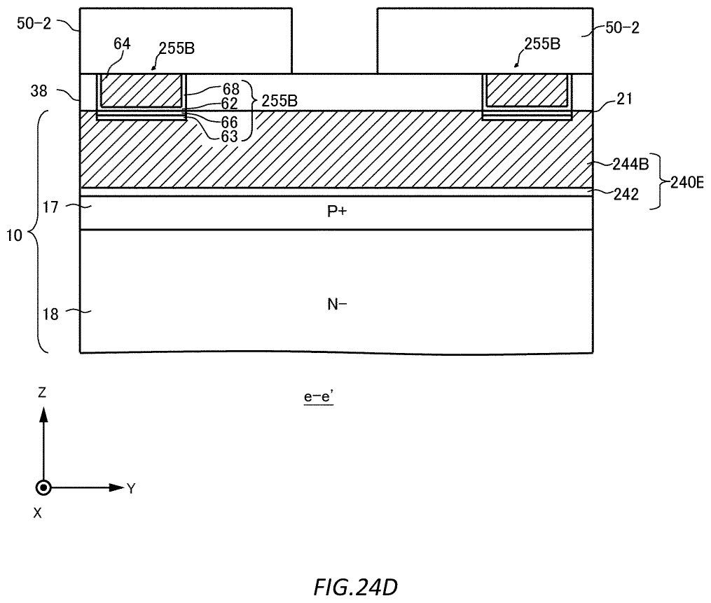

The first gate metal layer 50-1 and the second gate metal layer 50-2 surrounding the active portion 120 on the negative side in the Y axis direction are electrically connected to the first gate metal layer 50-1 and the second gate metal layer 50-2 surrounding the active portion 120 on the positive side in the Y axis direction, via the first connection portion 225A and the second connection portion 225B, respectively. The first gate metal layer 50-1 and the second gate metal layer 50-2 extending between the active portion 120 and the end side 102 configure the outer circumferential gate runner 130 together with the first connection portion 225A and the second connection portion 225B, and the first gate metal layer 50-1 and the second gate metal layer 50-2 extending between the active portions 120 configures an inter-active-portion gate runner 131. The first connection portion 225A connecting between the first gate metal layers 50-1 and the second connection portion 225B connecting between the second gate metal layers 50-2 are described referring to FIG. 24A and FIG. 24B.

FIG. 24A shows an example of the cross section d-d′ in FIG. 23. The cross section d-d′ is a Y-Z cross section passing through the first gate metal layer 50-1 and the second gate metal layer 50-2 in the intersection parts between the outer circumferential gate runner 130 and the inter-active-portion gate runner 131. The first gate metal layer 50-1 and the second gate metal layer 50-2 of the present example are provided to be spaced apart from each other. The first contact portion 255A of the present example is provided below the first gate metal layer 50-1, and electrically connects the first gate metal layer 50-1 to the first connection portion 225A. The first contact portion 255A of the present example has a longitudinal length in the Y axis direction, but is not limited thereto. The first contact portion 255A of the present example may have a structure such as the first contact portion 54A or the first trench contact portion 65A described by using FIG. 2A and figures after FIG. 2A.

The first gate metal layer 50-1 surrounding the active portion 120 on the negative side in the Y axis direction is electrically connected to the first connection portion 225A via the first contact portion 255A. Similarly, the first gate metal layer 50-1 surrounding the active portion 120 on the positive side in the Y axis direction is also electrically connected to the first connection portion 225A via the first contact portion 255A. That is, an underpass is formed below the second gate metal layer 50-2 by the first contact portion 255A and the first connection portion 225A, the first gate metal layer 50-1 surrounding the active portion 120 on the negative side in the Y axis direction is electrically connected to the first gate metal layer 50-1 surrounding the active portion 120 on the positive side in the Y axis direction via this underpass, and is electrically connected to the gate pad 112 via the first gate metal layer 50-1 surrounding the active portion 120 on the positive side in the Y axis direction.

FIG. 24B shows an example of cross section e-e′ from FIG. 23. The cross section e-e′ is a Y-Z cross section passing through the second gate metal layer 50-2 in the intersection parts between the outer circumferential gate runner 130 and the inter-active-portion gate runner 131. The second contact portion 255B of the present example is provided below the second gate metal layer 50-2, and electrically connects the second gate metal layer 50-2 to the second connection portion 225B. The second contact portion 255B of the present example has a longitudinal length in the Y axis direction, but is not limited thereto. The second contact portion 255B of the present example may have a structure such as the second contact portion 54B or the second trench contact portion 65B described by using FIG. 3A and figures after FIG. 3A. Note that the length of the second connection portion 225B in the Y axis direction in FIG. 23 and FIG. 24B, that is, the overall length of the second connection portion 225B in the Y axis direction or the distance between the second contact portions 255B is shown to be the same as the length of the first connection portion 225A in the Y axis direction of FIG. 23 and FIG. 24A, that is, the overall length of the first connection portion 225A in the Y axis direction, or the distance between the first contact portions 255A, but the length of the first connection portion 225A in the Y axis direction may be greater than or may be less than the length of the second connection portion 225B in the Y axis direction.

The second gate metal layer 50-2 surrounding the active portion 120 on the negative side in the Y axis direction is electrically connected to the second connection portion 225B via the second contact portion 255B. Similarly, the second gate metal layer 50-2 surrounding the active portion 120 on the positive side in the Y axis direction is also electrically connected to the second connection portion 225B via the second contact portion 255B. That is, an underpass is formed below the interlayer dielectric film 38 by the second contact portion 255B and the second connection portion 225B, the second gate metal layer 50-2 surrounding the active portion 120 on the negative side in the Y axis direction is electrically connected to the second gate metal layer 50-2 surrounding the active portion 120 on the positive side in the Y axis direction via this underpass, and is electrically connected to the gate pad 112 via the second gate metal layer 50-2 surrounding the active portion 120 on the positive side in the Y axis direction.

In the example shown in FIG. 23, FIG. 24A, and FIG. 24B, the inter-active-portion gate runner 131 is configured from two first gate metal layers 50-1 and two second gate metal layers 50-2, but may be configured from one first gate metal layer 50-1 and one second gate metal layer 50-2. That is, one first gate metal layer 50-1 and one second gate metal layer 50-2 may be connected to the gate trench portions 40 in both the positive side in the Y axis direction and the negative side in the Y axis direction. Also in such a case, in the intersection parts between the inter-active-portion gate runner 131 of the outer circumferential gate runner 130, an underpass using either of or both the first connection portion 225A and the second connection portion 225B may be formed. Also, since the first contact portion 255A and the second contact portion 255B are provided near the gate pad 112, it is possible to finely perform the adjustment of the characteristic even if each contact hole 255 connecting the first connection portion 225A and the second connection portion 225B to the first gate metal layer 50-1 and the second gate metal layer 50-2 does not have separate structures like the first contact portion 255A and the second contact portion 255B but has a structure of either of the first contact portion 255A or the second contact portion 255B.

FIG. 24c shows another example of the cross section d-d′ in FIG. 23. The present example is different from FIG. 24A in that the first connection trench portion 240A is provided instead of the first connection portion 225A. For another component, structures that are similar to the structures described by using FIG. 23 and FIG. 24A may be included.

The first gate metal layer 50-1 surrounding the active portion 120 on the negative side in the Y axis direction is electrically connected to the first connection trench conductive portion 244A via the first contact portion 255A. Similarly, the first gate metal layer 50-1 surrounding the active portion 120 on the positive side in the Y axis direction is also electrically connected to the first connection trench conductive portion 244A via the first contact portion 255A. That is, an underpass is formed below the second gate metal layer 50-2 by the first contact portion 255A and the first connection trench conductive portion 244A. The first gate metal layer 50-1 surrounding the active portion 120 on the negative side in the Y axis direction is electrically connected to the first gate metal layer 50-1 surrounding the active portion 120 on the positive side in the Y axis direction via this underpass, and is electrically connected to the gate pad 112 via the first gate metal layer 50-1 surrounding the active portion 120 on the positive side in the Y axis direction.

FIG. 24D shows another example of the cross section e-e′ in FIG. 23. The present example is different from FIG. 24B in that the second connection trench portion 240B is provided instead of the second connection portion 225B. For another component, structures that are similar to the structures described by using FIG. 23 and FIG. 24B may be included.

The second gate metal layer 50-2 surrounding the active portion 120 on the negative side in the Y axis direction is electrically connected to the second connection trench conductive portion 244B via the second contact portion 255B. Similarly, the second gate metal layer 50-2 surrounding the active portion 120 on the positive side in the Y axis direction is also electrically connected to the second connection trench conductive portion 244B via the second contact portion 255B. That is, an underpass is formed inside the semiconductor substrate 10 by the second contact portion 255B and the second connection trench conductive portion 244B. The second gate metal layer 50-2 surrounding the active portion 120 on the negative side in the Y axis direction is electrically connected to the second gate metal layer 50-2 surrounding the active portion 120 on the positive side in the Y axis direction via this underpass, and is electrically connected to the gate pad 112 via the second gate metal layer 50-2 surrounding the active portion 120 on the positive side in the Y axis direction.

As described above, also in the intersection parts between the inter-active-portion gate runner 131 of the outer circumferential gate runner 130 and also in the branch of the gate metal layers 50, like the connection between the gate pad 112 and the gate metal layer 50, the gate metal layers 50 surrounding each active portion 120 can be connected each other via the underpass obtained by the connection trench portion 240 provided on the front surface 21 of the semiconductor substrate 10 instead of the connection portion 225 provided above the semiconductor substrate 10. Also, the connection portion 225 and the connection trench portion 240 may be jointly used, for example, either of a connection between the gate pad 112 and the gate metal layer 50 or the underpass in the branch of the gate metal layers 50 may be configured with the connection portion 225 provided on the front surface 21 on the semiconductor substrate 10, and another one may be configured with the connection trench portion 240.

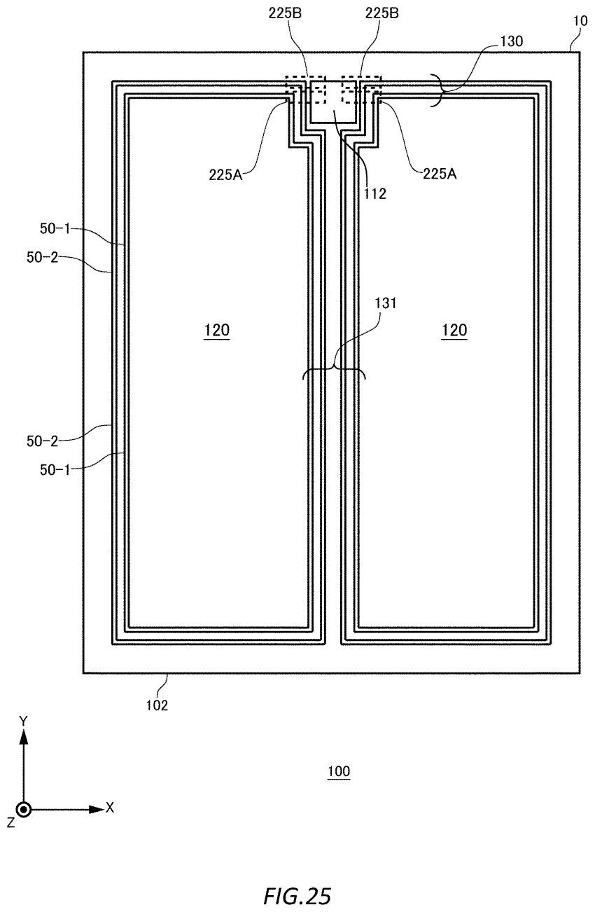

FIG. 25 shows another example of a top view of the semiconductor device 100. The semiconductor device 100 of FIG. 25 has two active portions 120 arranged side by side in the X axis direction, and is provided to have the first gate metal layer 50-1 and the second gate metal layer 50-2 surrounding each active portion 120 in a top view of the semiconductor substrate 10. In the active portion 120, an emitter electrode 52 is provided above the semiconductor substrate 10, but illustration thereof is omitted in FIG. 25. The emitter electrode 52, and the first gate metal layer 50-1 and the second gate metal layer 50-2 are provided to be spaced apart from each other. In the present example, in a top view of the semiconductor substrate 10, the first gate metal layer 50-1 is provided inside (the active portion 120 side), and the second gate metal layer 50-2 is provided outside (the end side 102 side). In the present example, in the active portion 120, the gate trench portion 40 may have a longitudinal length in the X axis direction, and may be connected to the outer circumferential gate runner 130 and the inter-active-portion gate runner 131 along the end side 102 in the X axis direction.

The first gate metal layer 50-1 and the second gate metal layer 50-2 surrounding the active portion 120 are electrically connected to the gate pad 112 via the first connection portion 225A and the second connection portion 225B, respectively. Similar to FIG. 20A, the first connection portion 225A of the present example is electrically connected to the gate pad 112 and the first gate metal layer 50-1 via the first contact portion 255A. Similar to FIG. 20B, the second connection portion 225B of the present example is electrically connected to the gate pad 112 and the second gate metal layer 50-2 via the second contact portion 255B.

The first gate metal layer 50-1 and the second gate metal layer 50-2 extending between the active portion 120 and the end side 102 configure the outer circumferential gate runner 130 together with the first connection portion 225A and the second connection portion 225B, and the first gate metal layer 50-1 and the second gate metal layer 50-2 extending between the active portions 120 configures an inter-active-portion gate runner 131. In the semiconductor device 100 of the present example, the inter-active-portion gate runner 131 and all of the active portions 120 are adjacent to the gate pad 112, and therefore, by connecting the gate pad 112 to the gate metal layer 50 forming the inter-active-portion gate runner 131 or the outer circumferential gate runner 130 surrounding each active portion 120 via the connection portion 225, all of the gate metal layers 50 are electrically connected to the gate pad 112. Therefore, in the semiconductor device 100 of the present example, the first connection portion 225A connecting between the first gate metal layers 50-1 and the second connection portion 225B connecting between the second gate metal layers 50-2 as shown in FIG. 24A and FIG. 24B may not be provided. Also in the present example, the gate pad 112 may be connected to the first gate metal layer 50-1 and the second gate metal layer 50-2 via the first connection trench portion 240A and the second connection trench portion 240B.

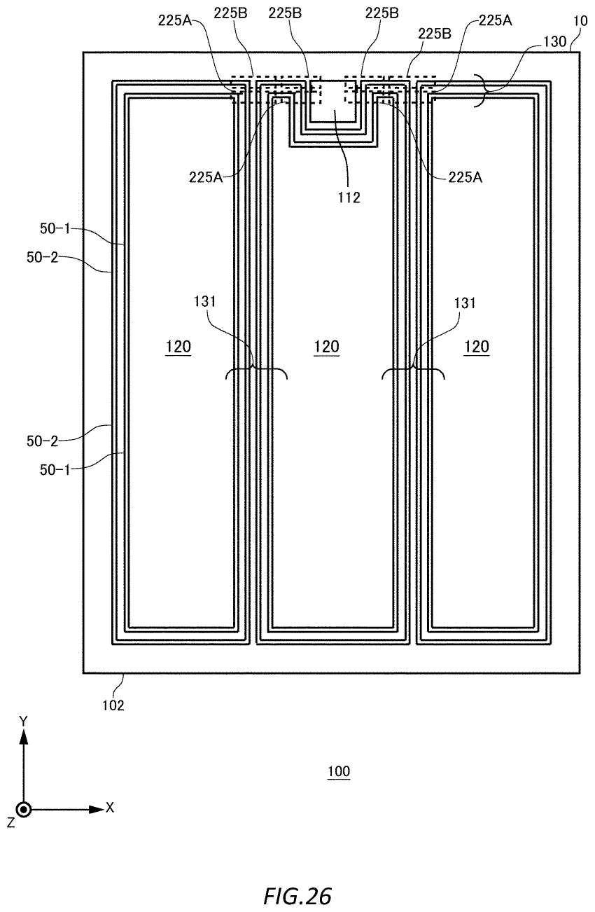

FIG. 26 shows another example of a top view of the semiconductor device 100. The semiconductor device 100 of FIG. 26 has three active portions 120 arranged side by side in the X axis direction, and is provided to have the first gate metal layer 50-1 and the second gate metal layer 50-2 surrounding each active portion 120 in a top view of the semiconductor substrate 10. In the active portion 120, an emitter electrode 52 is provided above the semiconductor substrate 10, but illustration thereof is omitted in FIG. 26. The emitter electrode 52, and the first gate metal layer 50-1 and the second gate metal layer 50-2 are provided to be spaced apart from each other. In the present example, in a top view of the semiconductor substrate 10, the first gate metal layer 50-1 is provided inside (the active portion 120 side), and the second gate metal layer 50-2 is provided outside (the end side 102 side).

The first gate metal layer 50-1 and the second gate metal layer 50-2 surrounding the active portion 120 positioned at the center in the X axis direction are electrically connected to the gate pad 112 via the first connection portion 225A and the second connection portion 225B, respectively. Similar to FIG. 20A, the first connection portion 225A of the present example is electrically connected to the gate pad 112 and the first gate metal layer 50-1 via the first contact portion 255A. Similar to FIG. 20B, the second connection portion 225B of the present example is electrically connected to the gate pad 112 and the second gate metal layer 50-2 via the second contact portion 255B.

The first gate metal layer 50-1 and the second gate metal layer 50-2 surrounding the active portion 120 positioned outside (the positive side in the X axis direction or the negative side) in the X axis direction are electrically connected to the first gate metal layer 50-1 and the second gate metal layer 50-2 surrounding the active portion 120 positioned at the center in the X axis direction, via the first connection portion 225A and the second connection portion 225B, respectively. The first gate metal layer 50-1 and the second gate metal layer 50-2 extending between the active portion 120 and the end side 102 configure the outer circumferential gate runner 130 together with the first connection portion 225A and the second connection portion 225B, and the first gate metal layer 50-1 and the second gate metal layer 50-2 extending between the active portions 120 configures an inter-active-portion gate runner 131. The first connection portion 225A connects between the first gate metal layers 50-1 via the first contact portion 255A, as shown in FIG. 24A. The second connection portion 225B connects between the second gate metal layers 50-2 via the second contact portion 255B, as shown in FIG. 24B. Also in the present example, the gate pad 112, the first gate metal layer 50-1 and the second gate metal layer 50-2 may be connected via the first connection trench portion 240A and the second connection trench portion 240B instead of the first connection portion 225A and the second connection portion 225B.

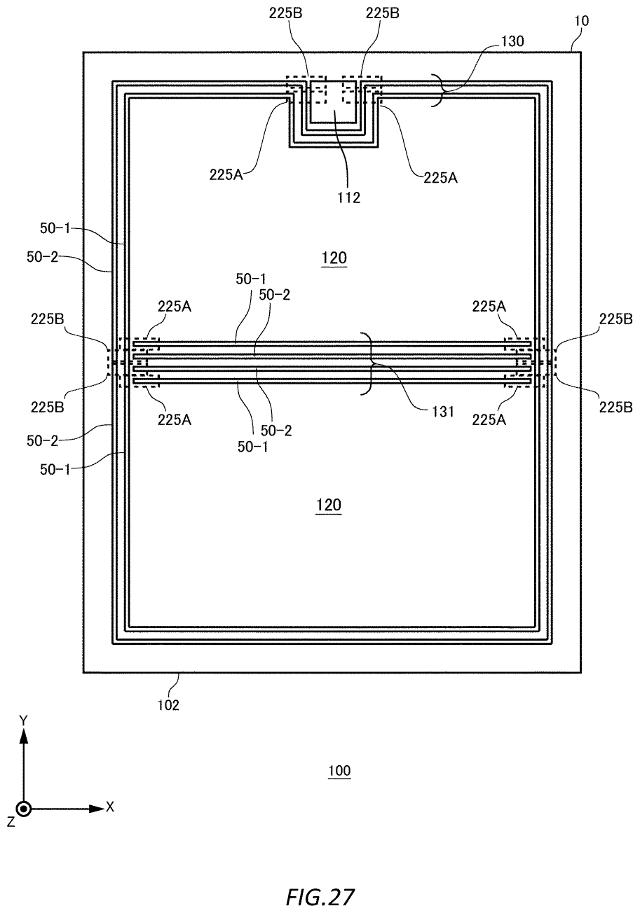

FIG. 27 shows another example of a top view of the semiconductor device 100. The present example is different from the example described in FIG. 23 in that the gate metal layers 50 of the outer circumferential gate runner 130 positioned outside the two active portions 120 are connected, and spaced apart from the gate metal layer 50 of the inter-active-portion gate runner 131. Also in such a case, the first gate metal layer 50-1 and the second gate metal layer 50-2 of the outer circumferential gate runner 130, the first gate metal layer 50-1 and the second gate metal layer 50-2 of the inter-active-portion gate runner 131 can be connected via the first connection portion 225A and the second connection portion 225B, to electrically connect the first gate metal layer 50-1 and the second gate metal layer 50-2 surrounding each active portion 120 to the gate pad 112. In another example, instead of the first connection portion 225A and the second connection portion 225B, the first connection trench portion 240A and the second connection trench portion 240B may be used.

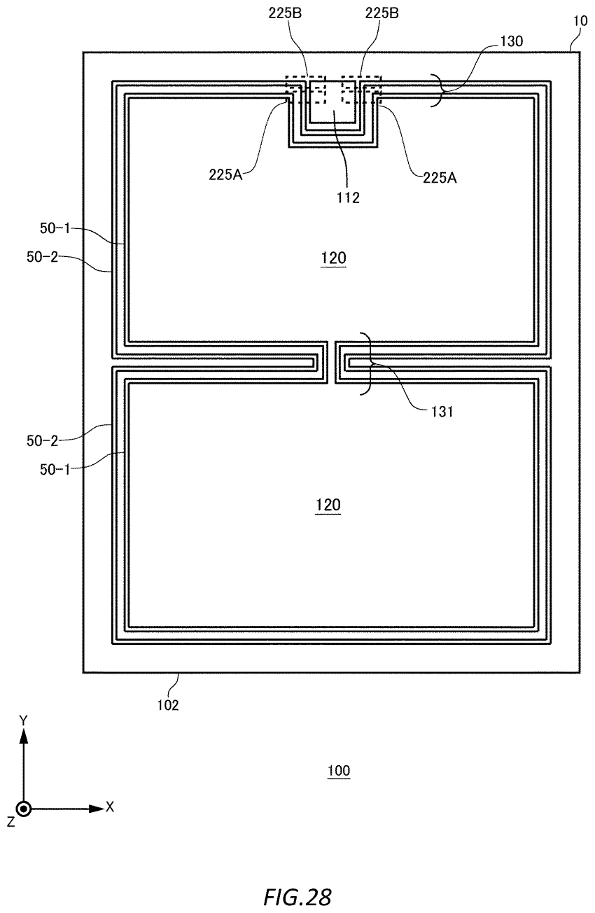

FIG. 28 shows another example of a top view of the semiconductor device 100. The present example is different from the example described in FIG. 23 in that the gate metal layer 50 of the inter-active-portion gate runner 131 that is connected to the gate metal layer 50 of the outer circumferential gate runner 130 surrounding one active portion 120 is separated into the gate metal layer 50 extending from the negative side in X axis direction and the gate metal layer 50 extending from the positive side in the X axis direction, and is respectively connected to the gate metal layer 50 extending from the negative side in X axis direction and the gate metal layer 50 extending from the positive side in the X axis direction in the outer circumferential gate runner 130 surrounding another active portion 120. When the gate metal layers 50 are connected to be one in this manner, the first connection portion 225A, the second connection portion 225B or the like is not required to be used for connecting each of the first gate metal layer 50-1 and the second gate metal layer 50-2 of the outer circumferential gate runner 130 to each of the first gate metal layer 50-1 and the second gate metal layer 50-2 of the inter-active-portion gate runner 131. Near the gate pad 112, by connecting each of the first gate metal layer 50-1, the second gate metal layer 50-2, and the gate pad 112 via the first connection portion 225A and the second connection portion 225B, the first gate metal layer 50-1 and the second gate metal layer 50-2 each surrounding the active portion 120 can be electrically connected to the gate pad 112. In another example, instead of the first connection portion 225A and the second connection portion 225B, the first connection trench portion 240A and the second connection trench portion 240B may be used.

In the inter-active-portion gate runner 131, when the gate metal layers 50 of both the active portions 120 are connected in the Y axis direction at a position corresponding to the first region 70-1, the second gate metal layers 50-2 extending from the positive side in the X axis direction are connected closer to the positive side in the X axis direction in the Y axis direction than the first gate metal layers 50-1 extending from the positive side in the X axis direction, and therefore, in the first region 70-1 in which the first gate metal layers 50-1 extending from the positive side in the X axis direction is connected in the Y axis direction, a region in which the second gate metal layers 50-2 are not extending in the X axis direction exists. Similarly, the second gate metal layers 50-2 extending from the negative side in X axis direction are connected closer to the negative side in X axis direction in the Y axis direction than the first gate metal layer 50-1 extending from the negative side in X axis direction, and therefore, in the first region 70-1 in which the first gate metal layers 50-1 extending from the negative side in X axis direction is connected in the Y axis direction, a region in which the second gate metal layers 50-2 are not extending in the X axis direction exists. However, in the region, the gate trench portion 40 corresponding to the second gate metal layer 50-2 does not exist, and therefore, there is no problem.

On the other hand, in inter-active-portion gate runner 131, at a position at which the gate metal layer 50 on one active portion 120 side and a gate metal layer 50 on another active portion 120 side are connected, the first gate metal layer 50-1 extending from the negative side in X axis direction of one active portion 120 side and the first gate metal layer 50-1 extending from the negative side in X axis direction of another active portion 120 side may be connected closer to the inside in the X axis direction than the second gate metal layer 50-2. Accordingly, since the first gate metal layer 50-1 can be extended in the entire region in the X axis direction in the first region 70-1, the gate trench portion 40 corresponding to the first gate metal layer 50-1 can be connected on an approximate extension of the gate trench portion 40 in the Y axis direction. Note that even if a region in which the first gate metal layer 50-1 is not extending in the X axis direction exists, by extending the connection portion 25 in the X axis direction or the like, the first gate metal layer 50-1 and the gate trench portion 40 can be connected.

In the inter-active-portion gate runner 131, when the gate metal layers 50 of both the active portions 120 are connected in the Y axis direction at a position corresponding to the diode portion 80, a corresponding gate trench portion 40 is not provided in the diode portion 80, and therefore, there is no problem even if a region in which the first gate metal layer 50-1 and the second gate metal layer 50-2 do not exist exists.

In the inter-active-portion gate runner 131, when the gate metal layer 50 of both the active portions 120 are connected in Y axis direction at a position corresponding to the second region 70-2, a gate trench portion 40 corresponding to the first gate metal layer 50-1 does not exist in the second region 70-2, and therefore, there is no problem even if a region in which the first gate metal layer 50-1 is not extending in the X axis direction exists. In a region in which the second gate metal layer 50-2 is not extending in the X axis direction in the second region 70-2, the second gate metal layer 50-2 cannot be connected to the corresponding gate trench portion 40 on the approximate extension of the gate trench portion 40 in the Y axis direction, but the second gate metal layer 50-2 and the corresponding gate trench portion 40 can be connected by extending the connection portion 25 in the X axis direction or the like.

Also, the gate metal layers 50 of the inter-active-portion gate runner 131 may be separated into the gate metal layer 50 extending from the negative side in X axis direction and the gate metal layer 50 extending from the positive side in the X axis direction, and may be connected, in a region in which the gate metal layer 50 is not extending in the X axis direction, between the emitter electrodes 52 on both the active portions 120. Note that in order to connect the first gate metal layer 50-1 and the second gate metal layer 50-2 into one, the gate metal layer 50 on one active portion 120 side may be connected to the gate metal layer 50 on another active portion 120 side in a region other than the inter-active-portion gate runner 131, then the first gate metal layer 50-1 or the second gate metal layer 50-2 may be provided in a region in which the active portion 120 is not extending in a part of the surroundings.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

### (Item 1)

A semiconductor device comprising:
a semiconductor substrate;
an interlayer dielectric film that is above the semiconductor substrate and is provided with a contact hole;
a first upper electrode provided above the interlayer dielectric film, and including
a first region having a first contact portion that is electrically connected to the first upper electrode via the contact hole, and a second region having a second contact portion that is electrically connected to the first upper electrode via the contact hole, wherein
the second contact portion has a higher resistance than that of the first contact portion.

### (Item 2)

The semiconductor device according to item 1, wherein the first contact portion includes:
a first alloy layer including a first metal provided on a bottom surface of the contact hole; and
a first barrier metal layer that is provided inside the contact hole and that includes the first metal.

### (Item 3)

The semiconductor device according to item 2, wherein the first barrier metal layer includes a metal film including the first metal.

### (Item 4)

The semiconductor device according to item 2, wherein the first barrier metal layer includes:
a lower layer barrier metal portion; and
an upper layer barrier metal portion that is stacked on the lower layer barrier metal portion, wherein
the lower layer barrier metal portion is denser than the upper layer barrier metal portion.

### (Item 5)

The semiconductor device according to item 4, wherein the upper layer barrier metal portion is provided to be in contact with an upper surface of the first alloy layer.

### (Item 6)

The semiconductor device according to item 2, wherein the second contact portion includes:
the first alloy layer including the first metal provided on a bottom surface of the contact hole;
an oxide layer provided on an upper surface of the first alloy layer; and
a second barrier metal layer provided inside the contact hole.

### (Item 7)

The semiconductor device according to item 6, wherein the second barrier metal layer includes a nitride of the first metal.

### (Item 8)

The semiconductor device according to item 6, wherein the first barrier metal layer includes a metal film including the first metal.

### (Item 9)

The semiconductor device according to item 6, wherein the first barrier metal layer includes:
a lower layer barrier metal portion provided on a side wall of the contact hole; and
an upper layer barrier metal portion that is stacked on the lower layer barrier metal portion, wherein
the lower layer barrier metal portion is denser than the second barrier metal layer.

### (Item 10)

The semiconductor device according to item 9, wherein the lower layer barrier metal portion is a nitride of the first metal.

### (Item 11)

The semiconductor device according to item 1, comprising a transistor portion and a diode portion, wherein
the transistor portion and the diode portion include an emitter electrode and a collector electrode between which a load current flows, and
the first upper electrode is the emitter electrode.

### (Item 12)

The semiconductor device according to item 11, wherein the first region is provided in the transistor portion, and is provided to be spaced apart from the diode portion, and the second region is provided on the transistor portion, and is provided to be adjacent to the diode portion.

### (Item 13)

The semiconductor device according to item 11, wherein the first region is provided on the transistor portion, and is provided to be adjacent to the diode portion, and the second region is provided on the transistor portion, and is provided to be spaced apart from the diode portion.

### (Item 14)

semiconductor device according to item 12 or 13, wherein in a top view of the semiconductor substrate, an area proportion of the second region in the transistor portion is higher than an area proportion of the first region in the transistor portion.

### (Item 15)

The semiconductor device according to item 11, wherein the diode portion has the second region.

### (Item 16)

The semiconductor device according to item 15, wherein a thickness of a first oxide layer that is provided on a bottom surface of the contact hole of the second contact portion of the second region in the diode portion is greater than a thickness of a second oxide layer that is provided on a bottom surface of the contact hole of the second contact portion of the second region in the transistor portion.

### (Item 17)

The semiconductor device according to item 11, wherein

The second contact portion of the second region in the transistor portion has a third contact portion, and a fourth contact portion that is provided closer to the diode portion side than the third contact portion; and
a thickness of a fourth oxide layer that is provided on a bottom surface of the contact hole of the fourth contact portion is greater than a thickness of a third oxide layer that is provided on a bottom surface of the contact hole of the third contact portion.

### (Item 18)

The semiconductor device according to any one of items 6 to 10, wherein the oxide layer includes an oxide of elements configuring the first metal or the first alloy layer.

### (Item 19)

The semiconductor device according to any one of items 2 to 10, wherein the first barrier metal layer includes a nitride of the first metal.

### (Item 20)

The semiconductor device according to any one of items 2 to 10, wherein the first alloy layer includes a silicide of the first metal.

### (Item 21)

The semiconductor device according to any one of items 2 to 10, wherein the first metal is titanium.

### (Item 22)

The semiconductor device according to item 1, wherein the semiconductor substrate has a lifetime control region provided on a side of a front surface of the semiconductor substrate.

### (Item 23)

The semiconductor device according to item 12 or 13, wherein the semiconductor substrate has a lifetime control region provided on a side of a front surface of the semiconductor substrate, and the lifetime control region is provided to be extended, from the diode portion, to a boundary between the first region in the transistor portion and the second region in the transistor portion.

### (Item 24)

The semiconductor device according to item 1, comprising:
a gate trench portion that is provided on a front surface of the semiconductor substrate, and
a connection portion that is provided above the gate trench portion and that is electrically connected to the gate trench portion, wherein
the first upper electrode has a gate metal layer that is provided above the semiconductor substrate, and
the first contact portion and the second contact portion electrically connect the gate metal layer and the connection portion.

### (Item 25)

The semiconductor device according to item 24, wherein
the first upper electrode has a plurality of gate metal layers that are provided above the semiconductor substrate; and
the first contact portion and the second contact portion electrically connect a different gate metal layer among the plurality of gate metal layers to the connection portion.

### (Item 26)

The semiconductor device according to item 1, comprising
a gate trench portion that is provided on a front surface of the semiconductor substrate, wherein
the first upper electrode has a gate metal layer that is provided above the gate trench portion, and
the first contact portion and the second contact portion electrically connect the gate metal layer and the gate trench portion.

### (Item 27)

The semiconductor device according to item 1, wherein
the first upper electrode has a gate pad that is provided above the semiconductor substrate, and
at least one of the first contact portion or the second contact portion is provided below the gate pad.

### (Item 28)

The semiconductor device according to item 27, wherein both the first contact portion and the second contact portion are provided below the gate pad.

### (Item 29)

The semiconductor device according to item 1, comprising
a connection portion that is provided above the semiconductor substrate or a connection trench portion that is provided on a front surface of the semiconductor substrate, wherein
the first upper electrode has a plurality of gate metal layers that are provided to be extended above the connection portion, and
at least one of the first contact portion or the second contact portion electrically connects the plurality of gate metal layers to a connection trench conductive portion that is provided inside the connection portion or the connection trench portion.

### (Item 30)

The semiconductor device according to item 1, comprising
a first gate trench portion that is provided on a front surface of the semiconductor substrate, and a second gate trench portion that extends further than the first gate trench portion, wherein
the first upper electrode includes a first gate metal layer, and a second gate metal layer that extends to an outside further than the first gate metal layer in a top view of the semiconductor substrate, and
the first gate trench portion is electrically connected to the first gate metal layer via the first contact portion, and
the second gate trench portion extends beyond the first gate metal layer in a top view of the semiconductor substrate, and is electrically connected to the second gate metal layer via the second contact portion.

### (Item 31)

A method for manufacturing a semiconductor device comprising:
forming an interlayer dielectric film above a semiconductor substrate;
forming a contact hole in the interlayer dielectric film;
forming a first upper electrode above the interlayer dielectric film;
forming a first contact portion in a first region; and
forming a second contact portion in a second region, wherein
the first contact portion is electrically connected to the first upper electrode via the contact hole, and the second contact portion is electrically connected to the first upper electrode via the contact hole, and
the second contact portion has a higher resistance than that of the first contact portion.

### EXPLANATION OF REFERENCES

10: semiconductor substrate;
12: emitter region;
14: base region;
15: contact region;
16: accumulation region;
17: well region;
18: drift region;
20: buffer region;
21: front surface;
22: collector region;
23: back surface;
24: collector electrode;
25: connection portion;
30: dummy trench portion;
31: extending part;
32: dummy dielectric film;
33: connecting part;
34: dummy conductive portion;
38: interlayer dielectric film;
40: gate trench portion;
41: extending part;
42: gate dielectric film;
43: connecting part;
44: gate conductive portion;
50: gate metal layer;
50-1: first gate metal layer;
50-2: second gate metal layer;
52: emitter electrode;
54: contact hole;
54A: first contact portion;
54B: second contact portion;
54C: third contact portion;
54D: fourth contact portion;
54b: bottom surface;
54w: side wall;
55: contact hole;
55A: first contact portion;
55B: second contact portion;
56: contact hole;
60: first barrier metal layer;
61: lower layer barrier metal portion;
62: upper layer barrier metal portion;
63: first alloy layer;
64: plug layer;
65A: first trench contact portion;
65B: second trench contact portion;
66: oxide layer;
68: second barrier metal layer;
69: metal film;
70: transistor portion;
70-1: first region;
70-2: second region;
71: mesa portion;
80: diode portion;
81: mesa portion;
82: cathode region;
85: extension region;
90: boundary portion;
91: mesa portion;
100: semiconductor device;
102: end side;
112: gate pad;
114: open region;
120: active portion;
130: outer circumferential gate runner;
131: inter-active-portion gate runner;
140: edge termination structure portion;
151: back surface side lifetime control region;
152: front surface side lifetime control region;
225: connection portion;
225A: first connection portion;
225B: second connection portion;
240: connection trench portion;
240A: first connection trench portion;
240B: second connection trench portion;
242: connection trench dielectric film;
244: connection trench conductive portion;
244A: first connection trench conductive portion;
244B: second connection trench conductive portion;
245: dummy connection trench portion;
249: dummy connection trench conductive portion;
255: contact hole;
255A: first contact portion;
255B: second contact portion.

What is claimed is:

1. A semiconductor device comprising:
a semiconductor substrate;
an interlayer dielectric film that is above the semiconductor substrate and is provided with a contact hole;
a first upper electrode provided above the interlayer dielectric film, and including
a first region having a first contact portion that is electrically connected to the first upper electrode via the contact hole, and a second region having a second contact portion that is electrically connected to the first upper electrode via the contact hole, wherein
the second contact portion has a higher resistance than that of the first contact portion.

2. The semiconductor device according to claim 1, wherein the first contact portion includes:
a first alloy layer including a first metal provided on a bottom surface of the contact hole; and
a first barrier metal layer that is provided inside the contact hole and that includes the first metal.

3. The semiconductor device according to claim 2, wherein the first barrier metal layer includes a metal film including the first metal.

4. The semiconductor device according to claim 2, wherein the first barrier metal layer includes:
a lower layer barrier metal portion; and
an upper layer barrier metal portion that is stacked on the lower layer barrier metal portion, wherein
the lower layer barrier metal portion is denser than the upper layer barrier metal portion.

5. The semiconductor device according to claim 4, wherein the upper layer barrier metal portion is provided to be in contact with an upper surface of the first alloy layer.

6. The semiconductor device according to claim 2, wherein the second contact portion includes:
the first alloy layer including the first metal provided on a bottom surface of the contact hole;
an oxide layer provided on an upper surface of the first alloy layer; and
a second barrier metal layer provided inside the contact hole.

7. The semiconductor device according to claim 6, wherein the second barrier metal layer includes a nitride of the first metal.

8. The semiconductor device according to claim 6, wherein the first barrier metal layer includes a metal film including the first metal.

9. The semiconductor device according to claim 6, wherein the first barrier metal layer includes:
a lower layer barrier metal portion provided on a side wall of the contact hole; and
an upper layer barrier metal portion that is stacked on the lower layer barrier metal portion, wherein
the lower layer barrier metal portion is denser than the second barrier metal layer.

10. The semiconductor device according to claim 9, wherein the lower layer barrier metal portion is a nitride of the first metal.

11. The semiconductor device according to claim 1, comprising a transistor portion and a diode portion, wherein
the transistor portion and the diode portion include an emitter electrode and a collector electrode between which a load current flows, and
the first upper electrode is the emitter electrode.

12. The semiconductor device according to claim 11, wherein the first region is provided in the transistor portion, and is provided to be spaced apart from the diode portion, and the second region is provided on the transistor portion, and is provided to be adjacent to the diode portion.

13. The semiconductor device according to claim 11, wherein the first region is provided on the transistor portion, and is provided to be adjacent to the diode portion, and the second region is provided on the transistor portion, and is provided to be spaced apart from the diode portion.

14. The semiconductor device according to claim 12, wherein in a top view of the semiconductor substrate, an area proportion of the second region in the transistor portion is higher than an area proportion of the first region in the transistor portion.

15. The semiconductor device according to claim 11, wherein the diode portion has the second region.

16. The semiconductor device according to claim 15, wherein a thickness of a first oxide layer that is provided on a bottom surface of the contact hole of the second contact portion of the second region in the diode portion is greater than a thickness of a second oxide layer that is provided on a bottom surface of the contact hole of the second contact portion of the second region in the transistor portion.

17. The semiconductor device according to claim 11, wherein
The second contact portion of the second region in the transistor portion has a third contact portion, and a fourth contact portion that is provided closer to the diode portion side than the third contact portion; and
a thickness of a fourth oxide layer that is provided on a bottom surface of the contact hole of the fourth contact portion is greater than a thickness of a third oxide layer that is provided on a bottom surface of the contact hole of the third contact portion.

18. The semiconductor device according to claim 6, wherein the oxide layer includes an oxide of elements configuring the first metal or the first alloy layer.

19. The semiconductor device according to claim 2, wherein the first barrier metal layer includes a nitride of the first metal.

20. The semiconductor device according to claim 2, wherein the first alloy layer includes a silicide of the first metal.

21. The semiconductor device according to claim 2, wherein the first metal is titanium.

22. The semiconductor device according to claim 1, wherein the semiconductor substrate has a lifetime control region provided on a side of a front surface of the semiconductor substrate.

23. The semiconductor device according to claim 12, wherein the semiconductor substrate has a lifetime control region provided on a side of a front surface of the semiconductor substrate, and the lifetime control region is provided to be extended, from the diode portion, to a boundary between the first region in the transistor portion and the second region in the transistor portion.

24. The semiconductor device according to claim 1, comprising:
a gate trench portion that is provided on a front surface of the semiconductor substrate; and
a connection portion that is provided above the gate trench portion and that is electrically connected to the gate trench portion, wherein
the first upper electrode has a gate metal layer that is provided above the semiconductor substrate, and
the first contact portion and the second contact portion electrically connect the gate metal layer and the connection portion.

25. The semiconductor device according to claim 24, wherein
the first upper electrode has a plurality of gate metal layers that are provided above the semiconductor substrate; and
the first contact portion and the second contact portion electrically connect a different gate metal layer among the plurality of gate metal layers to the connection portion.

26. The semiconductor device according to claim 1, comprising
a gate trench portion that is provided on a front surface of the semiconductor substrate, wherein
the first upper electrode has a gate metal layer that is provided above the gate trench portion, and
the first contact portion and the second contact portion electrically connect the gate metal layer and the gate trench portion.

27. The semiconductor device according to claim 1, wherein
the first upper electrode has a gate pad that is provided above the semiconductor substrate, and
at least one of the first contact portion or the second contact portion is provided below the gate pad.

28. The semiconductor device according to claim 27, wherein both the first contact portion and the second contact portion are provided below the gate pad.

29. The semiconductor device according to claim 1, comprising
a connection portion that is provided above the semiconductor substrate or a connection trench portion that is provided on a front surface of the semiconductor substrate, wherein
the first upper electrode has a plurality of gate metal layers that are provided to be extended above the connection portion, and
at least one of the first contact portion or the second contact portion electrically connects the plurality of gate metal layers to a connection trench conductive portion that is provided inside the connection portion or the connection trench portion.

30. The semiconductor device according to claim 1, comprising
a first gate trench portion that is provided on a front surface of the semiconductor substrate, and a second gate trench portion that extends further than the first gate trench portion, wherein
the first upper electrode includes a first gate metal layer, and a second gate metal layer that extends to an outside further than the first gate metal layer in a top view of the semiconductor substrate, and
the first gate trench portion is electrically connected to the first gate metal layer via the first contact portion, and
the second gate trench portion extends beyond the first gate metal layer in a top view of the semiconductor substrate, and is electrically connected to the second gate metal layer via the second contact portion.
